(19) United States
(12) Patent Application Publication
(10) Pub. No.: US 2003/0165772 A1
(43) Pub. Date: Sep. 4, 2003

(54) Negative resist composition

(75) Inventors: Hyou Takahashi, Shizuoka (JP); Shoichiro Yasunami, Shizuoka (JP)

Correspondence Address: SUGHRUE MION, PLLC, 2100 PENNSYLVANIA AVENUE, N.W., WASHINGTON, DC, 20037, US

(73) Assignee: FUJI PHOTO FILM CO., LTD.

(21) Appl. No.: 10/319,493

(22) Filed: Dec. 16, 2002

(30) Foreign Application Priority Data
Dec. 17, 2001 (JP) P.2001-383291

(51) Int. Cl. G03F 7/038

(52) U.S. Cl. 430/270.1

(57) ABSTRACT

A negative resist composition comprising: (A) a compound capable of generating an acid on exposure to active light or a radiation; (B) a resin soluble in an aqueous alkali solution; (C) a compound having an alcohol structure which is excited by the acid generated by the component (A) to reduce an alkali solubility of a resist film formed of the negative resist composition; (D) a crosslinking agent which is excited by the acid generated by the component (A) to induce a crosslinking reaction; and (E) a solvent.

### FIELD OF THE INVENTION

This invention relates to a negative resist composition having high sensitivity, high resolution and excellent isolated line resolution (isolated line performance).

### BACKGROUND OF THE INVENTION

Various type of negative-working resist compositions have recently been proposed.

Application of electron beam (e-beam) lithography for pattern formation in the fabrication of ultralarge-scale integrated (ULSI) semiconductor devices of next generations having integrity levels of 256 Mega, 1 Giga, 4 Giga, etc. has been under study for expectation of achievable higher resolution powers as compared with optical lithography using radiations such as i-lines and excimer laser light as a light source. E-beam lithography is said to be disadvantageous in that pattern formation is too time-consuming, requiring a longer exposure (writing) time with an increasing pattern to be wrote because, unlike the optical exposure system using i-lines, excimer laser light or a like light source, e-beam lithography involves direct writing of a resist pattern by scanning. That is, as the integrity drastically increases to 256 Mega, 1 Giga or 4 Giga, the exposure time drastically increases, too, resulting in extremely low throughputs.

In order to put e-beam lithography to practical use, it is essentially required to reduce the exposure time. To meet this requirement, it has been keenly demanded to increase the sensitivity of a resist composition as a pattern forming material. Since an increase in sensitivity is accompanied by reduction in resolution, it has been a problem to be solved to obtain high sensitivity as well as high resolution.

Techniques for reducing alkali solubility of a resist film by using a compound having an alcohol structure include processes comprising dehydration of an alicyclic tertiary alcohol and subsequent crosslinking with a neighboring phenol nucleus (see JP-A-2001-249455 (The term “JP-A” as used herein means an “unexamined published Japanese patent application”), JP-A-2001-154357, JP-A-2001-24956, DE10043678A1, JP-A-11-295885, and US2001-0006752A1) and processes comprising dehydration of a tertiary alcohol having a hydroxyl group on a carbon atom directly bonded to an aromatic ring and resultant polarity conversion (see Japanese Patent 3042701, JP-A-2000-31020, JP-A-10-268518, JP-A-11-133606, JP-A-2000-171976, JP-A-11-249307, and JP-A-7-104473).

None of these conventional techniques has satisfied both the requirements of high sensitivity and high resolution. Additionally, there still remains the problem that sufficient isolated line performance is not obtained. The isolated line performance is one of the important performance requirements of a negative resist composition.

### SUMMARY OF THE INVENTION

An object of the present invention is to provide a negative resist composition which achieves both high sensitivity and high resolution and also exhibits excellent isolated line performance.

As a result of extensive investigations, the present inventors have found that all the sensitivity, resolution and isolated line performance requirements can be met by a composition comprising a combination of specific compounds and completed the present invention.

The present invention provides a negative resist composition comprising (A) a compound capable of generating an acid on exposure to active light (actinic ray) or a radiation, (B) a resin soluble in an aqueous alkali solution, (C) a compound having an alcohol structure which is excited by the acid generated by component (A) to reduce the alkali solubility of a resist film, (D) a crosslinking agent which is excited by the acid generated by component (A) to induce a crosslinking reaction, and (E) a solvent.

The present invention also provides preferred embodiments of the negative resist composition, including:

(1) The negative resist composition, wherein component (D) is at least one compound selected from the group consisting of a compound represented by formula (2):

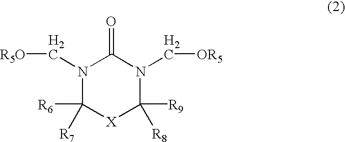

wherein two R₅'s each represent a hydrogen atom, an alkyl group or an acyl group; R₆, R₇, R₈, and R₉ each represent a hydrogen atom, a hydroxyl group, an alkyl group or an alkoxy group; and X represents a single bond, a methylene group or an oxygen atom,

a compound represented by formula (3):

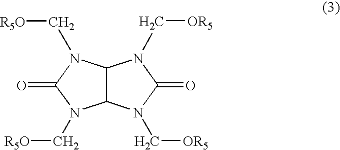

wherein a plurality of R₅'s are each as defined above,

a compound represented by formula (4):

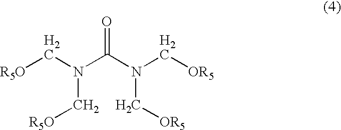

wherein a plurality of R₅'s are each as defined above, and an alkoxymethylated melamine compound;

(2) The negative resist composition, wherein component (D) is a phenol derivative having 1 to 6 benzene rings and having at least two substituents selected from a hydroxymethyl group and an alkoxymethyl group bonded to at least one of the benzene rings; and

(3) The negative resist composition which further-comprises (F) a basic compound.

### DETAILED DESCRIPTION OF THE INVENTION

The compound capable of generating an acid on exposure to active light or a radiation (hereinafter referred to as an acid generator) which can be used as component (A) is appropriately selected from compounds capable of generating an acid on exposure to known light sources (e.g., ultraviolet rays of 200 to 400 nm, far-infrared rays (g-lines, h-lines, i-lines, and KrF excimer laser light)), ArF excimer laser light, electron beams, X-rays, molecular beams or ion beams, which are used as photo initiators for photo-cationic polymerization, photo initiators for photo-radical polymerization, photobleaching agents for dyes, photo-discoloring agents, compounds used in microresists, and the like.

Further included are onium salts, such as diazonium salts, ammonium salts, phosphonium salts, iodonium salts, sulfonium salts, selenonium salts, and arsonium salts; organic halogen compounds; organometallic/organohalogen compounds; acid generators having an o-nitrobenzyl type protective group; compounds generating sulfonic acid on photolysis which are represented by iminosulfonates; disulfone compounds; diazoketosulfone; and diazodisulfone compounds. Polymers having the acid generating compound recited above or an acid-generating group derived therefrom in the main or side chain thereof are also useful as component (A).

Additional useful acid generators are described in V. N. R. Pillai Synthesis, 1980, (1), 1, A. Abd, et al., Tetrahedron Lett., 1971, (47), 4555, D. H. R. Barton, et al., J. Chem. Soc., 1970, (C), 329, U.S. Pat. No. 3,779,778, and EP126,712.

Of the above-recited acid generators, those having a fluorine-containing anion are mentioned as effective ones. Such acid generators include sulfonates composed of an iodonium cation or a sulfonium cation and an anion represented by R^{F}SO₃⁻, wherein R^{F} is a fluoroalkyl group having 1 to 10 carbon atoms. The fluoroalkyl group as R^{F} may be straight, branched or cyclic. R^{F} is preferably a straight-chain fluoroalkyl group CF₃(CF₂)_{y} wherein y is an integer of 0 to 9.

The iodonium or sulfonium cation preferably includes those represented by formulae (I), (II) and (III):

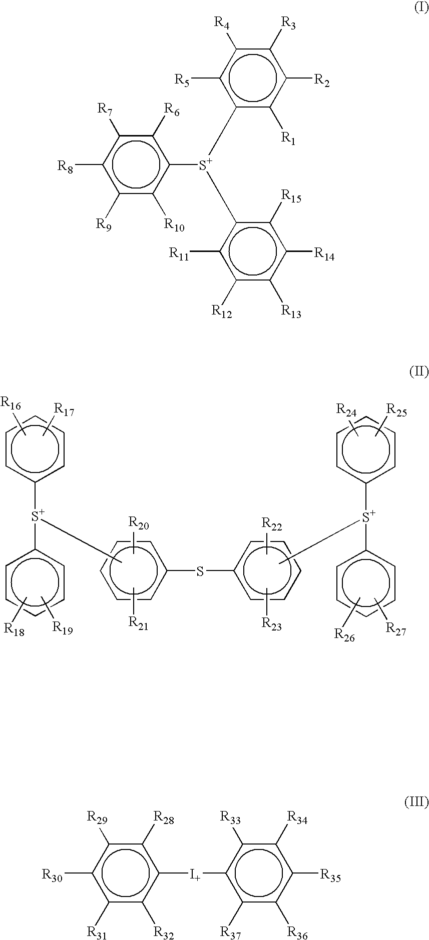

wherein R₁, R₂, R₃, R₄, R₅, R₆, R₇, R₈, R₉, R₁₀, R₁₁, R₁₂, R₁₃, R₁₄, R₁₅, R₁₆, R₁₇, R₁₈, R₁₉, R₂₀, R₂₁, R₂₂, R₂₃, R₂₄, R₂₅, R₂₆, R₂₇, R₂₈, R₂₉, R₃₀, R₃₁, R₃₂, R₃₃, R₃₄, R₃₅, R₃₆, and R₃₇, which are the same or different, each represent a hydrogen atom, a straight-chain, branched or cyclic alkyl group, a straight-chain, branched or cyclic alkoxy group, a hydroxyl group, a halogen atom or —S—R₃₈, wherein R₃₈ represents a straight-chain, branched or cyclic alkyl group or an aryl group; two or more of R₁, R₂, R₃, R₄, R₅, R₆, R₇, R₈, R₉, R₁₀, R₁₁, R₁₂, R₁₃, R₁₄ and R₁₅, two or more of R₁₆, R₁₇, R₁₉, R₁₉, R₂₀, R₂₁, R₂₂, R₂₃, R₂₄, R₂₅, R₂₆, and R₂₇,- or two or more of R₂₈, R₂₉, R₃₀, R₃₁, R₃₂, R₃₃, R₃₄, R₃₅, R₃₆, and R₃₇ may be taken together to form a ring containing at least one member selected from a single bond, a carbon atom, an oxygen atom, a sulfur atom, and a nitrogen atom.

In formulae I to (III), the straight-chain or branched alkyl groups as represented by R₁ through R₃₈ include those having 1 to 4 carbon atoms such as methyl, ethyl, propyl, n-butyl, sec-butyl and t-butyl, each of which may have a substituent. The cyclic alkyl group as represented by R₁ to R₃₈ include those having 3 to 8 carbon atoms, such as cyclopropyl, cyclopentyl, and cyclohexyl, each of which may have a substituent.

The straight-chain or branched alkoxy groups as represented by R₁ to R₃₇ include those having 1 to 4 carbon atoms, such as methoxy, ethoxy, hydroxyethoxy, propoxy, n-butoxy, isobutoxy, sec-butoxy, and t-butoxy. The cyclic alkoxy groups as represented by R₁ to R₃₇ include cyclopentyloxy and cyclohexyloxy.

The halogen atoms as represented by R₁ through R₃₇ include fluorine, chlorine, bromine, and iodine.

The aryl group as represented by R₃₈ is selected from substituted or unsubstituted aryl groups having 6 to 14 carbon atoms, such as phenyl, tolyl, methoxyphenyl, and naphthyl.

The substituents the above-described alkyl, alkoxy or aryl groups may have preferably include an alkoxy group having 1 to 4 carbon atoms, a halogen atom (e.g., fluorine, chlorine or iodine), an aryl group having 6 to 10 carbon atoms, an alkenyl group having 2 to 6 carbon atoms, a cyano group, a hydroxyl group, a carboxyl group, an alkoxycarbonyl group, and a nitro group.

The ring containing at least one member selected from a single bond, a carbon atom, an oxygen atom, a sulfur atom, and a nitrogen atom, which is formed of two or more of R₁ to R₁₅, two or more of R₁₆ to R₂₇, or two or more of R₂₈ to R₃₇ connected to each other, includes a furan ring, a dihydrofuran ring, a pyran ring, a trihydropyran ring, a thiophene ring, and a pyrrole ring.

Specific examples of acid generators which can be used in the present invention are shown below.

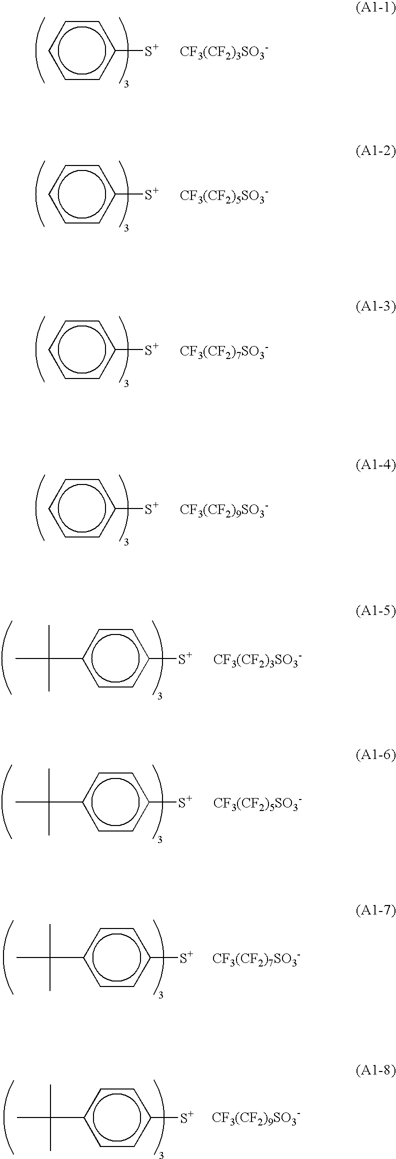

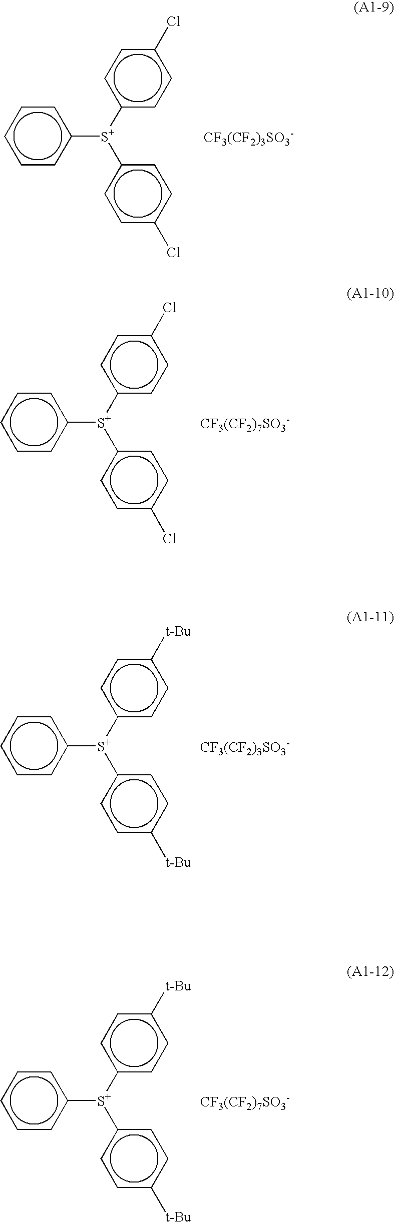

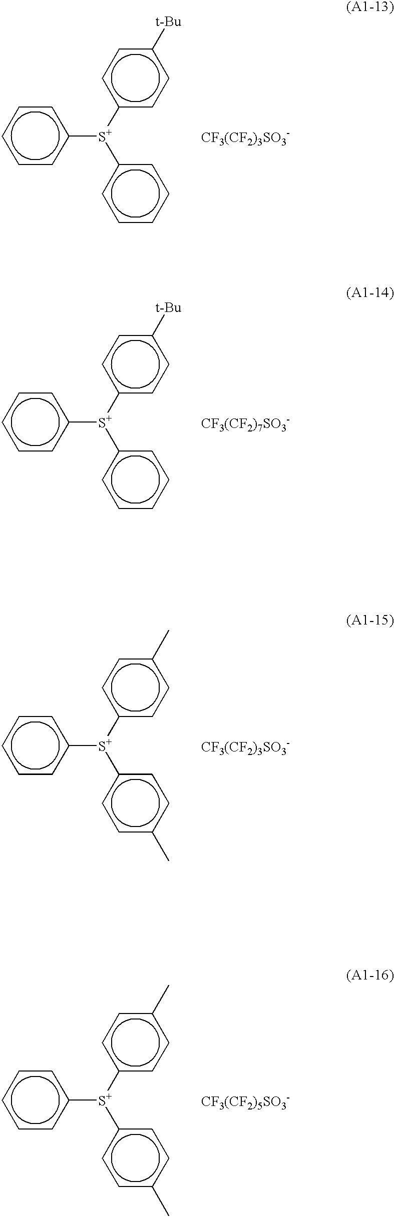

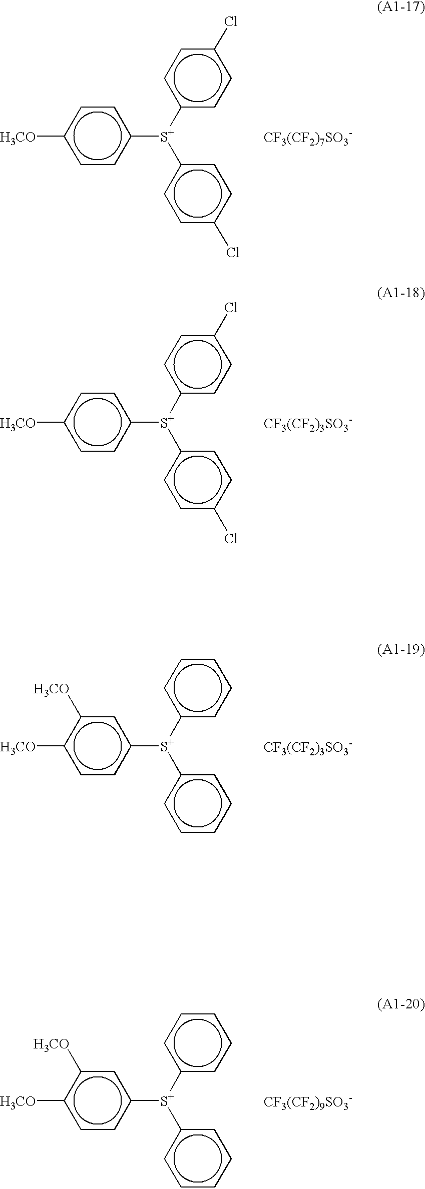

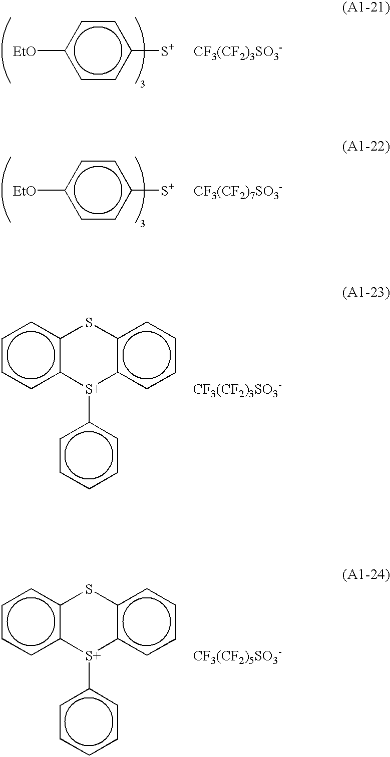

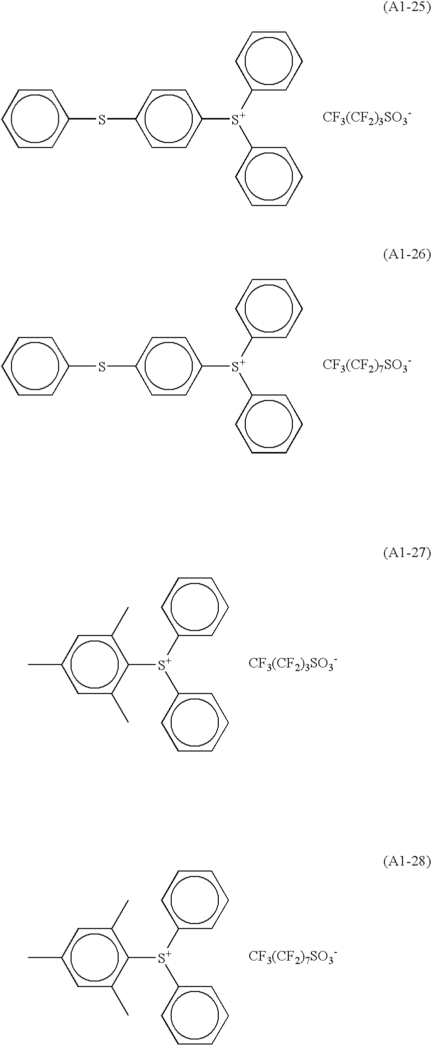

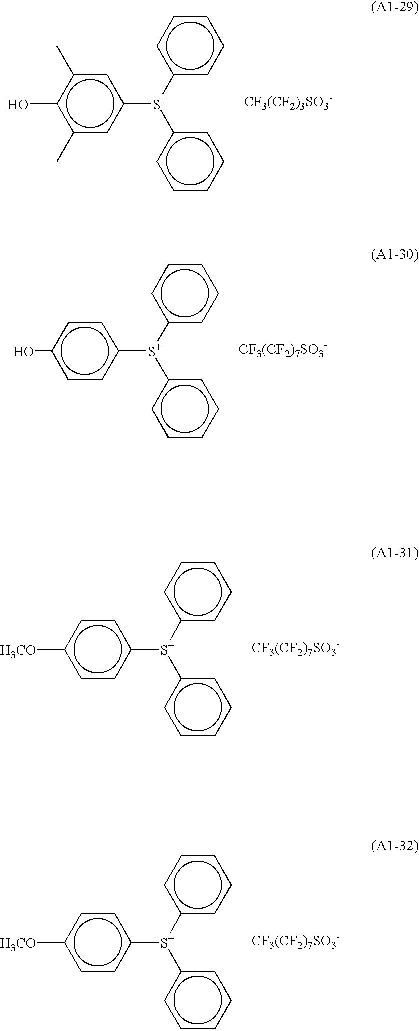

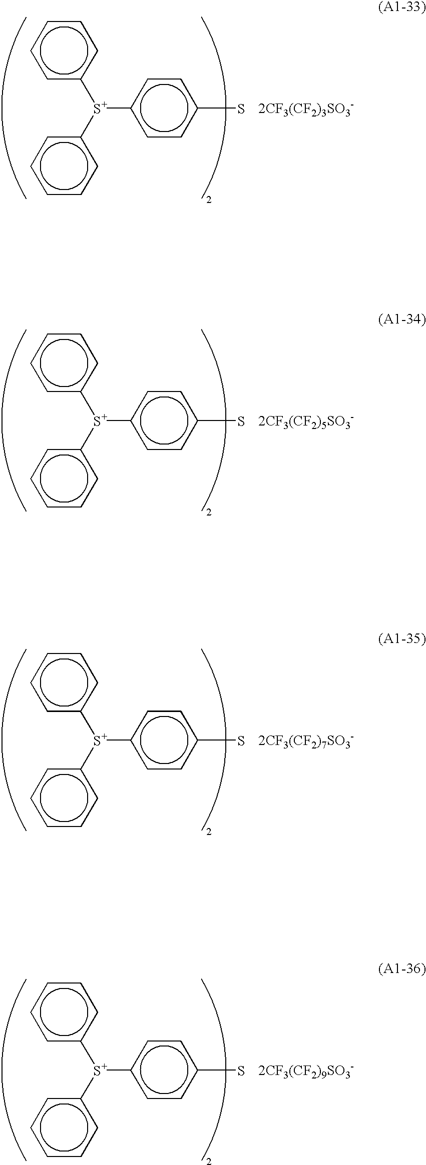

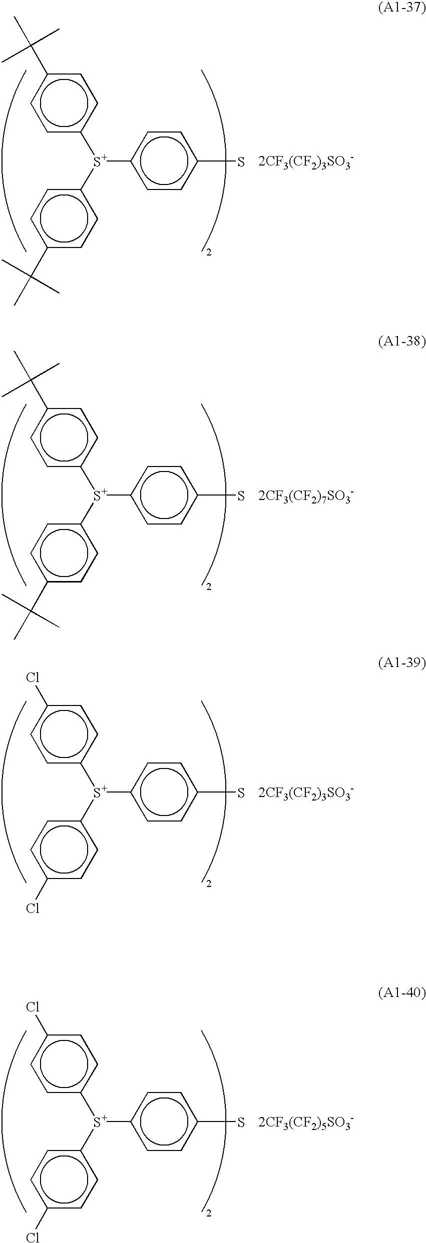

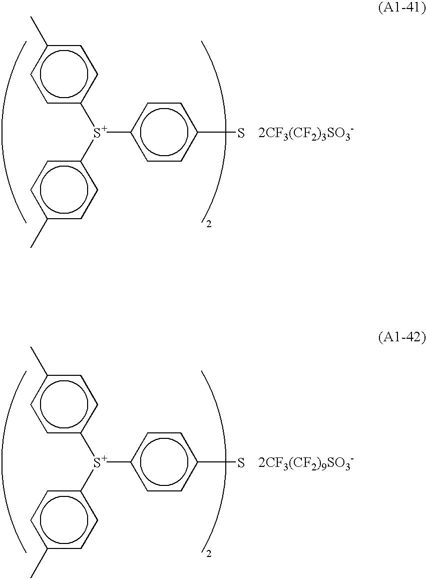

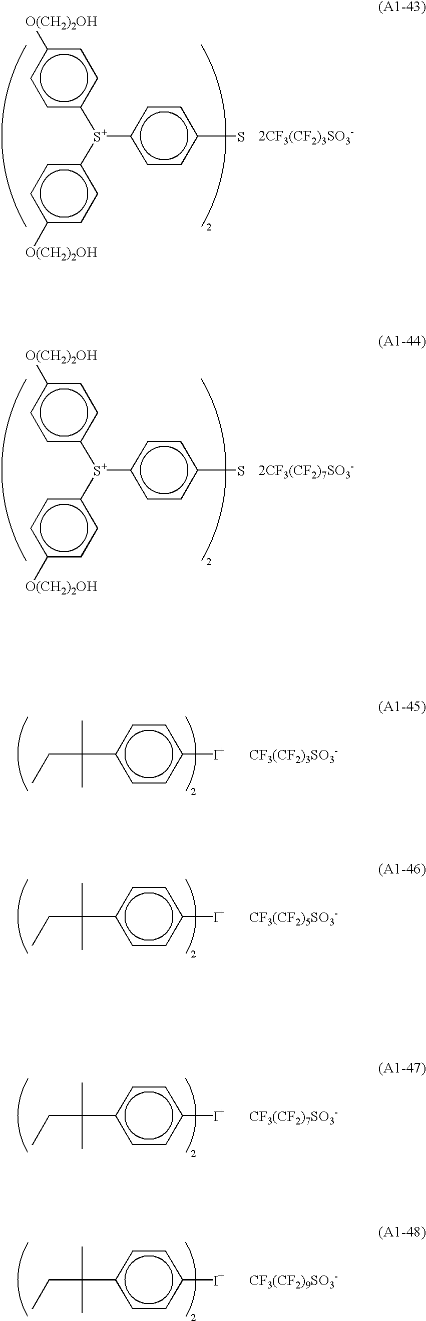

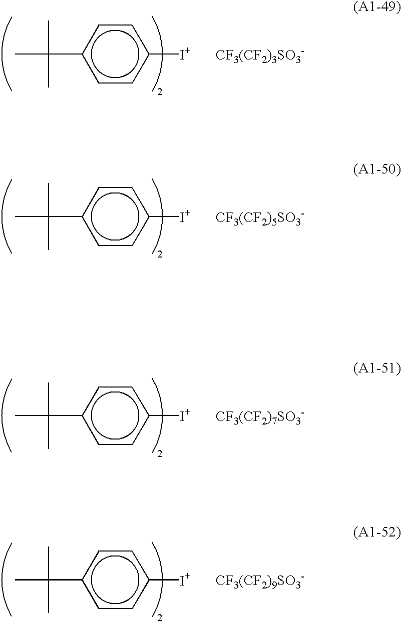

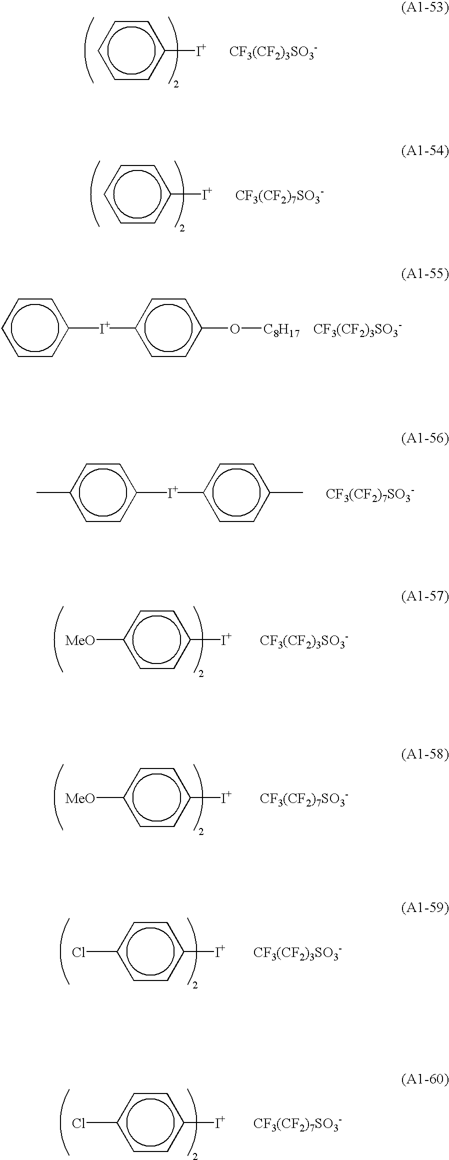

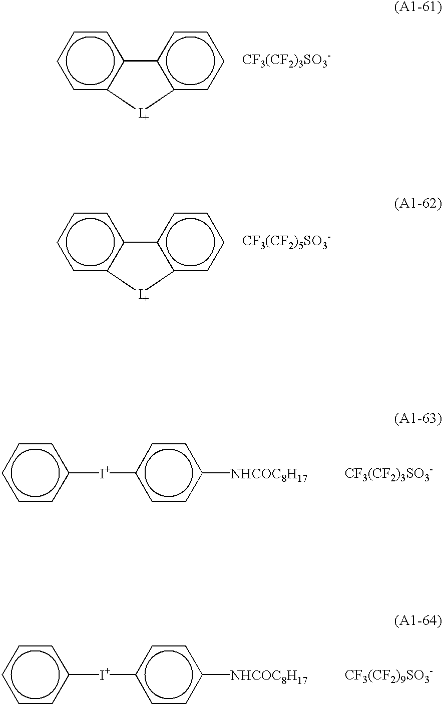

The following four groups of compounds are also used as preferred acid generators.

(1) Oxazole derivatives and s-triazine derivatives having a trihalomethyl group, represented by formulae (PAG1) and (PAG2), respectively.

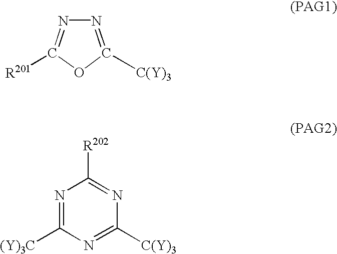

wherein R²⁰¹ represents a substituted or unsubstituted aryl group or a substituted or unsubstituted alkenyl group; R²⁰² represents a substituted or unsubstituted aryl group, a substituted or unsubstituted alkenyl group, a substituted or unsubstituted alkyl group or —C(Y)₃; and Y represents a chlorine atom or a bromine atom.

Illustrative examples of the group (1) compounds are shown below.

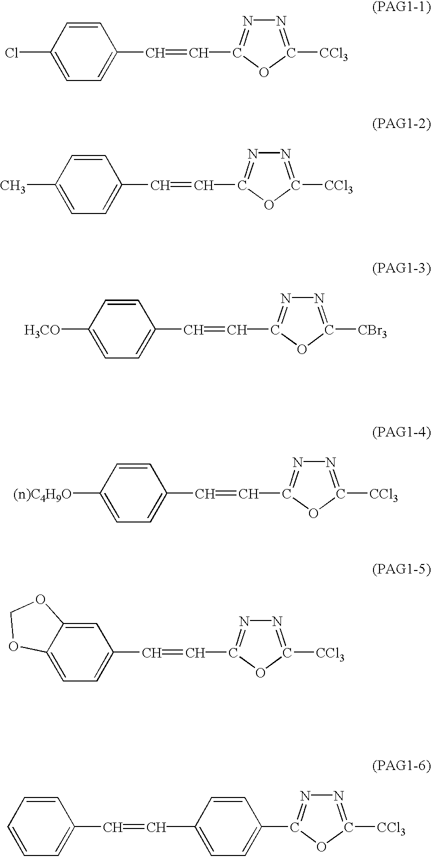

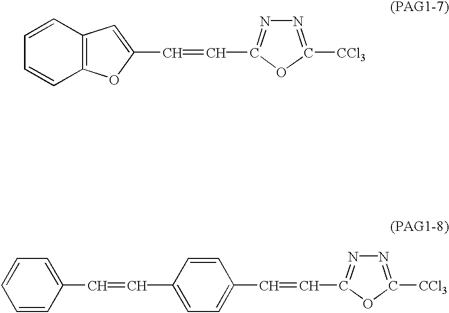

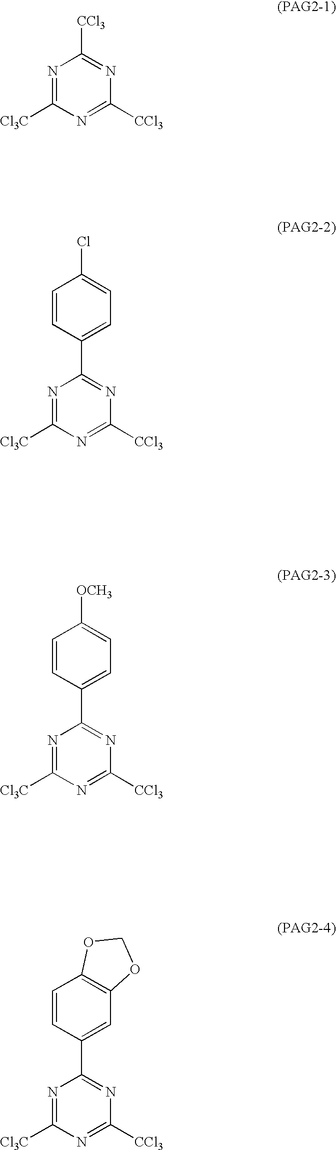

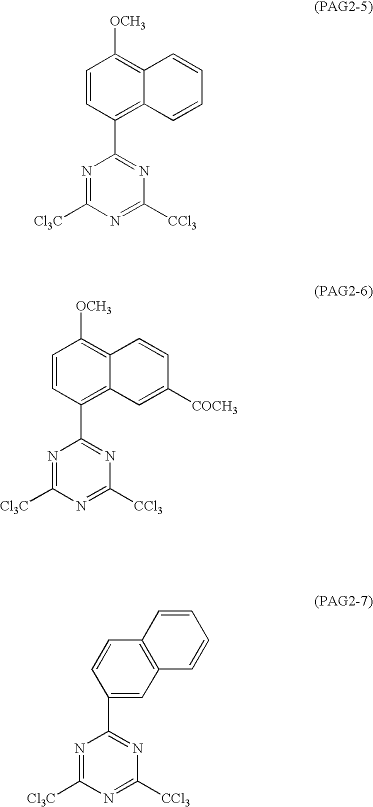

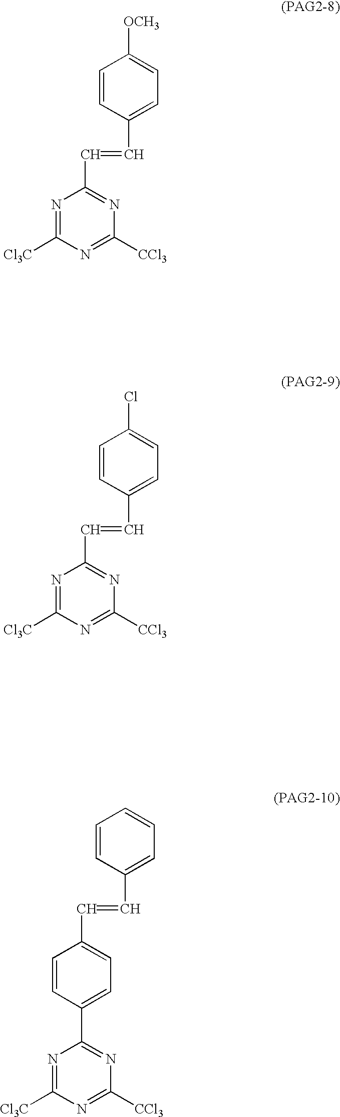

(2) Iodonium salts represented by formula (PAG3) and sulfonium salts represented by formula (PAG4):

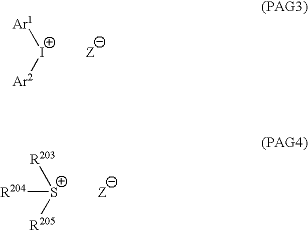

wherein Ar¹ and Ar² each represent a substituted or unsubstituted aryl group; R²⁰³, R²⁰⁴, and R²⁰⁵ each represent a substituted or unsubstituted alkyl group or a substituted or unsubstituted aryl group; Z⁻¹ represents a counter anion; Ar¹ and Ar² may be connected via a single bond or a substituent; and two out of R²⁰³, R²⁰⁴, and R²⁰⁵ may be connected via a single bond or a substituent.

The counter anion Z⁻¹ includes, but is not limited to, BF₄⁻, AsF₆⁻, PF₆⁻, SbF₆⁻, SiF₆⁻, ClO₄⁻, perfluoroalkanesulfonate anions (e.g., CF₃SO₃⁻), pentafluorobenzenesulfonate anion, condensed polynucleic aromatic sulfonate anions (e.g., naphthalene-1-sulfonate anion, antnraquinonesulfonate anion, and sulfonic group-containing dye anions.

Illustrative examples of the group (2) compounds are shown below.

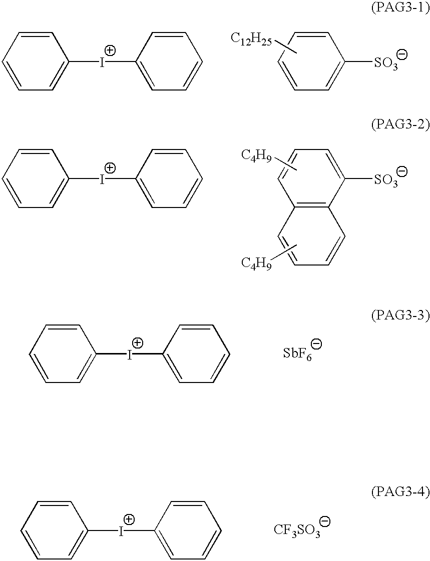

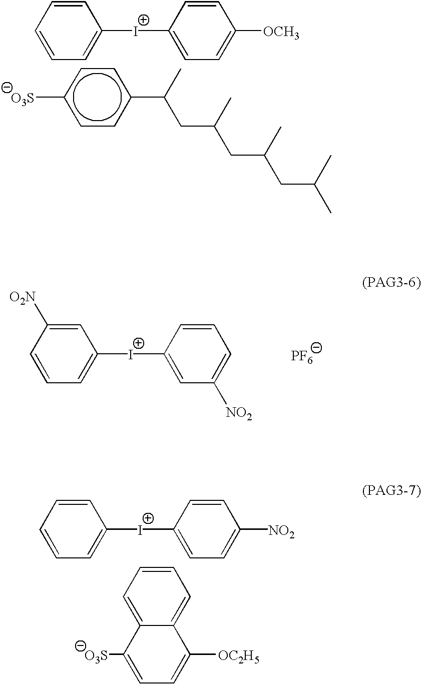

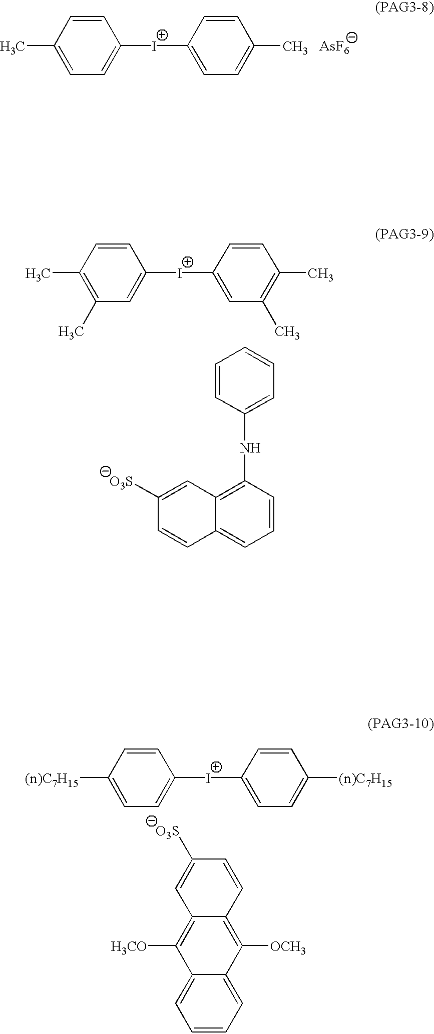

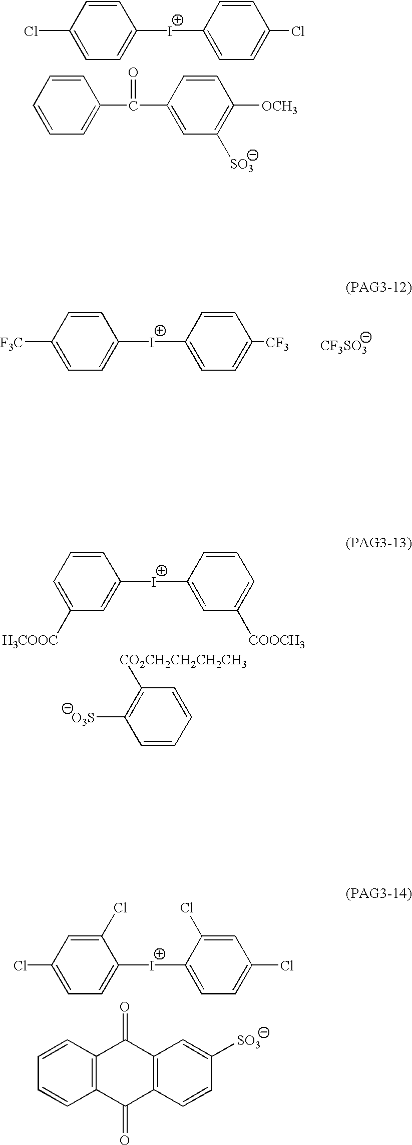

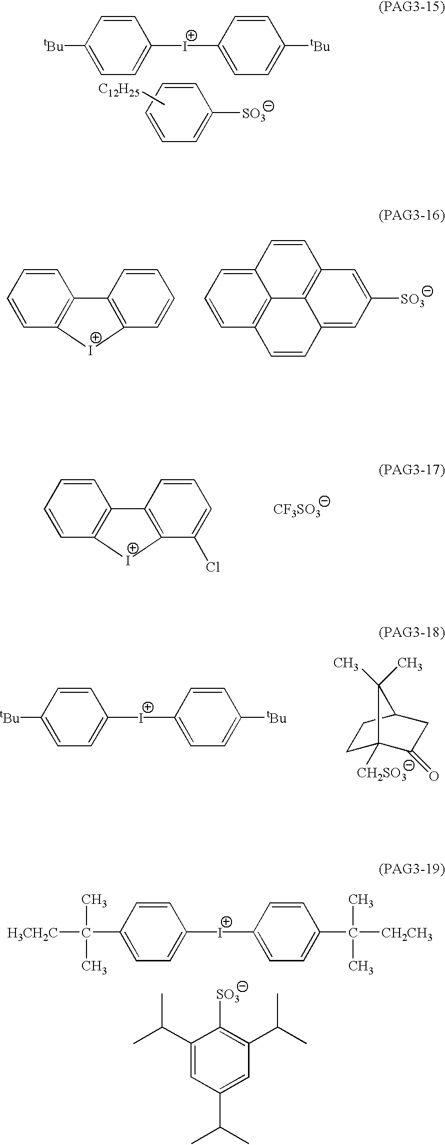

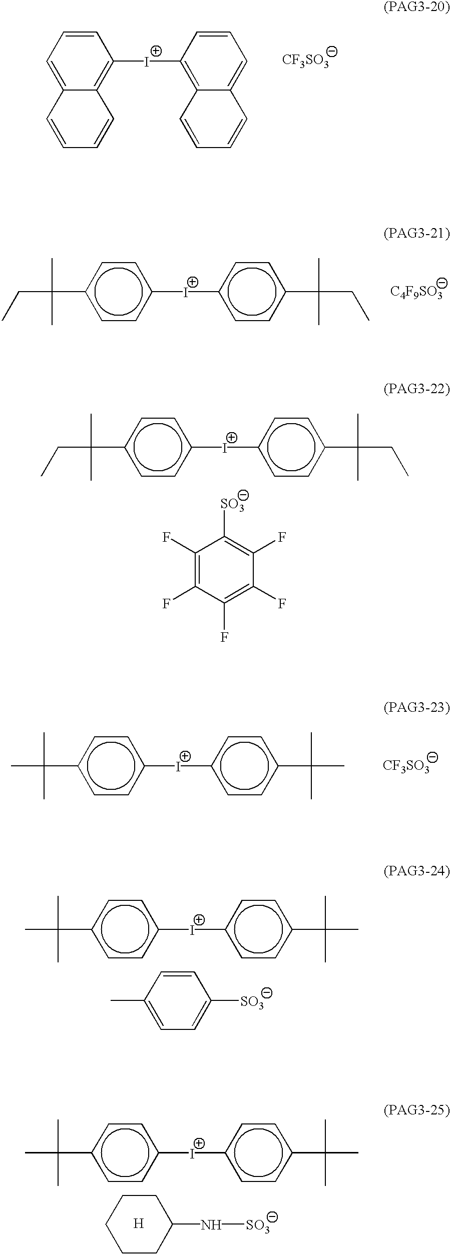

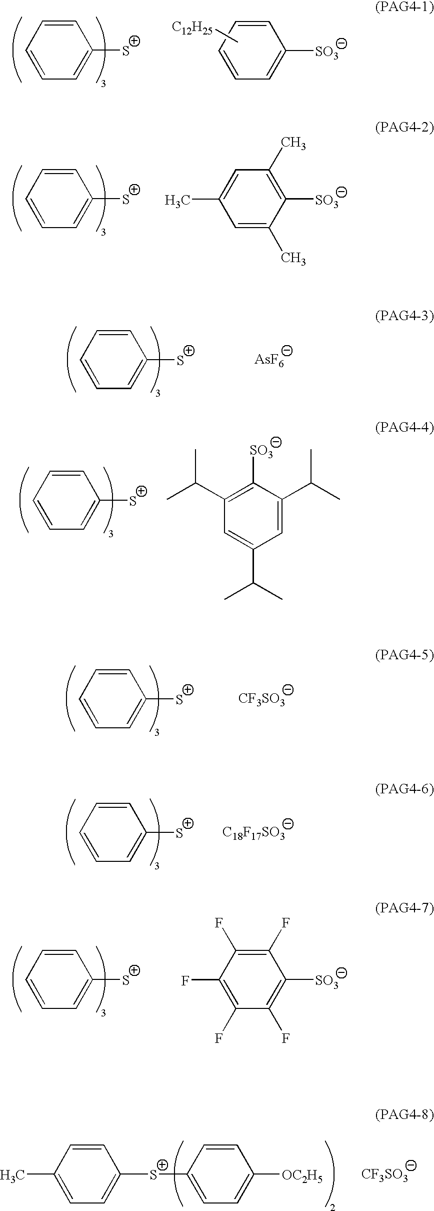

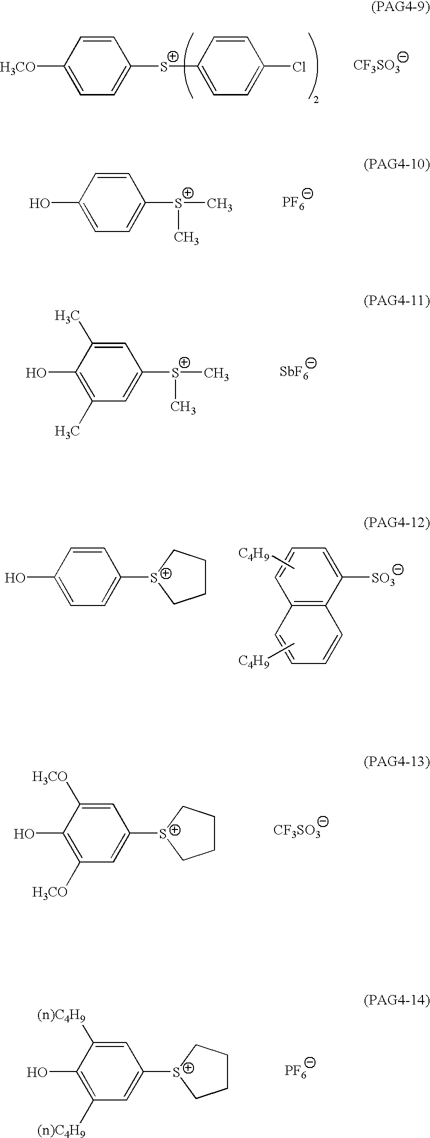

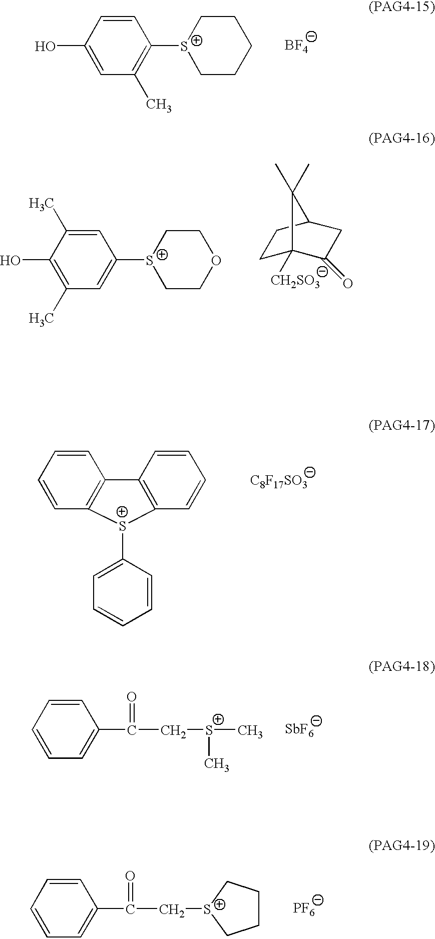

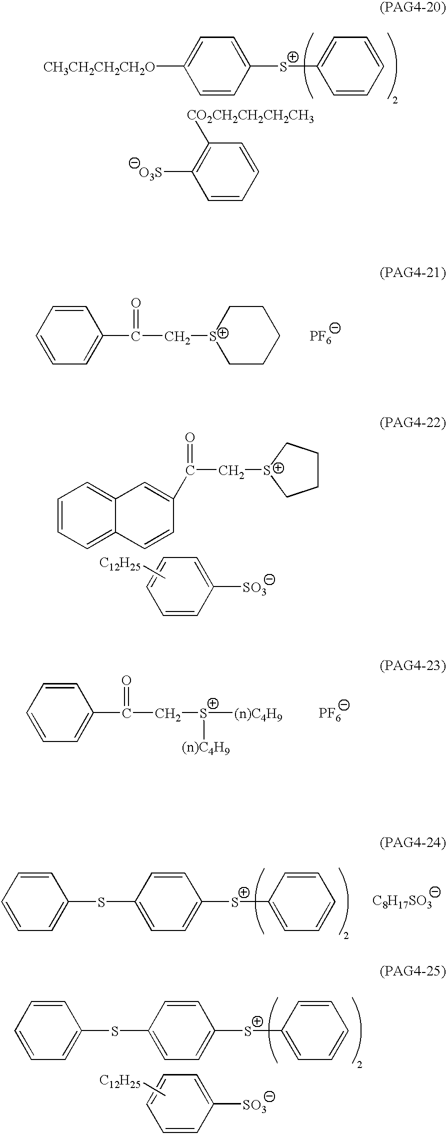

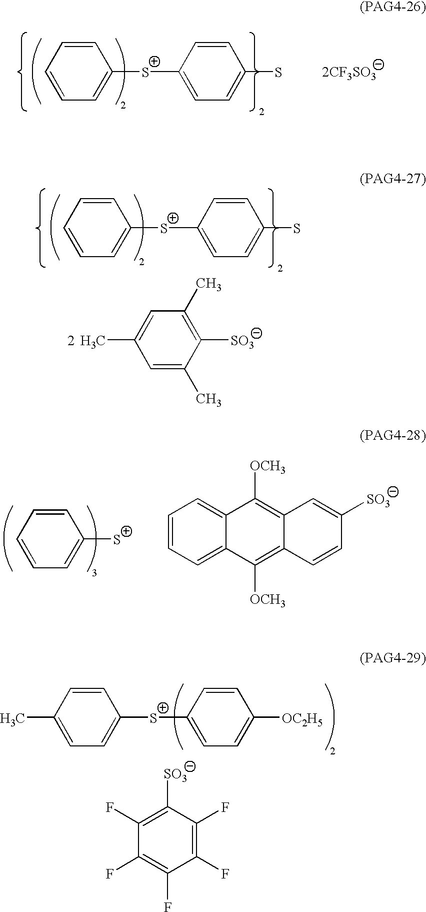

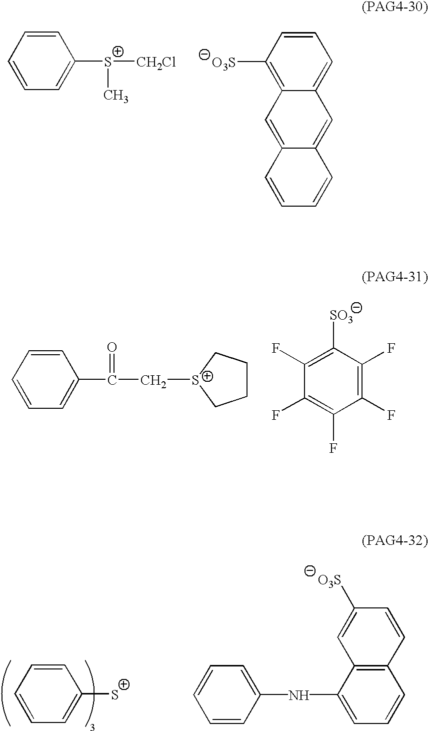

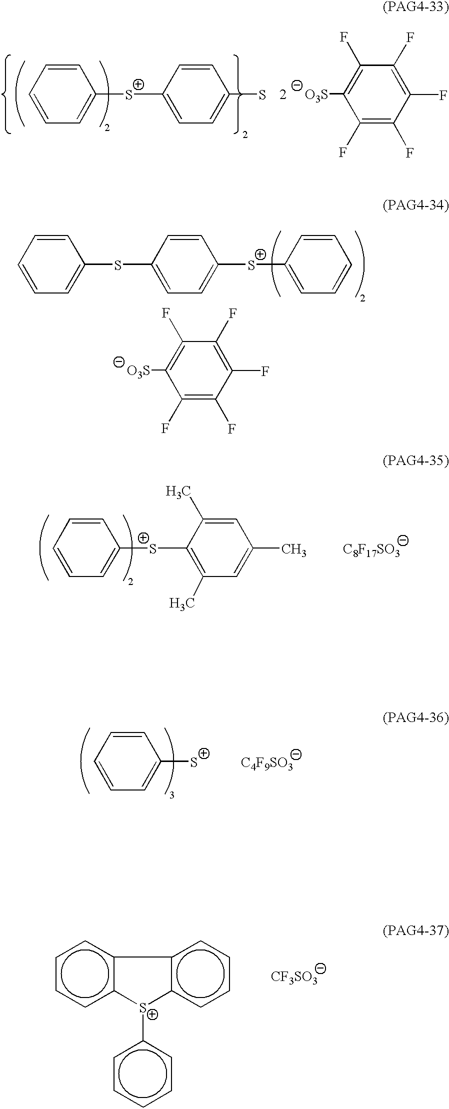

The onium salts represented by formulae (PAG3) and (PAG4) are known compounds, which can be synthesized by the processes taught in U.S. Pat. Nos. 2,807,648 and 4,247,473 and JP-A-53-101331.

(3) Disulfone derivatives represented by formula (PAG5) and iminosulfonate derivatives represented by formula (PAG6):

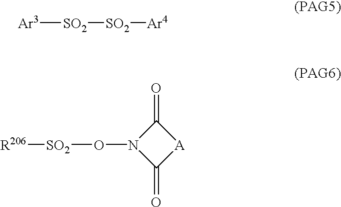

wherein Ar³ and Ar⁴ each represent a substituted or unsubstituted aryl group; R²⁰⁶ represents a substituted or unsubstituted alkyl group or a substituted or unsubstituted aryl group; and A represents a substituted or unsubstituted alkylene group, a substituted or unsubstituted alkenylene group or a substituted or unsubstituted arylene group.

Illustrative examples of the group (3) compound are listed below.

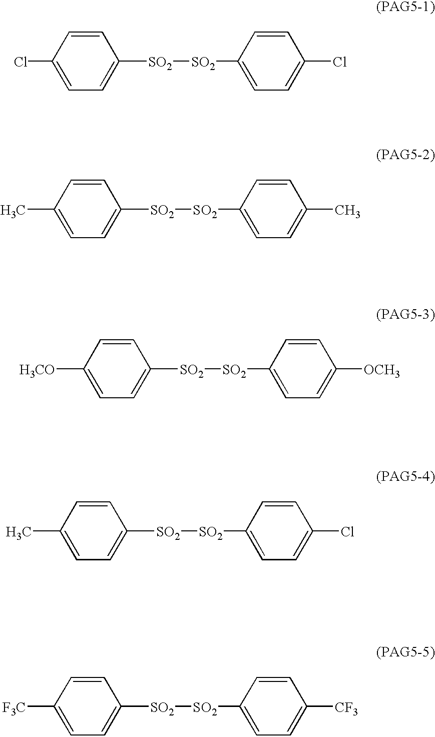

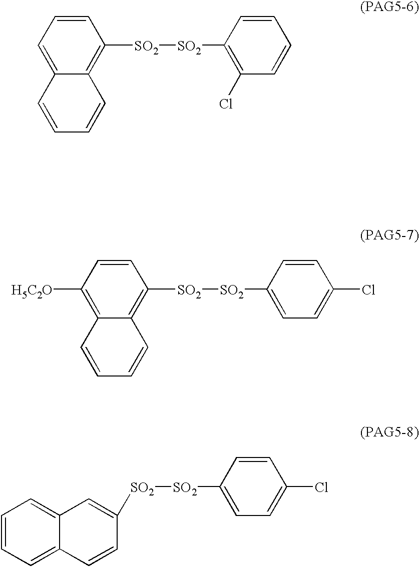

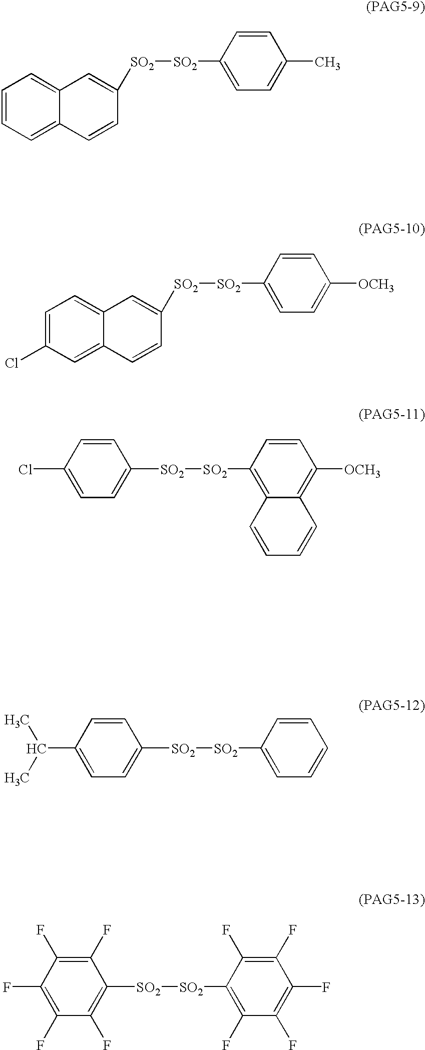

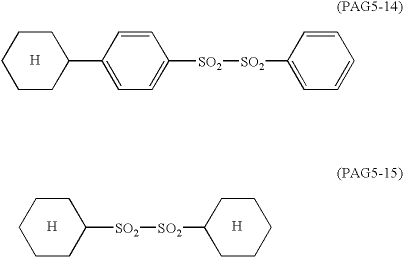

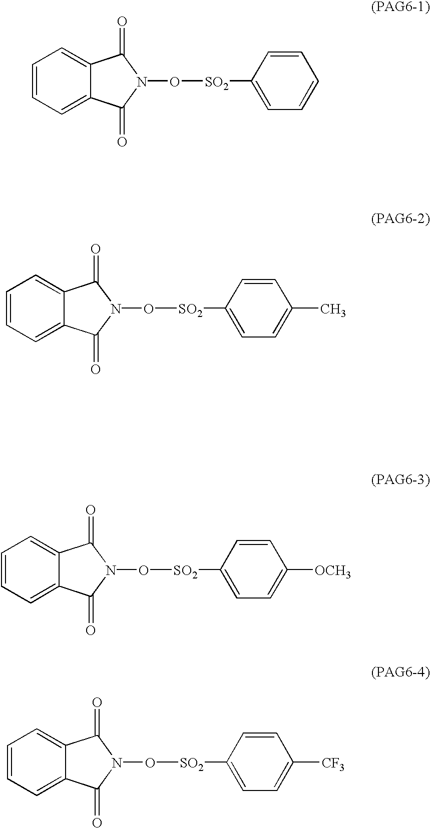

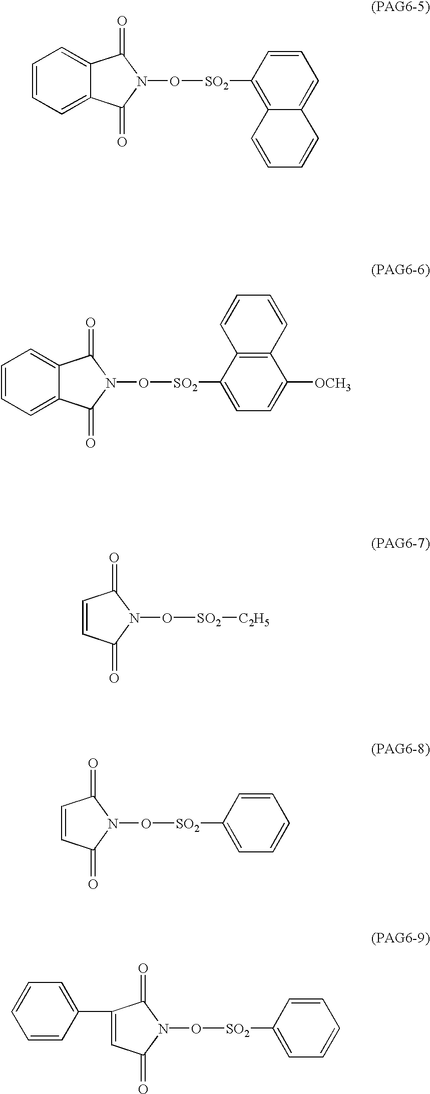

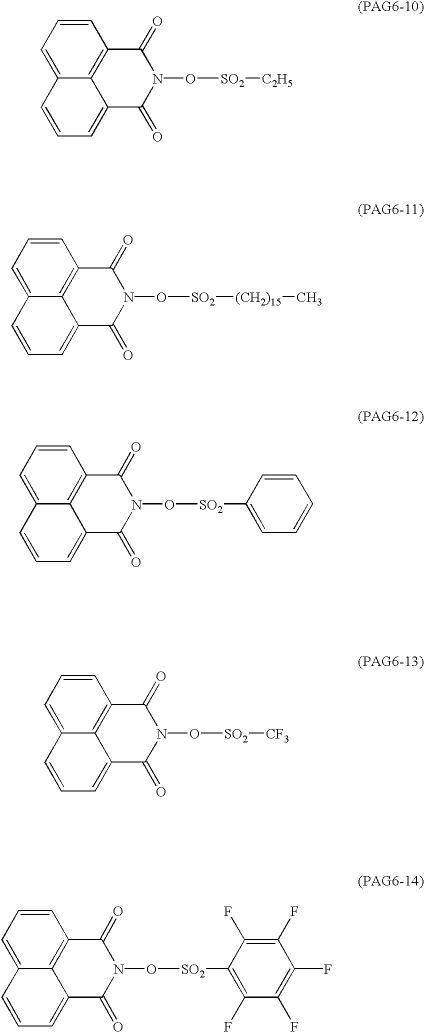

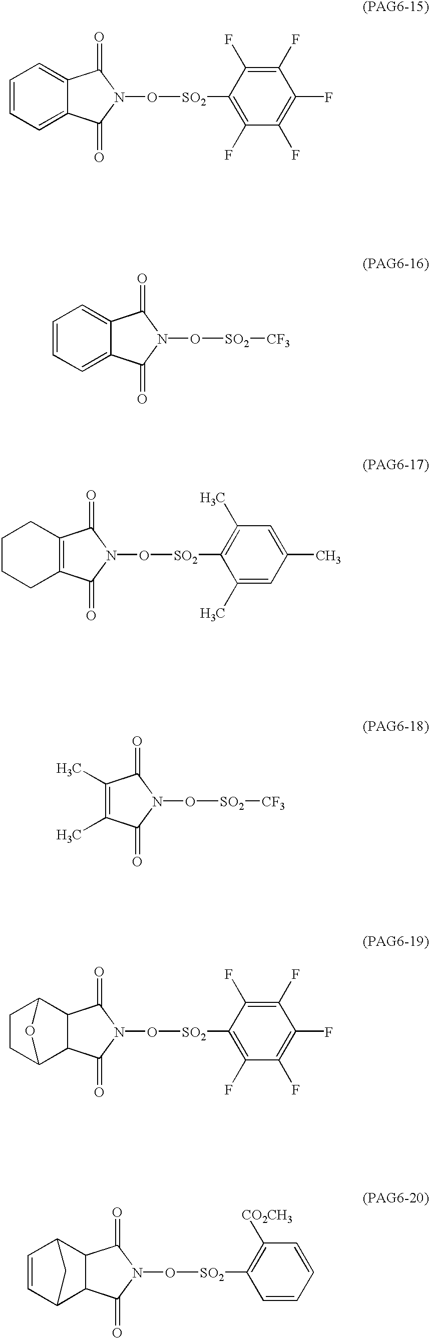

(4) Diazodisulfone derivatives represented by formula (PAG7):

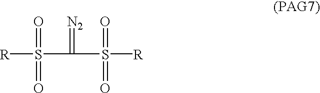

wherein R represents a straight-chain, branched or cyclic alkyl group or a substituted or unsubstituted aryl group.

Illustrative examples of the group (4) compounds are shown below.

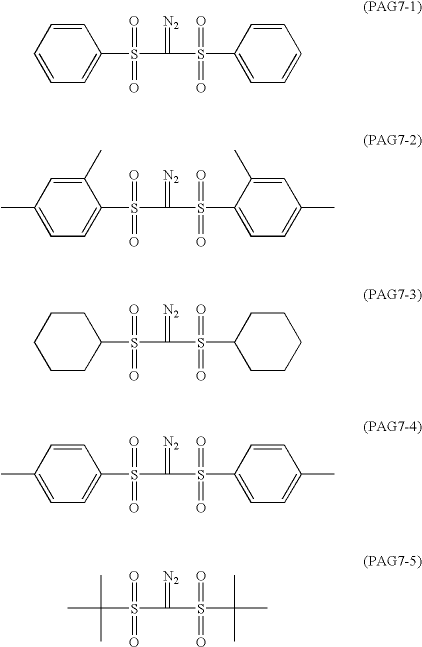

The acid generator as component (A) is usually used in an amount of 0.001 to 40% by weight, preferably 0.01 to 20% by weight, still preferably 0.1 to 5% by weight, based on the solids content of the total composition. Amounts of the acid generator less than 0.001% result in reduced sensitivity. Amounts exceeding 40% can result in deteriorated resist profile and narrowed process latitude especially in baking.

The resin soluble in an aqueous alkali solution (hereinafter simply referred to as an alkali-soluble resin) which can be used as component (B) include a broad range of polymers having a phenol skeleton that have been proposed for use in chemically amplified negative resists, such as phenol novolak resins, polyvinyl phenol resins, copolymers having a repeating unit derived from vinylphenol, and partially-protected or modified polyvinyl phenol resins.

The alkali-soluble resin as component (B) is preferably a resin comprising a repeating unit represented by formula (a):

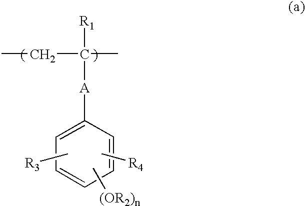

wherein R₁ represents a hydrogen atom, a halogen atom, a cyano group, a substituted or unsubstituted alkyl group or a substituted or unsubstituted haloalkyl group; R₂ represents a hydrogen atom, a substituted or unsubstituted alkyl group, a substituted or unsubstituted cycloalkyl group, a substituted or unsubstituted aryl group, a substituted or unsubstituted aralkyl group or a substituted or unsubstituted acyl group; R₃ and R₄, which may be the same or different, each represent a hydrogen atom, a halogen atom, a cyano group, a substituted or unsubstituted alkyl group, a substituted or unsubstituted cycloalkyl group, a substituted or unsubstituted alkenyl group, a substituted or unsubstituted aralkyl group or a substituted or unsubstituted aryl group; A represents a single bond, a substituted or unsubstituted alkylene group, a substituted or unsubstituted alkenylene group, a substituted or unsubstituted cycloalkylene group, a substituted or unsubstituted arylene

group, —O—, —SO₂—, —O—CO—R₅—, —CO—O—R₆— or —CO—N(R₇)—R₈—; R₅, R₆, and R₈ each represent a single bond, a substituted or unsubstituted alkylene group, a substituted or unsubstituted alkenylene group, a substituted or unsubstituted cycloalkylene group, a substituted or unsubstituted arylene group, or a divalent linking group made up of at least one of these divalent groups and at least one member selected from the group consisting of an ether structure, an ester structure, an amide structure, a urethane structure, and a ureido structure; R₇ represents a hydrogen atom, a substituted or unsubstituted alkyl group, a substituted or unsubstituted cycloalkyl group, a substituted or unsubstituted aralkyl group or a substituted or unsubstituted aryl group; n represents an integer of 1 to 3; when n is 2 or 3, two R₂'s may be taken together to form a ring; and R₂ and R₃ or R₄ may be taken together to form a ring.

The alkali-soluble resin as component (B) is still preferably a phenol resin comprising the repeating unit represented by formula (a).

The alkyl groups as represented by R₁, R₂, R₃, R₄, and R₇ preferably include those having 1 to 8 carbon atoms, such as methyl, ethyl, propyl, n-butyl, sec-butyl, hexyl, 2-ethylhexyl, and octyl. The cycloalkyl groups as R₂, R₃, R₄, and R₇ are either monocyclic or polycyclic. Monocyclic ones preferably include those having 3 to 8 carbon atoms, such as cyclopropyl, cyclopentyl, and cyclohexyl. Polycyclic ones preferably include adamantyl, norbornyl, isobornyl, dicyclopentyl, α-pinenyl, and tricyclodecanyl.

The alkenyl groups as R₃ and R₄ preferably include those containing 2 to 8 carbon atoms, such as vinyl, allyl, butenyl and cyclohexenyl.

The aryl groups as R₂, R₃, R₄, and R₇ preferably include those containing 6 to 15 carbon atoms, such as phenyl, tolyl, dimethylphenyl, 2,4,6-trimethylphenyl, naphthyl, and anthryl.

The aralkyl groups as R₂, R₃, R₄, and R₇ preferably include those containing 7 to 12 carbon atoms, such as benzyl, phenethyl or naphthylmethyl.

The haloalkyl group as R, preferably includes one containing 1 to 4 carbon atoms, such as chloromethyl, chloroethyl, chloropropyl, chlorobutyl, bromomethyl or bromoethyl.

The acyl group as R₂ preferably includes one containing 1 to 8 carbon atoms, such as formyl, acetyl, propanoyl, butanoyl, pivaroyl or benzoyl.

The alkylene groups as A, R₅, R₆, and R₈ preferably include substituted or unsubstituted ones containing 1 to 8 carbon atoms, such as methylene, ethylene, propylene, butylene, hexylene and octylene.

The alkenylene groups as A, R₅, R₆, and Re preferably include substituted or unsubstituted ones containing 2 to 6 carbon atoms, such as ethenylene, propenylene and butenylene.

The cycloalkylene groups as A, R₅, R₆, and R₈ preferably include substituted or unsubstituted ones containing 5 to 8 carbon atoms, such as cyclopentylene and cyclohexylene.

The arylene groups as A, R₅, R₆, and R₈ preferably include those containing 6 to 12 carbon atoms, such as phenylene, tolylene or naphthylene.

The substituents the above-enumerated groups may have include active hydrogen-containing groups, such as an amino group, an amido group, a ureido group, a urethane group, a hydroxyl group, and a carboxyl group, a halogen atom (e.g., fluorine, chlorine, bromine or iodine), an alkoxy group (e.g., methoxy, ethoxy, propoxy or butoxy), a thioether group, an acyl group (e.g., acetyl, propanoyl or benzoyl), an acyloxy group (e.g., acetoxy, propanoyloxy or benzoyloxy), an alkoxycarbonyl group (e.g., methoxycarbonyl, ethoxycarbonyl or propoxycarbonyl), a cyano group, and a nitro group. Preferred of them are those having active hydrogen, such as an amino group, a hydroxyl group, and a carboxyl group.

The ring formed between a plurality of R₂'s or between R₂ and R₃ or R₄ includes an oxygen-containing 4- to 7-membered ring, such as a benzofuran ring, a benzodioxonol ring or a benzopyran ring.

The alkali-soluble resin (B) includes a homopolymer made solely of the repeating unit of formula (a) and a copolymer comprising the repeating unit of formula (a)- and a repeating unit derived from a copolymerizable monomer which contributes to further improvement of resist performance.

Usable copolymerizable monomers include compounds having one addition-polymerizable unsaturated bond other than those providing the unit of formula (a), such as acrylic esters, acrylamides, methacrylic esters, methacrylamides, allyl compounds, vinyl ethers, vinyl esters, styrenes, and crotonic esters.

Preferred copolymerizable monomers include those effective in improving alkali solubility, such as carboxyl-containing monomers, e.g., carboxystyrene, N-(carboxyphenyl)acrylamide, and N-(carboxyphenyl)methacrylamide, and maleimide.

The comonomer unit content in the resin (B) is preferably not more than 50 mol %, still preferably 30 mol % or less, based on the total repeating units.

Illustrative examples of the alkali-soluble resin (B) having the repeating unit of formula (a) are shown below.

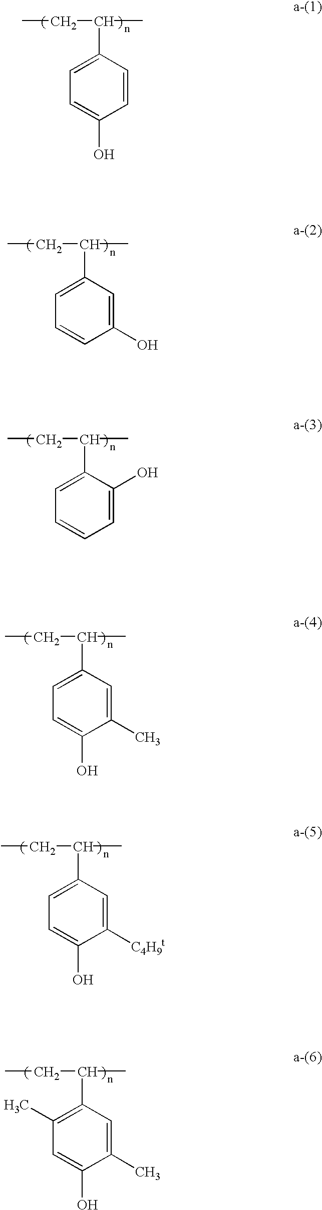

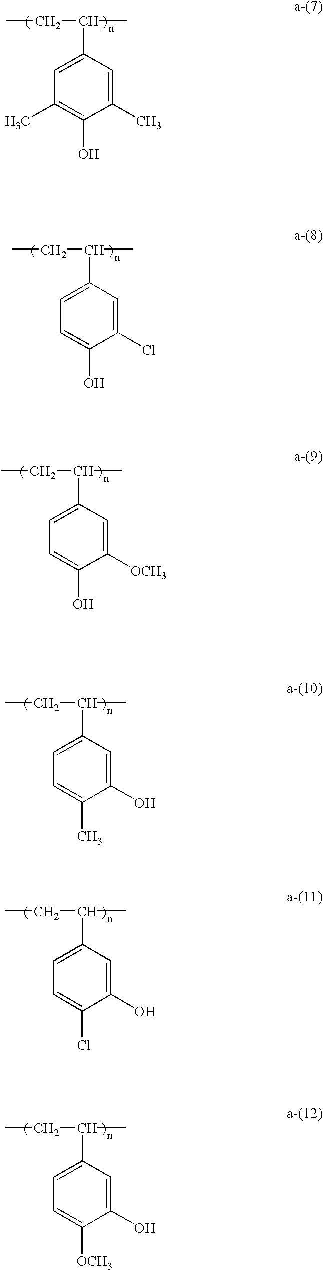

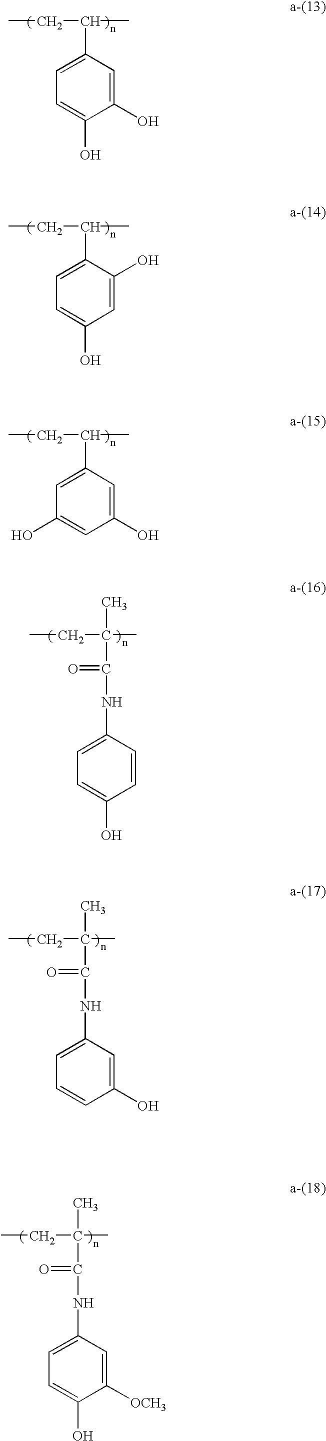

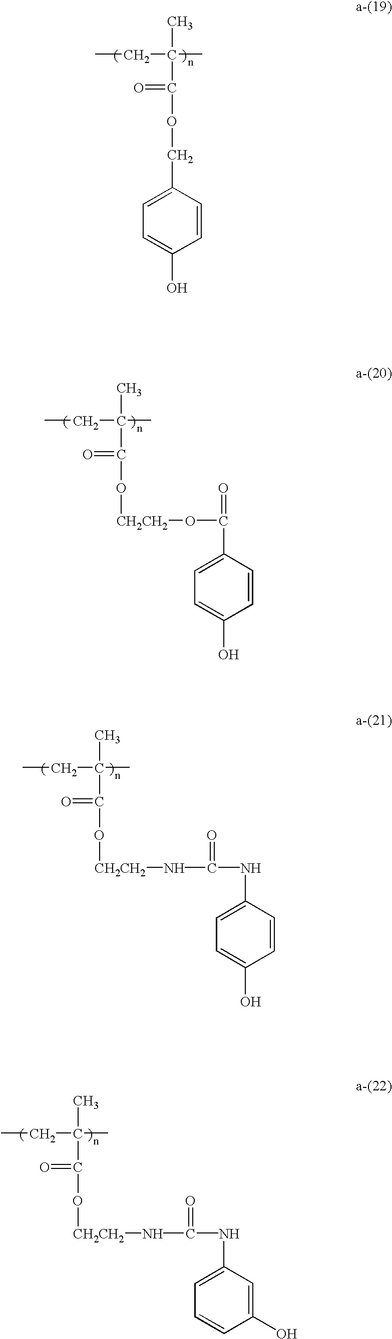

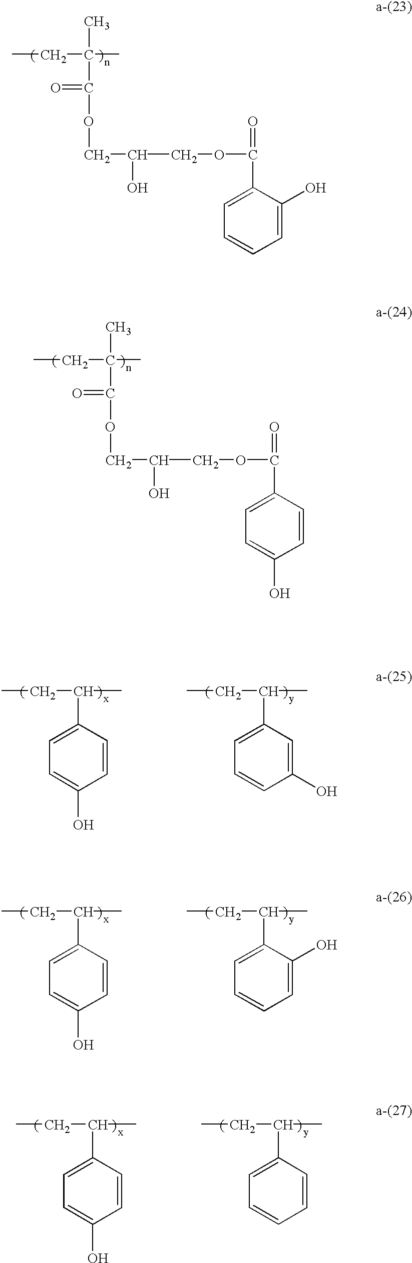

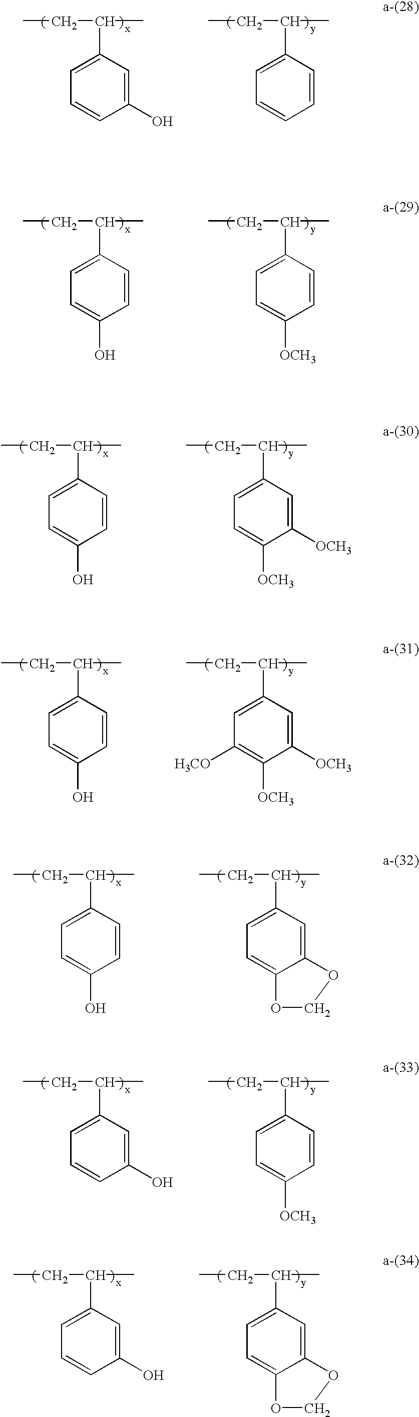

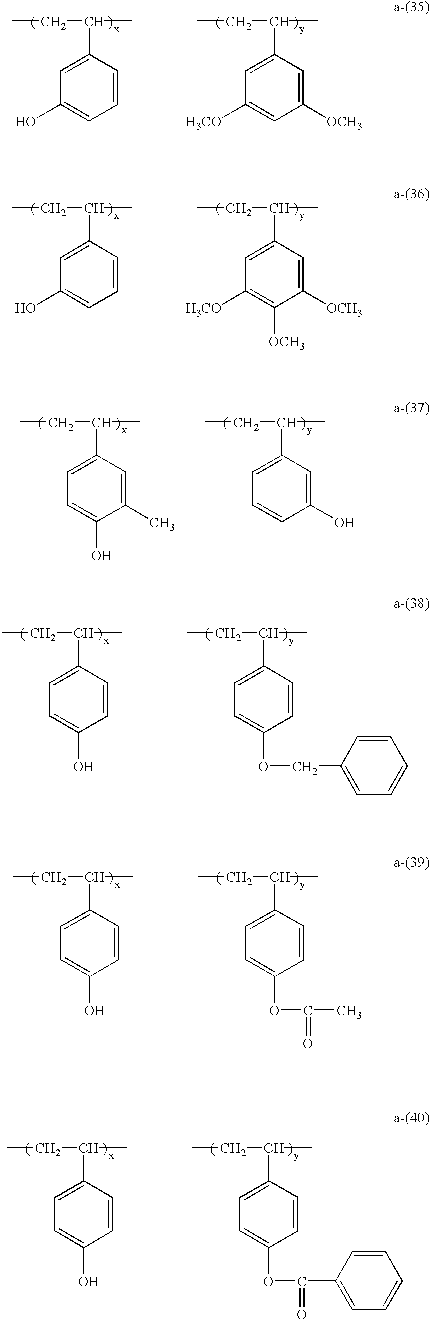

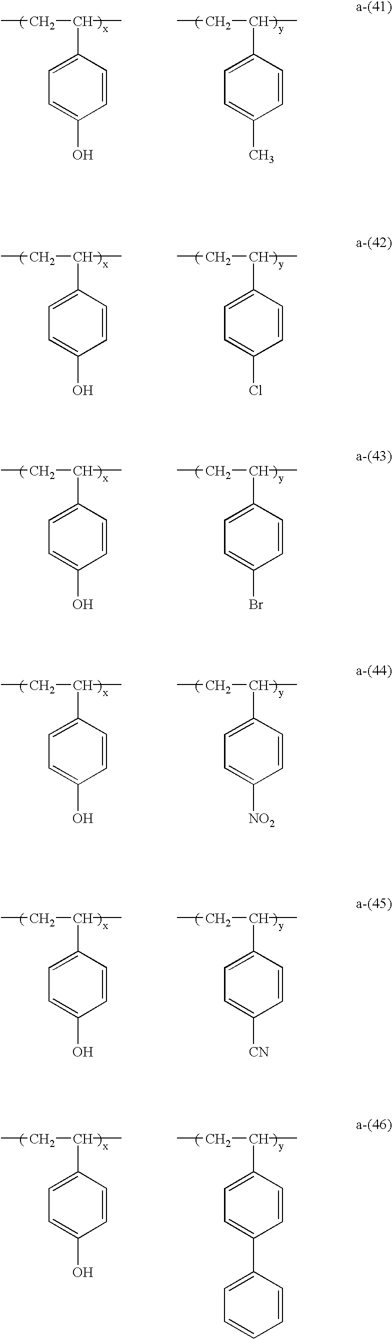

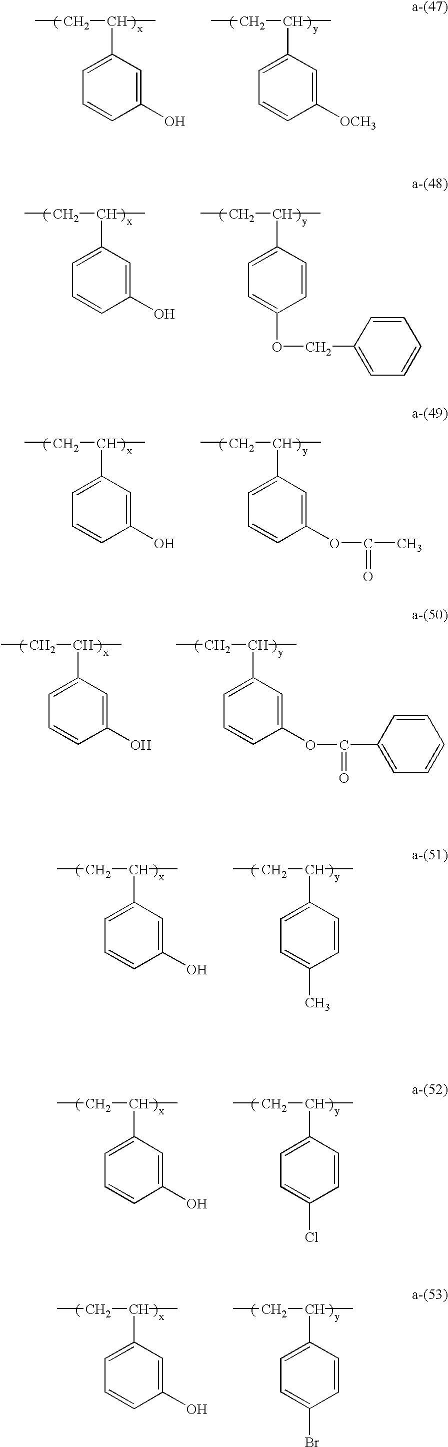

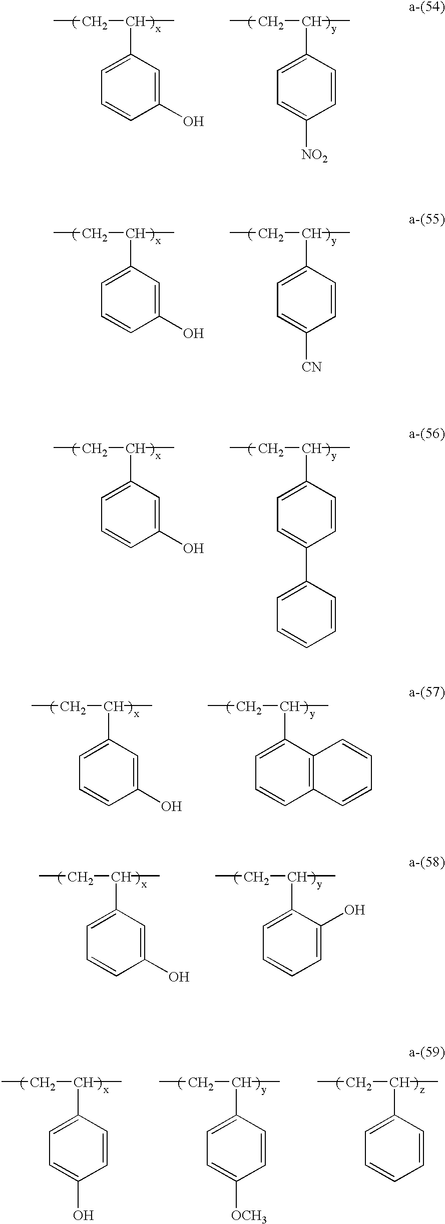

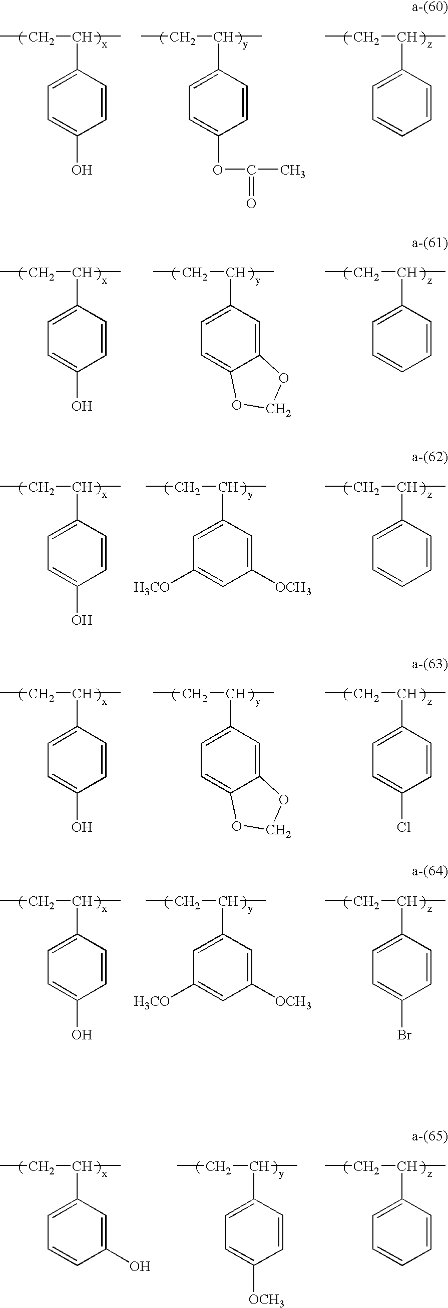

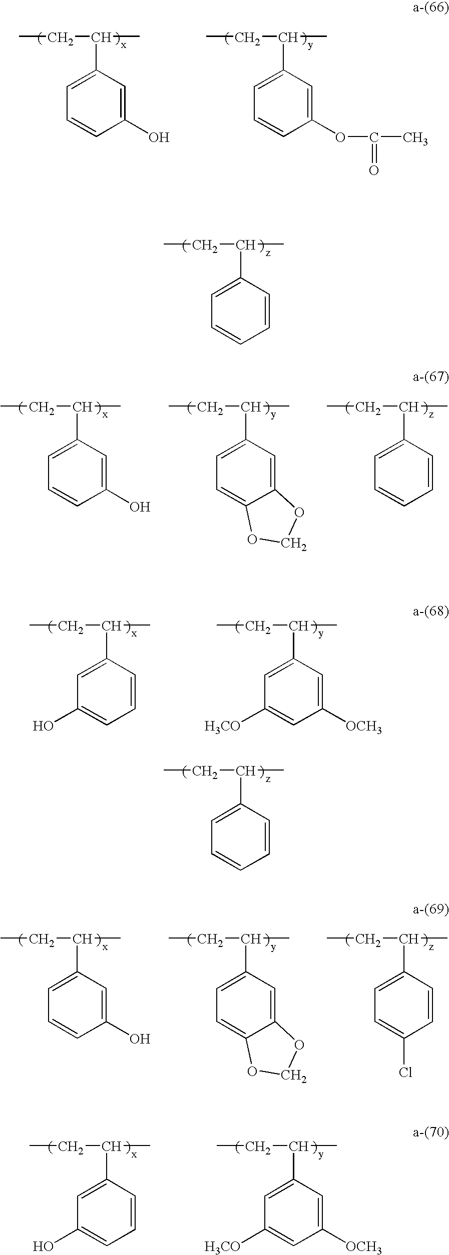

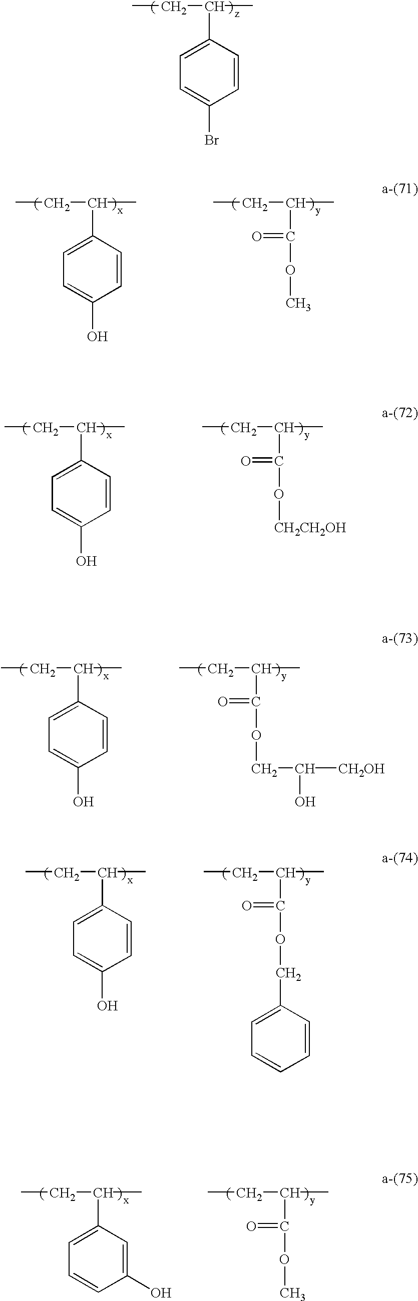

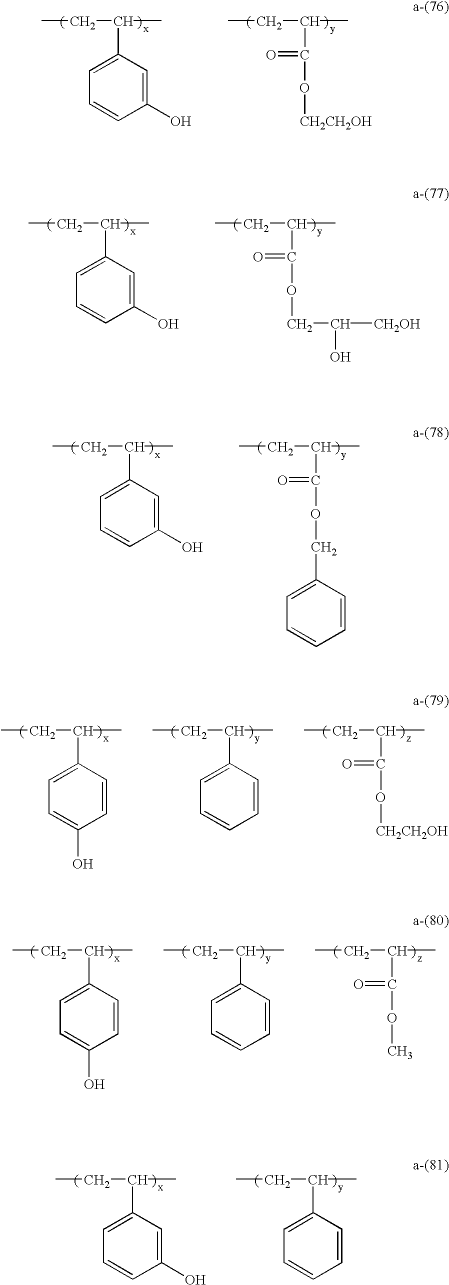

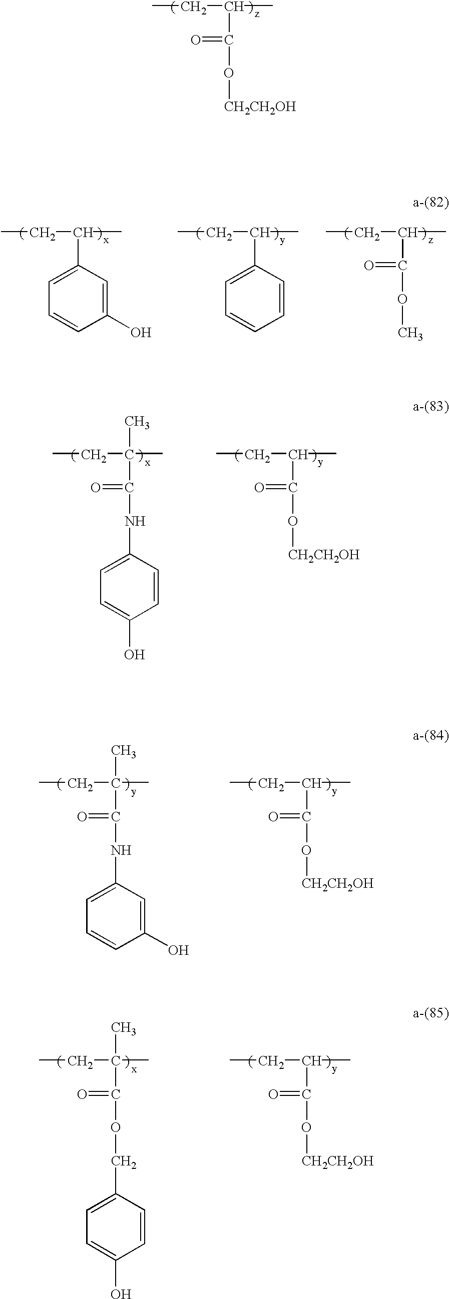

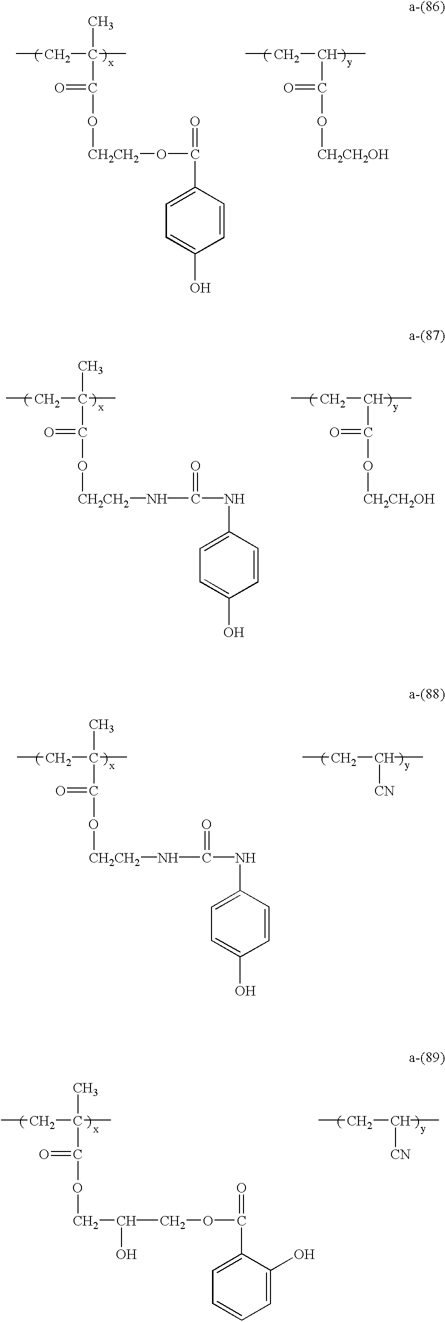

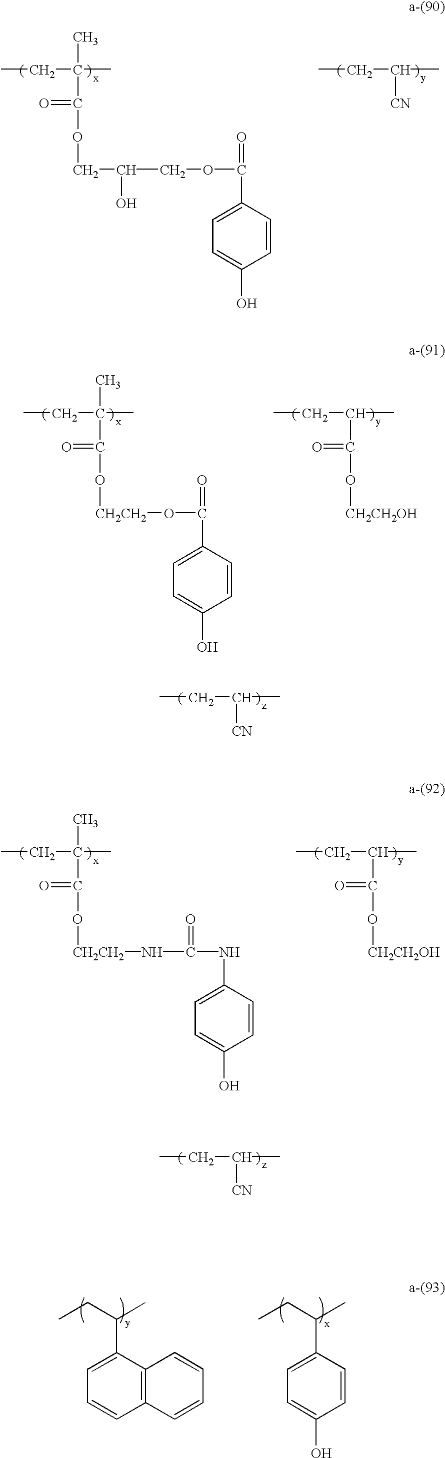

In the formulae given above, n represents a positive integer, and x, y, and z represent a molar ratio of the respective units. In two-component copolymers, x=10 to 95, preferably 40 to 90, and y=5 to 90, preferably 10 to 60. In three-component copolymers, x=10 to 90, y=5 to 85, and z=5 to 85, preferably x=40 to 80, y=10 to 50, and z=10 to 50.

The alkali-soluble resin (B), preferably the resin having the repeating unit of formula (a) preferably has a weight average molecular weight of 1,000 to 200,000, particularly 3,000 to 50,000, and a molecular weight distribution (weight average molecular weight/number average molecular weight) of 1 to 10, particularly 1 to 3, especially 1 to 1.5. With a smaller molecular weight distribution, the resin provides a resist film with higher performance in resolution, profile, smoothness of side wall of resist pattern, and reduced line edge roughness.

The total content of the repeating units represented by formula (a) is 5 to 100 mol %, preferably 10 to 90 mol %, based on the total resin.

The alkali-soluble resin having the repeating unit of formula (a) is synthesized by radical polymerization or living anionic polymerization according to the processes disclosed in Macromolecules, 1995, 28(11), 3787-3789, Polym. Bull. (Berlin), 1990, 24(4), 385-389, and JP-A-8-286375. The alkali-soluble resins comprising the repeating unit of formula (a) can be used either individually or a mixture of two or more thereof.

The weight average molecular weight of the resin as referred to in the present invention is a polystyrene equivalent molecular weight as measured by gel-permeation chromatography (GPC).

It is preferred for the alkali-soluble resin to have an alkali dissolution rate of 20 A/sec or higher, particularly 200 A/sec or higher, as measured in a 0.261N tetramethylammonium hydroxide (TMAH) developing solution at 23° C.

The alkali-soluble resin having the repeating unit of formula (a) can be used either alone or in combination with other alkali-soluble resins. In the latter case, the other alkali-soluble resin can be used in an amount of up to 100 parts by weight per 100 parts by weight of the alkali-soluble resin having the repeating unit of formula (a). The other alkali-soluble resins include, but are not limited to, novolak resins, hydrogenated novolak resins, acetone-pyrogallol resins, styrene-maleic anhydride copolymer resins, and carboxyl-containing methacrylic resins and their derivatives.

Alkali-soluble resins comprising a repeating unit represented by formula (b-2) or (b-3) are also preferred as component (B).

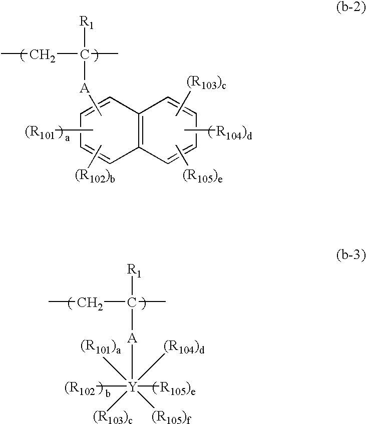

wherein R₁ and A are as defined above with respect to formula (a); R₁₀₁, R₁₀₂, R₁₀₃, R₁₀₄, R₁₀₅, and R₁₀₆ each represent a hydroxyl group, an alkyl group, an alkoxy group, an alkylcarbonyloxy group, an alkylsulfonyloxy group, an alkenyl group, an aryl group, an aralkyl group, a carboxyl group, an amino group, an N-alkylamino group or an N-dialkylamino group, wherein the alkyl group or moiety is straight-chain, branched or cyclic; a to f each represent an integer of 0 to 3; and Y represents a condensed polycyclic aromatic group derived from any one of the following structures:

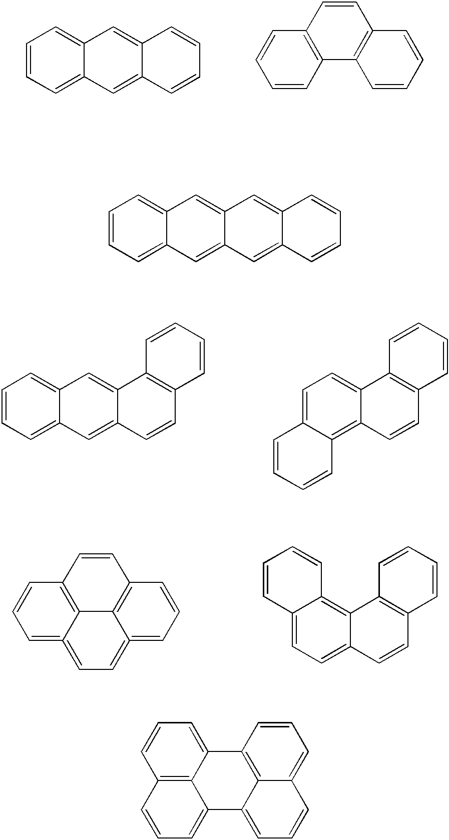

In formulae (b-2) and (b-3), the straight-chain or branched alkyl group or the straight-chain or branched alkyl moiety of the alkoxy group, the alkylcarbonyloxy group, the alkylsulfonyloxy group, the N-alkylamino group, and the N-dialkylamino group preferably includes methyl, ethyl, propyl, n-butyl, sec-butyl, hexyl, 2-ethylhexyl and octyl. The cyclic alkyl group or the cyclic alkyl moiety of the alkoxy group, the alkylcarbonyloxy group, the alkylsulfonyloxy group, the N-alkylamino group, and the N-dialkylamino group preferably includes monocyclic ones, such as cyclopropyl, cyclopentyl, and cyclohexyl; and polycyclic ones, such as adamantyl, norbornyl, isobornyl, dicyclopentyl, α-pinenyl, and tricyclodecanyl.

The alkenyl group preferably includes vinyl, allyl, butenyl, and cyclohexenyl.

The aryl group preferably includes phenyl, tolyl, dimethylphenyl, 2,4,6-trimethylphenyl, naphthyl, and anthryl.

The aralkyl group preferably includes benzyl, phenethyl, and naphthylmethyl.

In the condensed polycyclic aromatic structures shown above, from which Y is derived, the positions of the bonds to the main chain and to the substituents are arbitrary.

The content of the repeating unit of formulae (b-2) and/or (b-3) in the alkali-soluble resin is preferably 3 to 50 mol %, still preferably 5 to 40 mol %, based on the total repeating units.

Illustrative examples of the alkali-soluble resin having the repeating unit of formulae (b-2) and/or (b-3) are shown below.

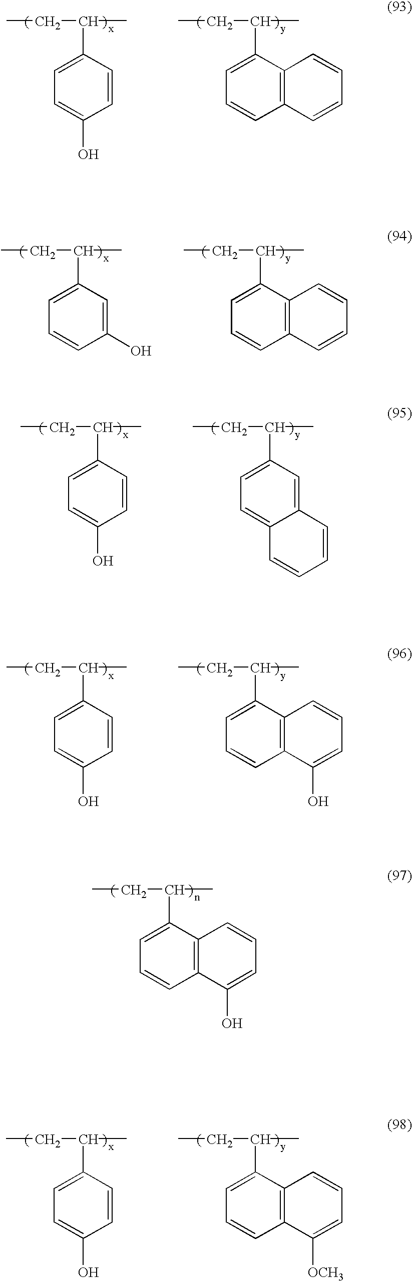

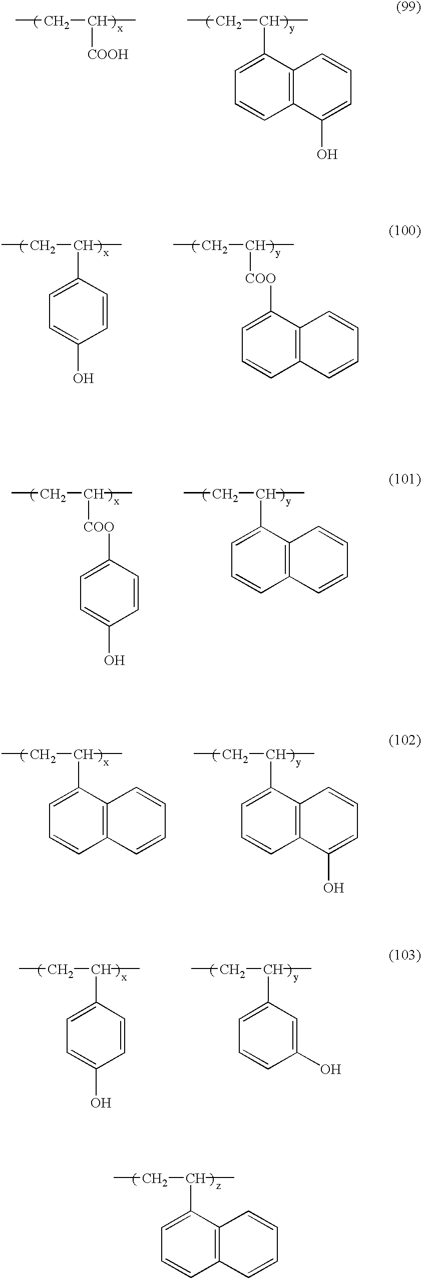

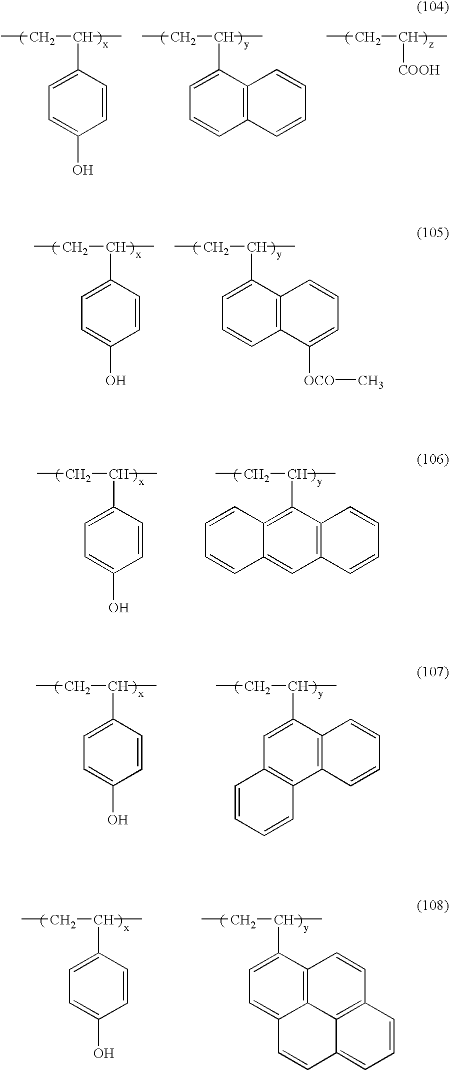

The alkali-soluble resin as component (B) is preferably used in an amount of 30 to 95% by weight, particularly 40 to 90% by weight, especially 50 to 80% by weight, based on the total solids content of the resist composition.

Component (C) of the negative resist composition of the invention is a compound having an alcohol structure which is excited by the acid generated by component (A) to reduce the alkali solubility of a resist film formed of the negative resist composition (hereinafter referred to as a compound (C)). The compound (C) is preferably a compound which undergoes addition and/or polarity conversion by the action of an acid generated by component (A). The term “addition” as referred to here means a reaction between a reactive group and other reactive site to form a new covalent bond. The term “polarity conversion” as applied to the present invention means conversion of a site having a dissolution accelerating action in an aqueous alkali solution, such as a hydroxyl group, to a site having a dissolution inhibitory action in an aqueous alkali solution, such as a double bond or an ion-containing site. When such polarity conversion occurs, the compound (C) comes to inhibit the resist film from dissolving in an aqueous alkali developing solution.

Compounds which predominantly undergo addition preferably include alicyclic tertiary alcohols. The compounds disclosed in JP-A-2000-249455, JP-A-2001-154357, JP-A-2001-24956, DE 10043678A1, JP-A-11-295885, and US 2001-0006752A1 are particularly suitable.

Compounds which predominantly undergo polarity conversion preferably include secondary or tertiary alcohols having a hydroxyl group on a carbon atom directly bonded to the aromatic ring thereof, particularly tertiary alcohol compounds having a hydroxyl group on a carbon atom directly bonded to their aromatic ring.

The compounds (C) preferably include those represented by formulae (C-1), (C-2), (C-3), (C-4), and (C-5):

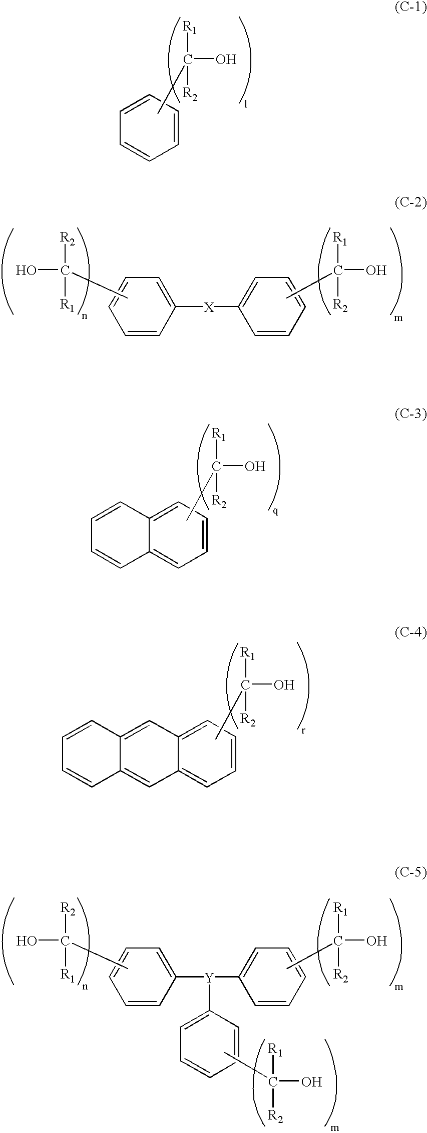

wherein R₁ represents a hydrogen atom, a substituted or unsubstituted cyclic or acyclic alkyl group (preferably having 1 to 9 carbon atoms), a hydroxyl group, an acetoxy group or an alkoxy group (preferably having 1 to 6 carbon atoms); R₂ represents a substituted or unsubstituted cyclic or acyclic alkyl group (preferably having 1 to 9 carbon atoms); X represents a single bond, a substituted or unsubstituted straight-chain or branched alkylene group having 1 to 6 carbon atoms, a substituted or unsubstituted arylene group having 6 to 15 carbon atoms, —S—, —S (═O)—, —S(═O)₂—, —S—S—, —O—, —NH₂— or a combination thereof; Y represents CH, N or C(OH); 1 represents an integer of 1 to 4; m represents an integer of 0 to 3; n represents an integer of 1 to 3; q represents an integer of 1 to 4; and r represents an integer of 1 to 6.

The substituents the alkyl group as R₁ or R₂ may have include an acyl group having 2 to 6 carbon atoms, an amino group, an amido group, an imido group, a halogen atom, a halogen-substituted alkyl group, a halogen-substituted aryl group, an alkoxy group, an alkenyloxy group, an alkyl ester group, a hydroxyl group, a carboxyl group, a thiol group, a cyano group, a nitro group, a formyl group, a sulfonyl group, a sulfonamido group, an acyl group, and an acyloxy group.

Examples of R₁ are hydrogen, hydroxyl, methyl, ethyl, propyl, isopropyl, n-butyl, sec-butyl, t-butyl, hexyl, cyclopentyl, cyclohexyl, norbornyl, adamantyl, trifluoromethyl, methoxy, ethoxy, n-butoxy, sec-butoxy, t-butoxy, and acetoxy.

Examples of R₂ are methyl, ethyl, propyl, isopropyl, n-butyl, sec-butyl, t-butyl, hexyl, cyclopentyl, cyclohexyl, norbornyl, adamantyl, and trifluoromethyl.

The condensed ring which is not substituted with —C(R₁) (R₂)OH may have a substituent on its carbon.

The substituents that the alkylene or arylene group as X or the —C(R₁) (R₂)OH-unsubstituted condensed ring may have include an alkyl group having 1 to 20 carbon atoms, an aryl group having 6 to 20 carbon atoms, an alkenyl group having 2 to 10 carbon atoms, an aralkyl group having 7 to 15 carbon atoms, an alkoxy group having 1 to 20 carbon atoms, an acyl group having 2 to 20 carbon atoms, a primary aliphatic amino group, a secondary aliphatic amino group, a mixed amino group, an aromatic amino group, a heterocyclic amino group, an amido group, an imido group, a halogen atom, a halogen-substituted alkyl group, a halogen-substituted aryl group, an alkoxy group, an alkenyloxy group, an alkyl ester group, a heterocyclic group, a hydroxyl group, a carboxyl group, a thiol group, a cyano group, a nitro group, a formyl group, a sulfonyl group, a sulfonamido group, an acyl group, and an acyloxy group. These substituents are further described below.

The alkyl group preferably contains 1 to 20 carbon atoms, including methyl, ethyl, propyl, isopropyl, n-butyl, sec-butyl, t-butyl, pentyl, isopentyl, t-amyl, hexyl, heptyl, octyl, cyclopentyl, cyclohexyl, cycloheptyl, cyclopropylmethyl, 4-methylcyclohexyl, cyclohexymethyl, norbornyl, adamantyl, decanyl, lauryl, palmityl, and stearyl.

The aryl group preferably contains 6 to 20 carbon atoms, including phenyl, naphthyl, biphenyl, phenanthrenyl, anthranyl, fluorenyl, pyrenyl, alkoxyphenyl (e.g., p-methoxyphenyl, m-methoxyphenyl, o-methoxyphenyl, ethoxyphenyl, p-t-butoxyphenyl or m-t-butoxyphenyl), alkylphenyl (e.g., 2-methylphenyl, 3-methylphenyl, 4-methylphenyl, ethylphenyl, 4-t-butylphenyl, 4-butylphenyl or dimethylphenyl), alkylnaphthyl (e.g., methylnaphthyl or ethylnaphthyl), alkoxyanphthyl (e.g., methoxynaphthyl or ethoxynaphthyl), dialkylnaphthyl (e.g., dimethylnaphthyl or diethylnaphthyl), and dialkoxynaphthyl (e.g., dimethoxynaphtyl or diethoxynaphthyl).

The alkenyl group preferably contains 2 to 10 carbon atoms, including vinyl, allyl, propenyl, butenyl, hexenyl, and cyclohexyl.

The aralkyl group preferably has 7 to 15 carbon atoms, including benzyl and phenethyl.

Examples of the primary aliphatic amino group are amino, methylamino, ethylamino, n-propylamino, isopropylamino, n-butylamino, isobutylamino, sec-butylamino, t-butylamino, pentylamino, t-amylamino, cyclopentylamino, hexylamino, cyclohexylamino, heptylamino, octylamino, nonylamino, decylamino, dodecylamino, cetylamino, methylenediamino, ethylenediamino, and tetraethylenepentamino.

Examples of the secondary aliphatic amino group are dimethylamino, diethylamino, di-n-propylamino, diisopropylamino, di-n-butylamino, diisobutylamino, di-sec-butylamino, dipentylamino, dicyclopentylamino, dicyclohexylamino, diheptylamino, dioctylamino, dinonylamino, didecylamino, didodecylamino, and dicetylamino.

Examples of the aromatic amino group and the heterocyclic amino group (C- or N-substituted) include those derived from aniline derivatives (e.g., aniline, N-methylaniline, N-ethylaniline, N,N′-dimethylaniline, N,N′-diethylaniline, N-propylaniline, 2-methylaniline, 3-methylaniline, 4-methylaniline, and 2,6-dinitroaniline), diphenylamine, phenylenediamine, naphthylamine, diaminonaphthalene, pyrrole derivatives (e.g., pyrrole, 2H-pyrrole, 1-methylpyrrole, 2,4-dimethylpyrrole, 2,4-dimethylpyrrole, and 2,5-dimethylpyrrole), oxazole derivatives (e.g., oxazole and isoxazole), thiazole derivatives (e.g., thiazole and isothiazole), imidazole derivatives (e.g., imidazole, 4-methylimidazole, and 4-methyl-2-phenylimidazole), pyrazole derivatives, furazane derivatives, pyrroline derivatives (e.g., pyrroline and 2-methyl-1-pyrroline), pyrrolidine derivatives (e.g., pyrrolidine, N-methylpyrrolidine, pyrrolidinone, and N-methylpyrrolidone), imidazoline derivatives, imidazolidine derivatives, pyridine derivatives (e.g., pyridine, methylpyridine, ethylpyridine, propylpyridine, butylpyridine, 4-(1-butylpentyl)pyridine, dimethylpyridine, trimethylpyridine, triethylpyridine, phenylpyridine, 3-methyl-2-phenylpyridine, 4-t-butylpyridine, diphenylpyridine, methoxypyridine, butoxypyridine, dimethoxypyridine, 1-methyl-2-pyridine, 4-pyrrolidinopyridine, 1-methyl-4-phenylpyridine, 2-(1-ethylpropyl)pyridine, aminopyridine, and dimethylaminopyridine), pyridazine derivatives, pyrimidine derivatives, pyrazine derivatives, pyrazolone derivatives, pyrazolidine derivatives, piperidine derivatives, piperazine derivatives, morpholine derivatives, indole derivatives, isoindole derivatives, 1H-indazole derivatives, indoline derivatives, guanidine derivatives, quinoline derivatives (e.g., quinoline and 3-quinolinecarbonitrile), isoquinoline derivatives, cinnoline derivatives, quinazoline derivatives, quinoxaline derivatives, phthalazine derivatives, purine derivatives, pteridine derivatives, carbazole derivatives, phenanthridine derivatives, acridine derivatives, phenazine derivatives, phenanthroline derivatives, adenine derivatives, adenosine derivatives, guanine derivatives, guanosine derivatives, uracil derivatives, and uridine derivatives.

Examples of the amido group are carbamoyl, N-methylcarbamoyl, N,N-dimethylcarbamoyl, acetamido, N-methylacetamido, propionamido, benzamido, methacrylamido, decanylamido, laurylamido, palmitylamido, and stearylamido.

Examples of the imido group are phthalimido, succinimido, and maleimido.

Examples of the ester group are carbamate, methyl ester, ethyl ester, propyl ester, isopropyl ester, n-butyl ester, sec-butyl ester, t-butyl ester, pentyl ester, isopentyl ester, t-amylester, hexylester, heptylester, octylester, cyclopentyl ester, cyclohexyl ester, cycloheptyl ester, norbornyl ester, and adamantyl ester groups.

The halogen-substituted alkyl group includes trifluoromethyl, 1,1,1-trifluoroethyl, 1,1,1-trichloroethyl, and nonafluorobutyl.

The halogen-substituted aryl group includes fluorobenzene, chlorobenzene, and 1,2,3,4,5-pentafluorobenzene.

The alkoxy group and the alkenyloxy group include methoxy, ethoxy, propoxy, isopropoxy, n-butoxy, sec-butoxy, t-butoxy, pentyloxy, isopentyloxy, t-amyloxy, hexyloxy, heptyloxy, octyloxy, cyclopentyloxy, cyclohexyloxy, cycloheptyloxy, norbornyloxy, adamantyloxy, acryloxy, and methacryloxy.

The heterocyclic group includes those derived from thiophene, furan, tetrahydrofuran, morpholine, pyran, tetrahydropyran, dioxane, thiocarbazole, xanthene, and thioxanthene.

Illustrative examples of the compound (C) are shown below.

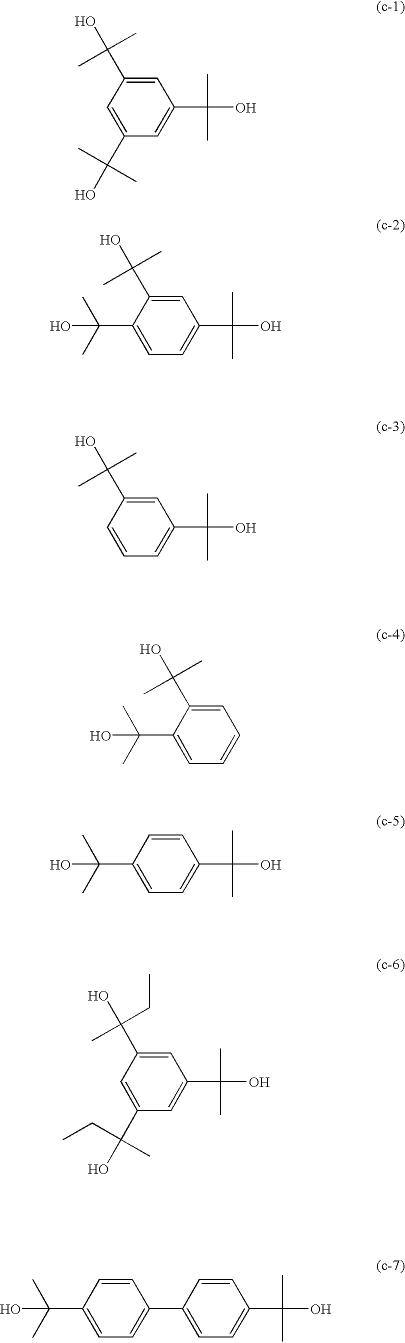

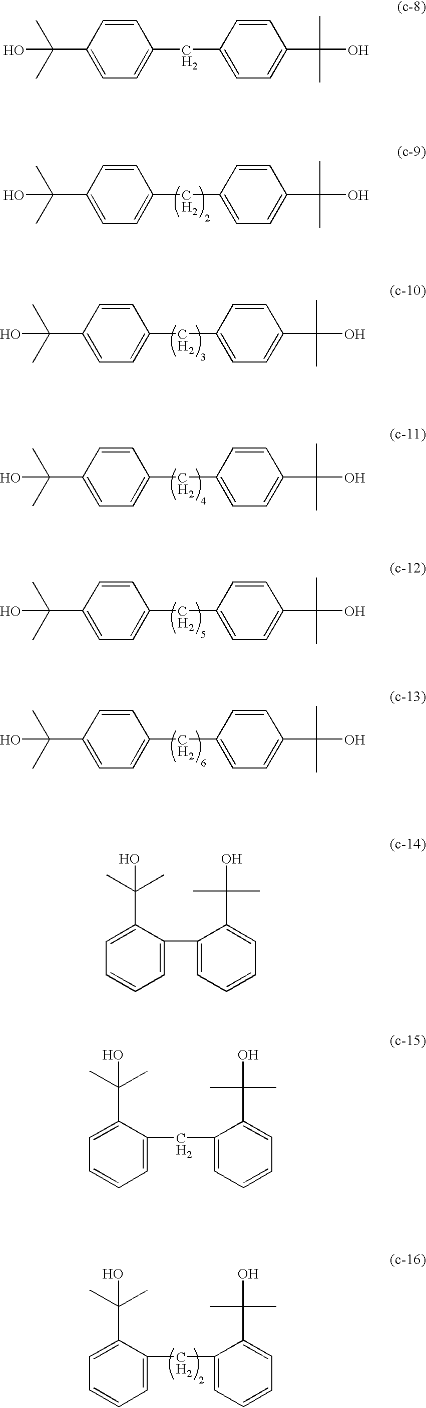

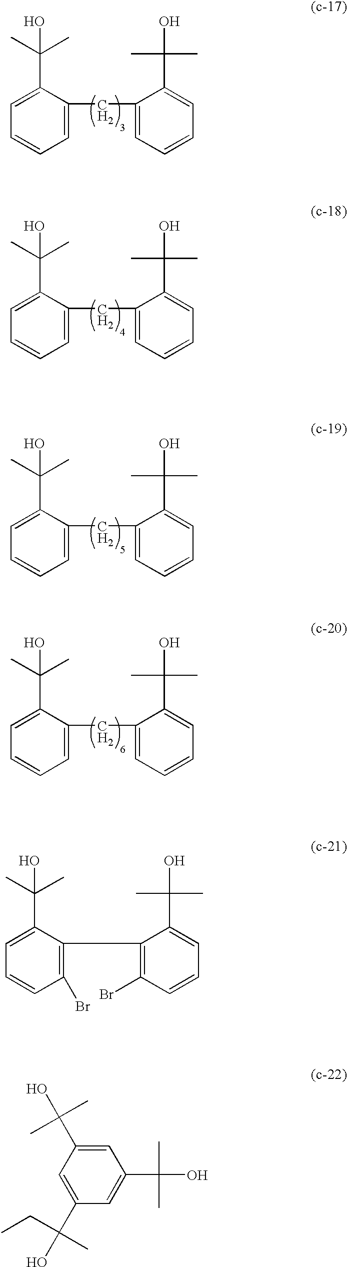

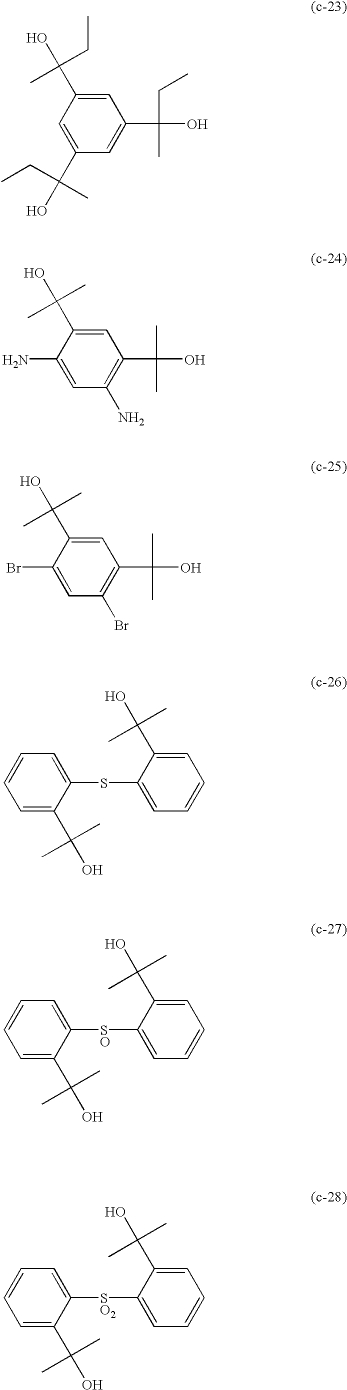

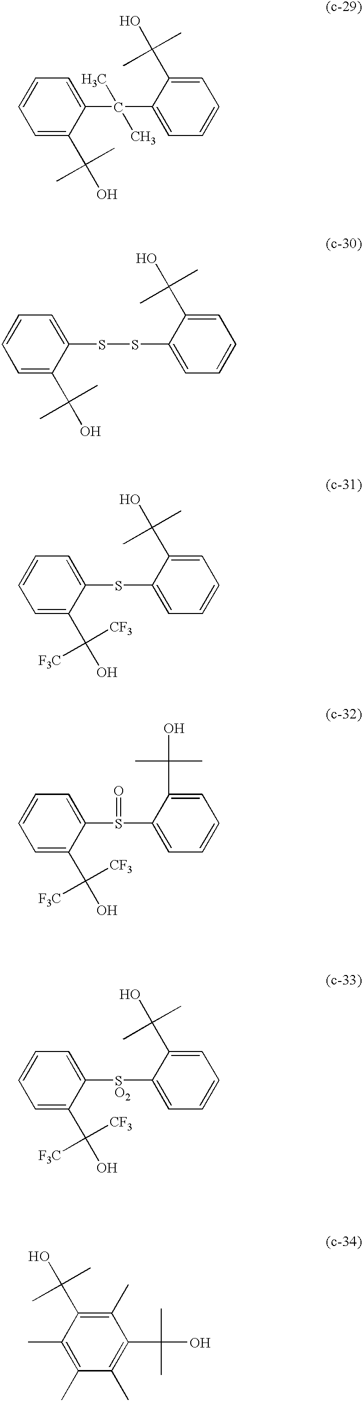

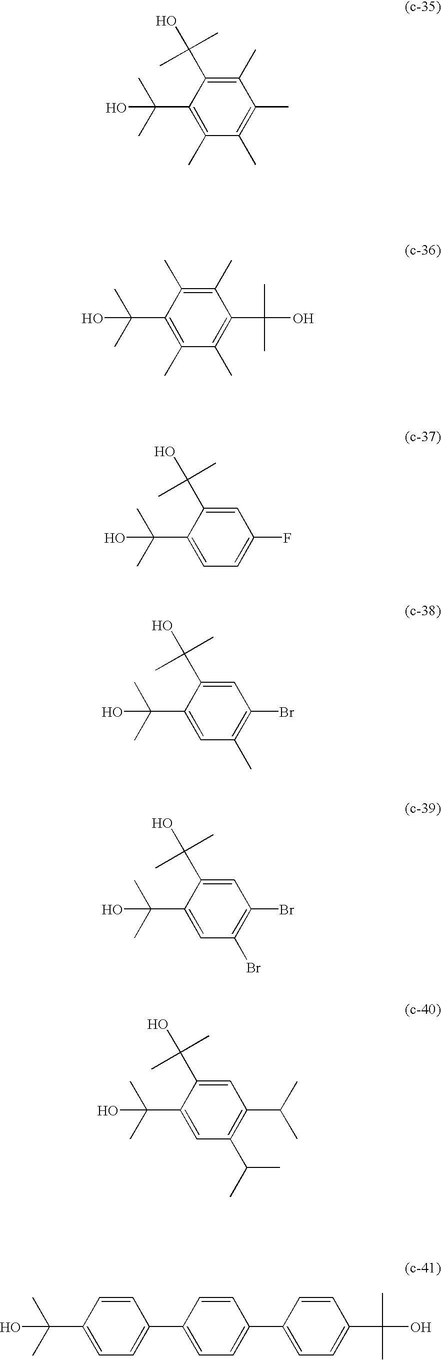

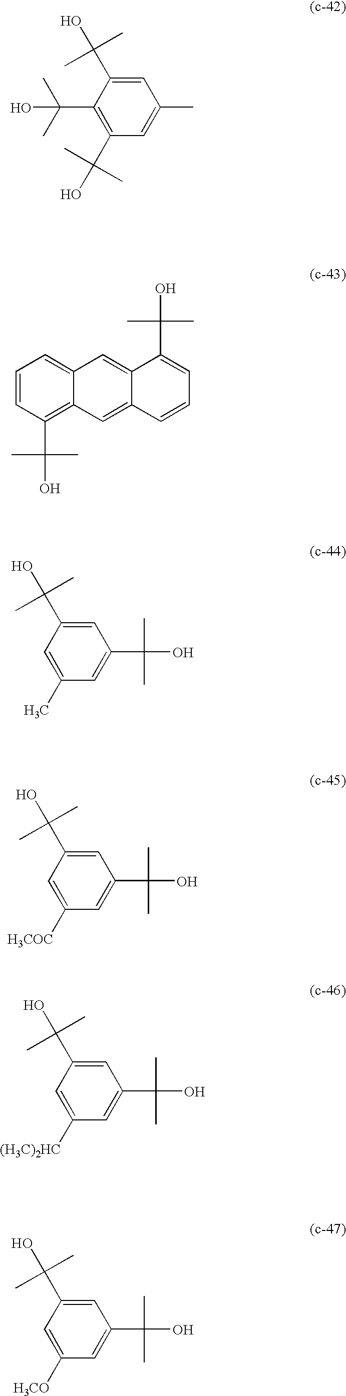

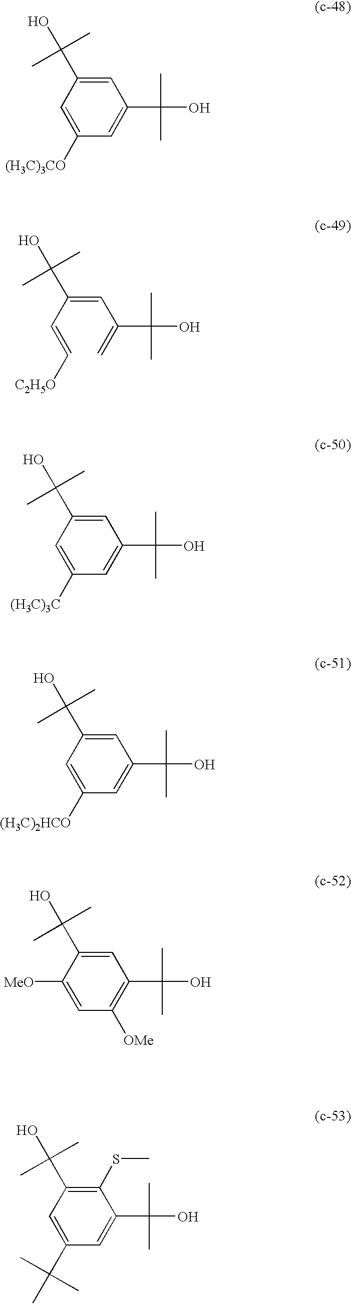

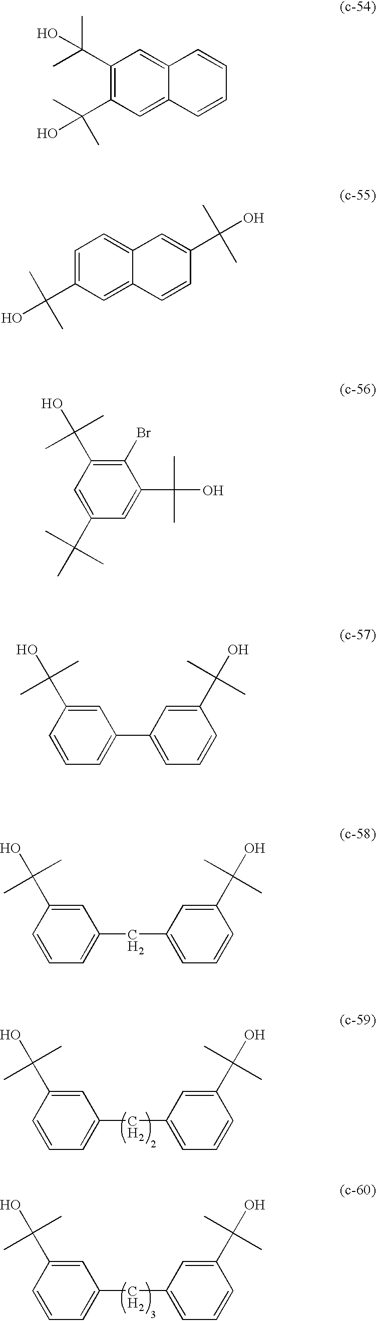

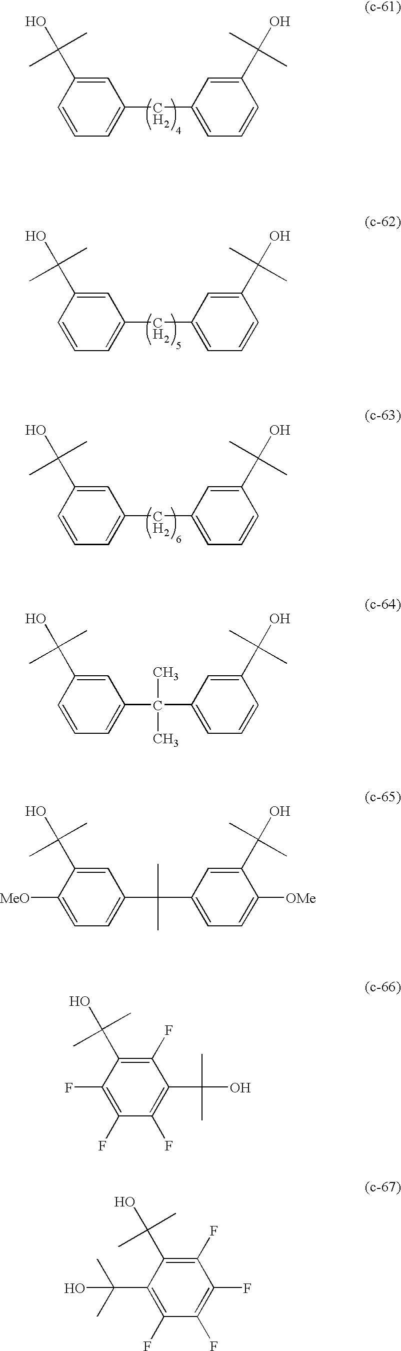

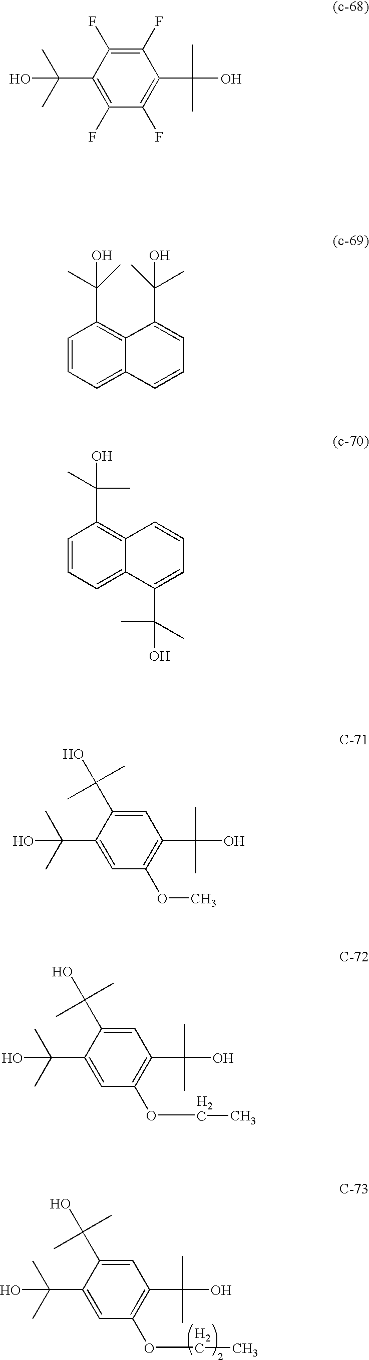

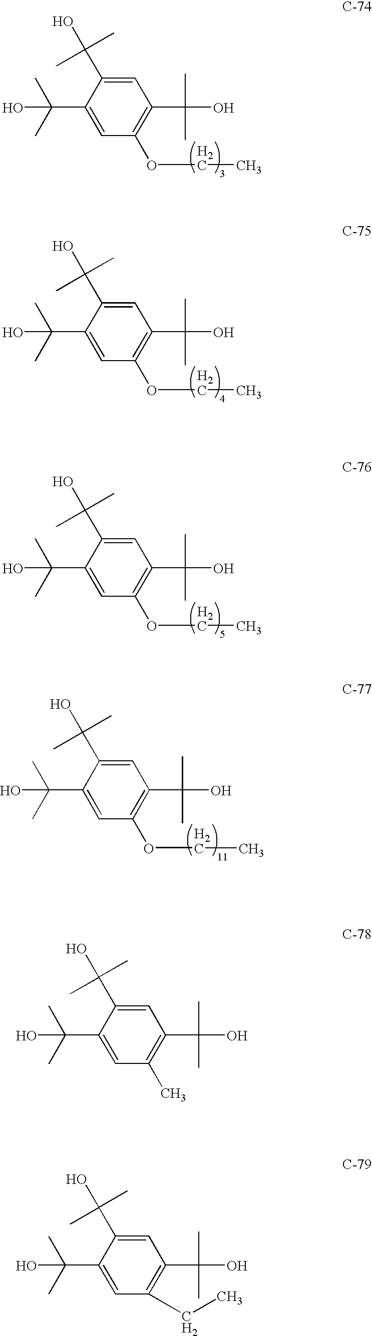

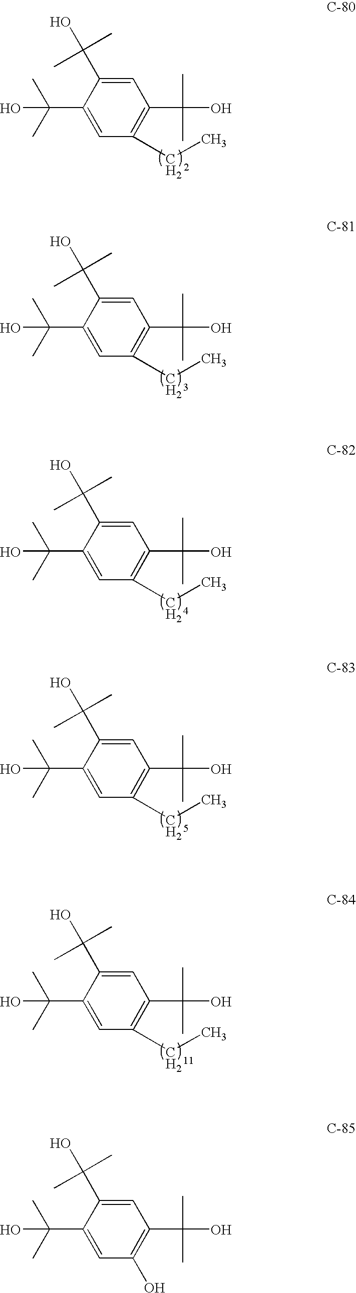

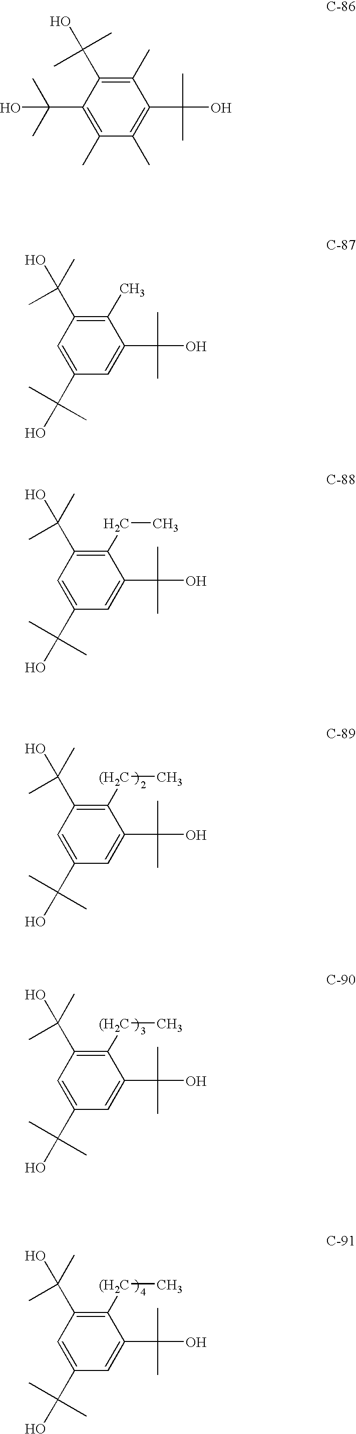

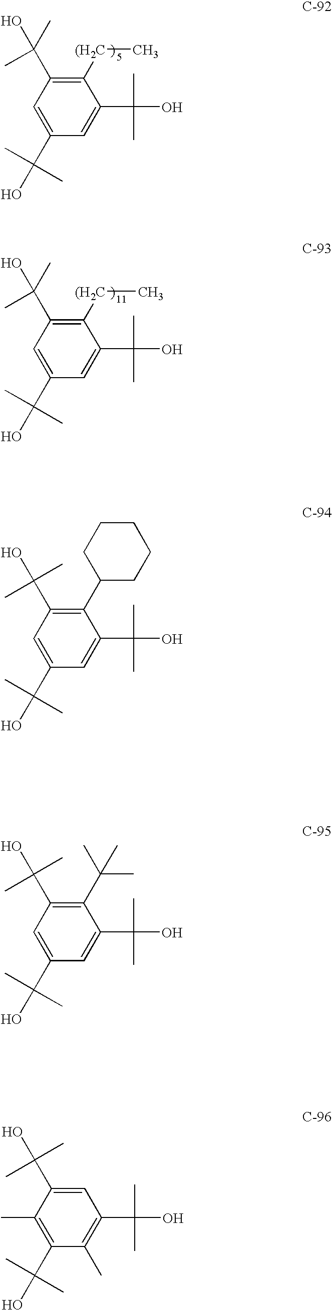

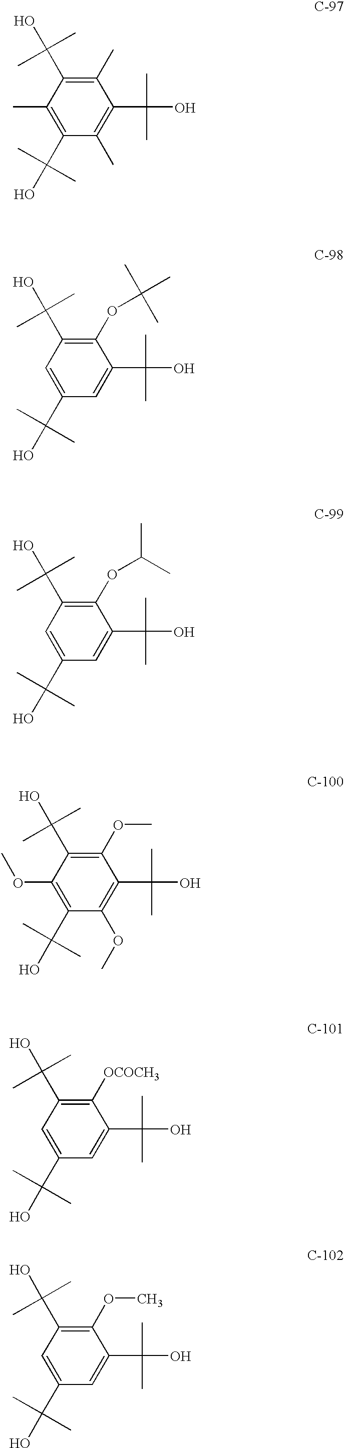

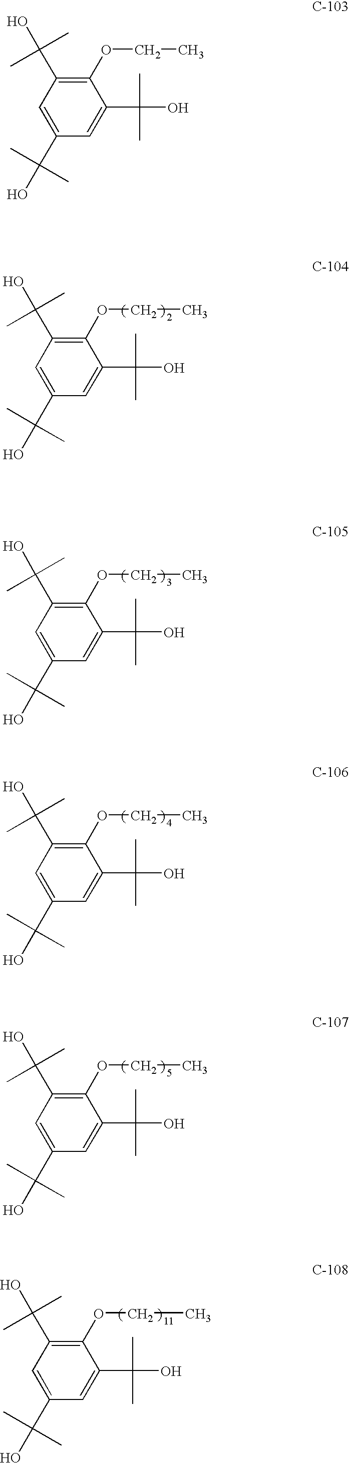

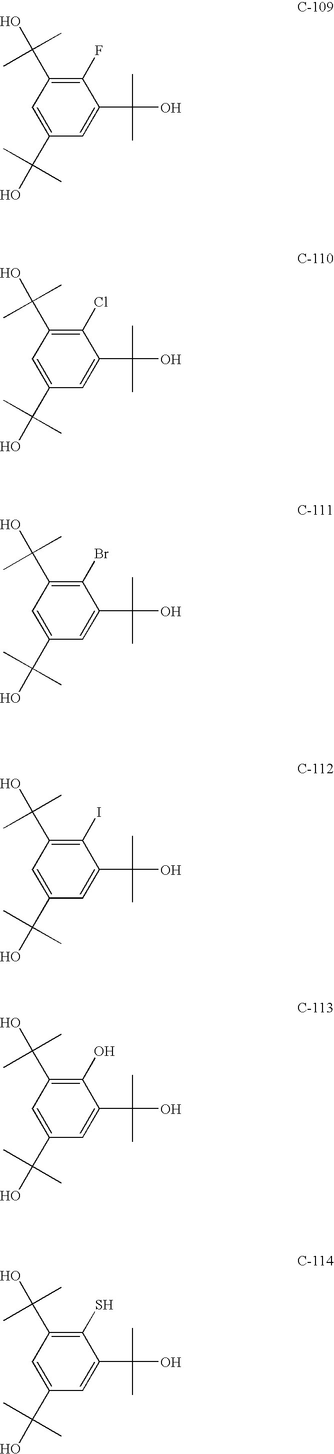

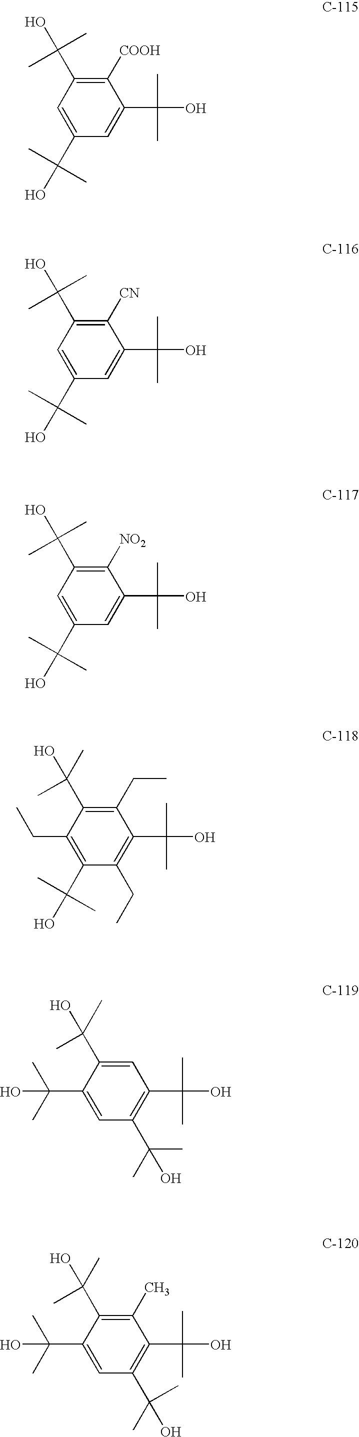

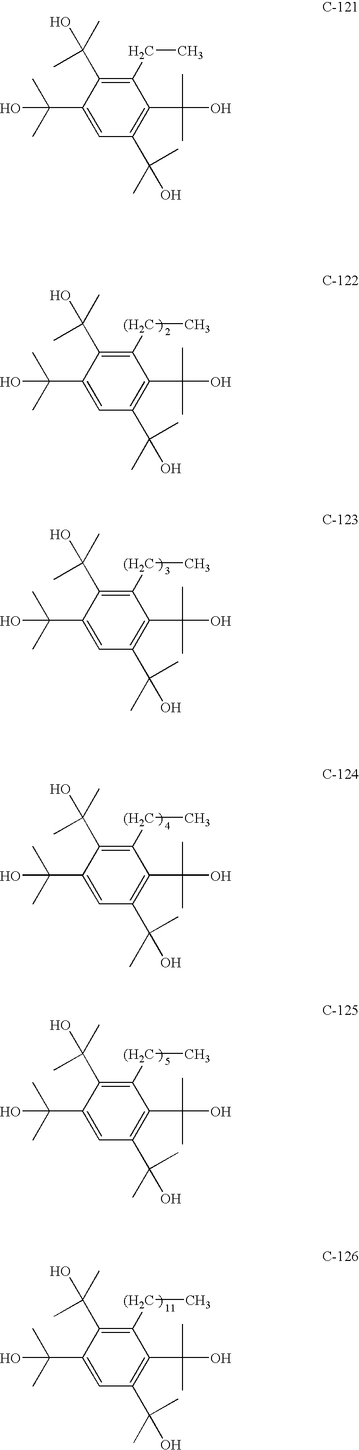

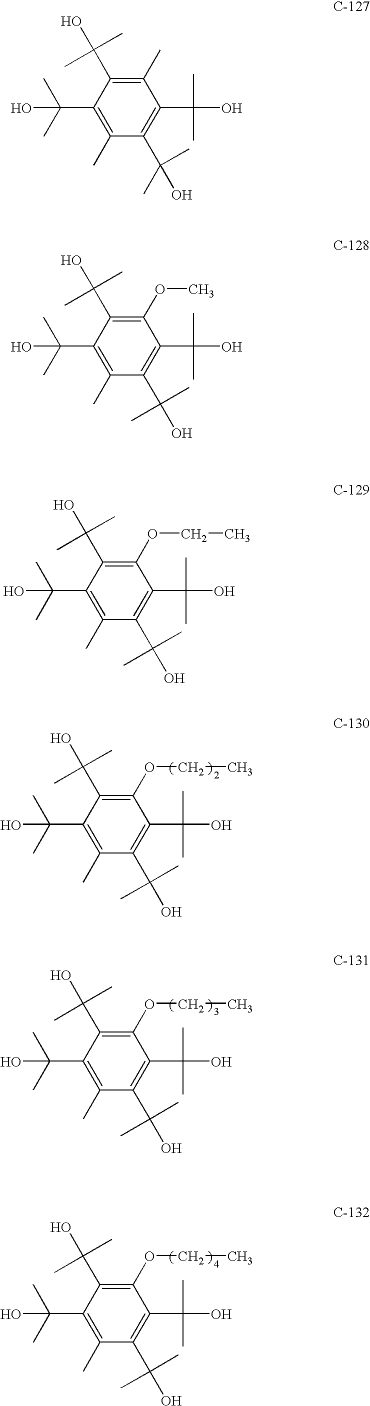

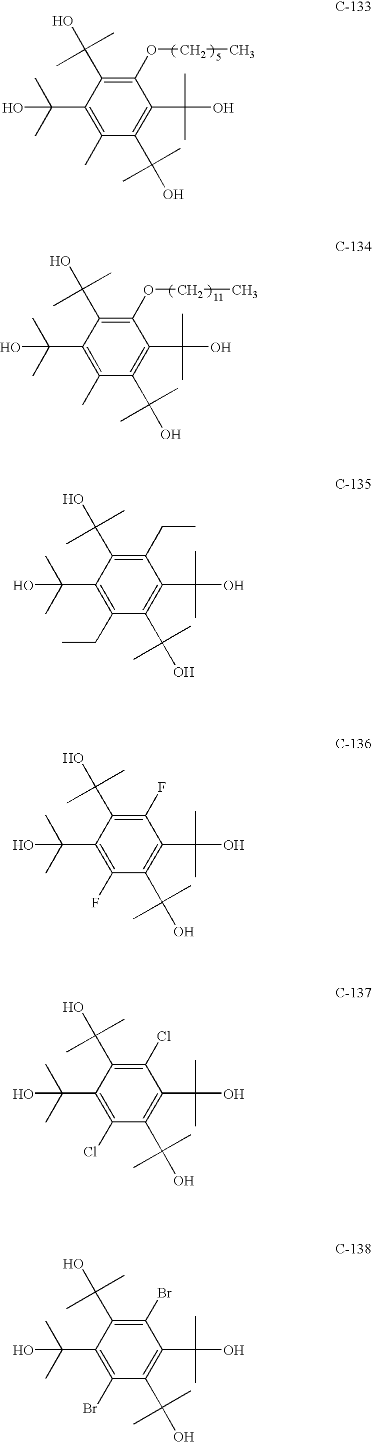

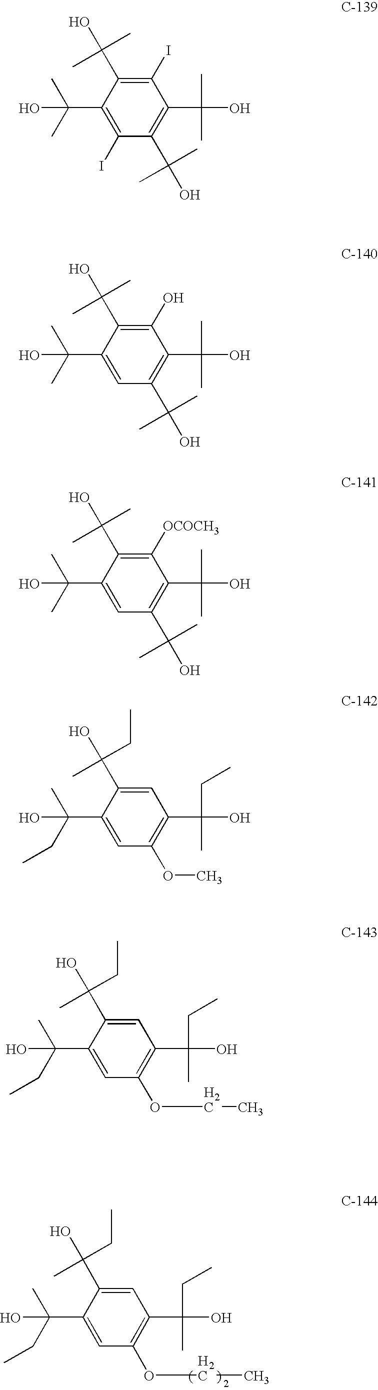

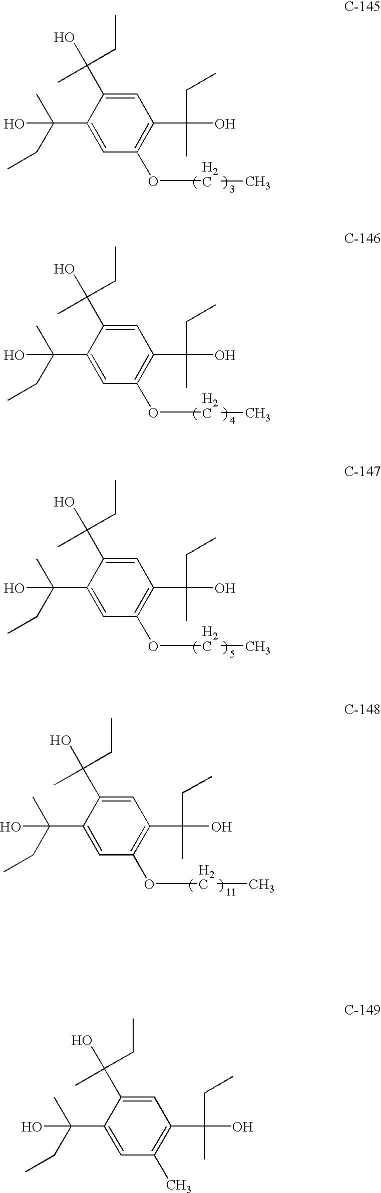

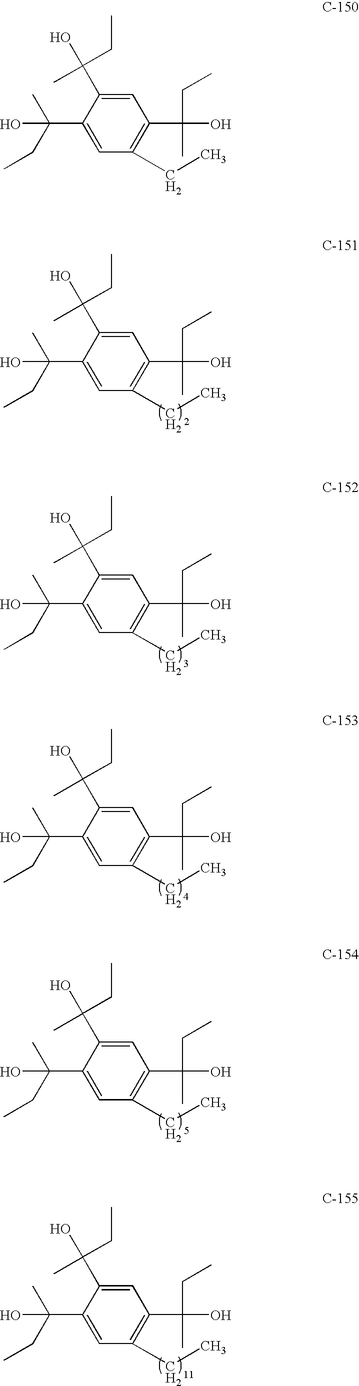

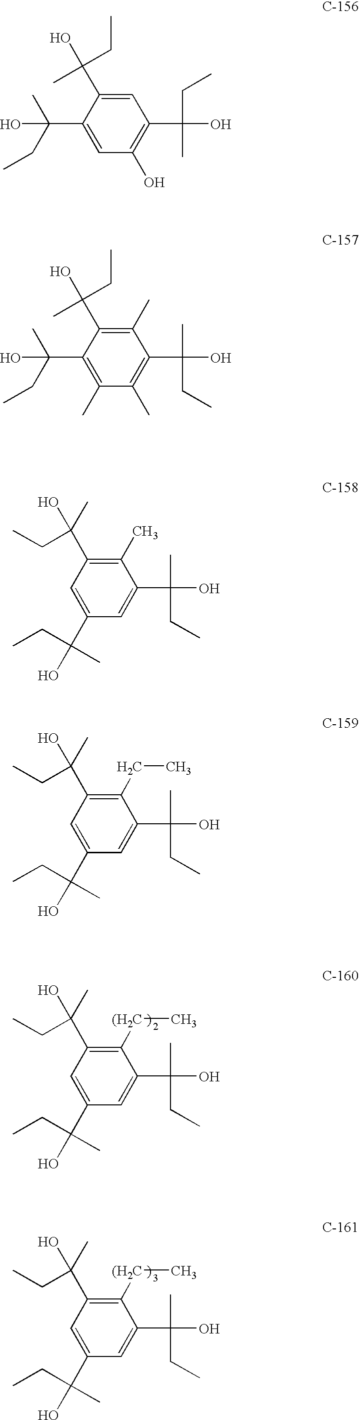

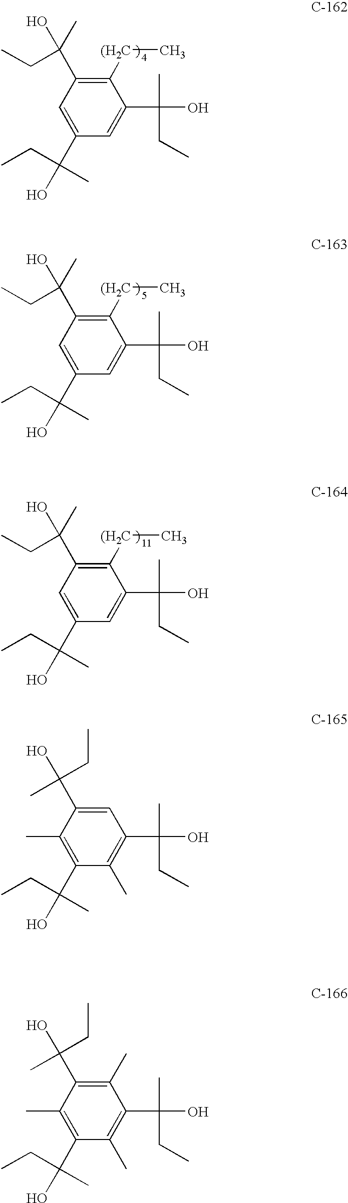

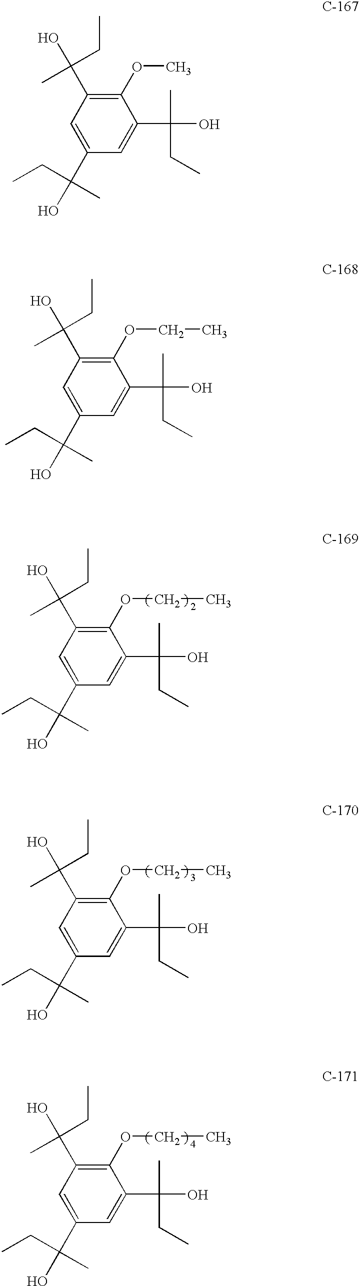

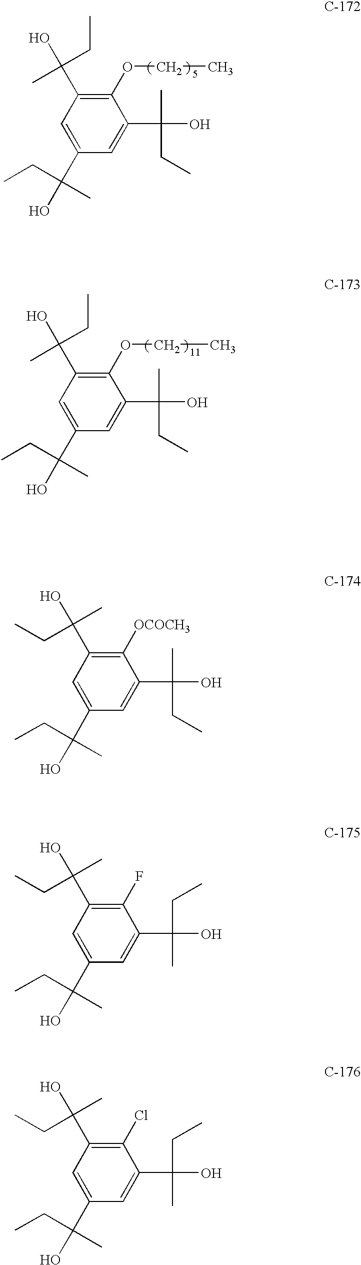

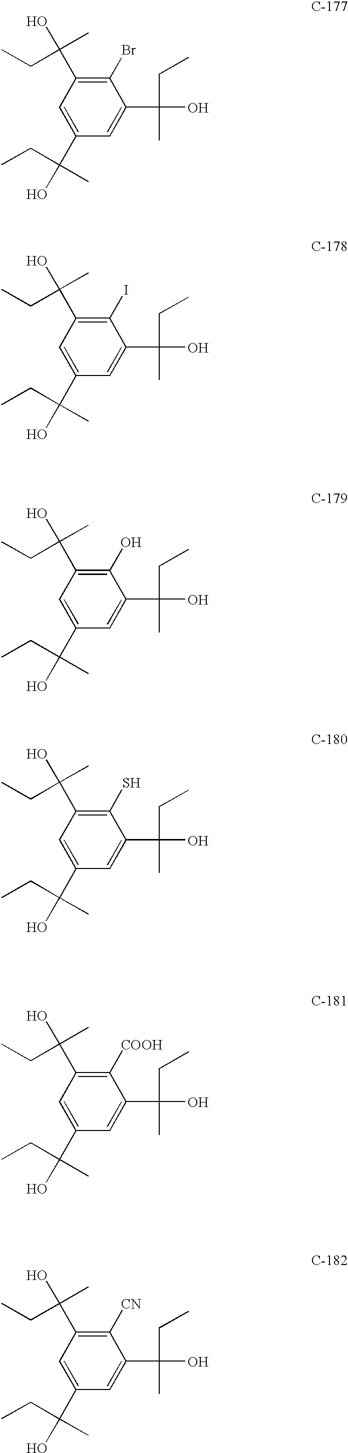

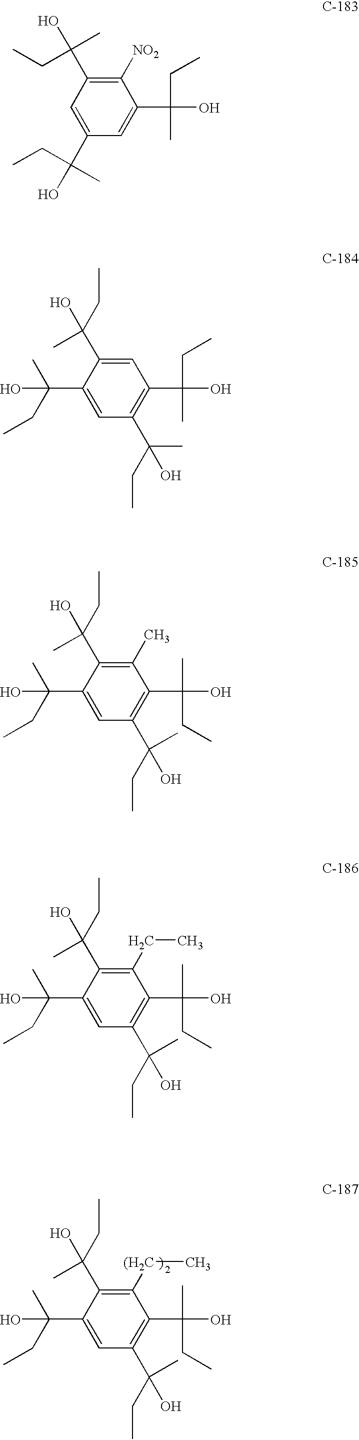

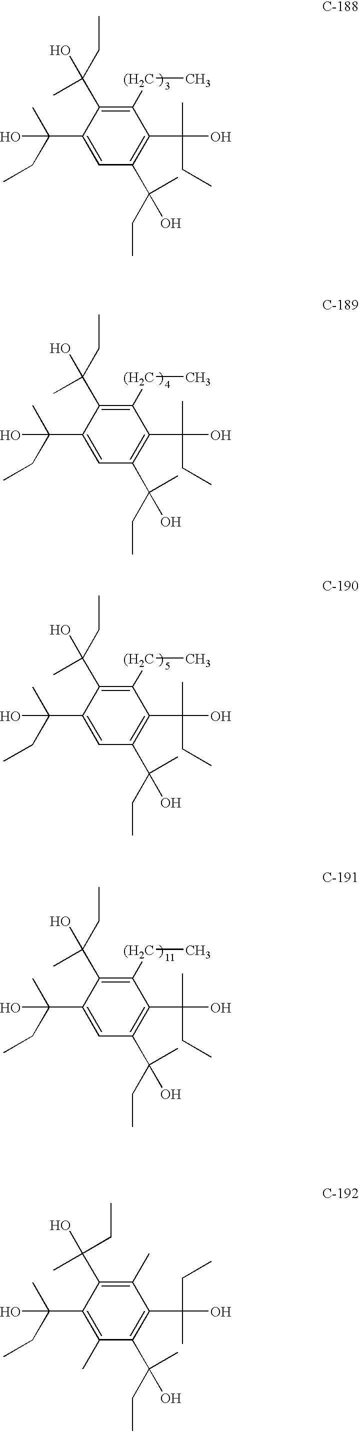

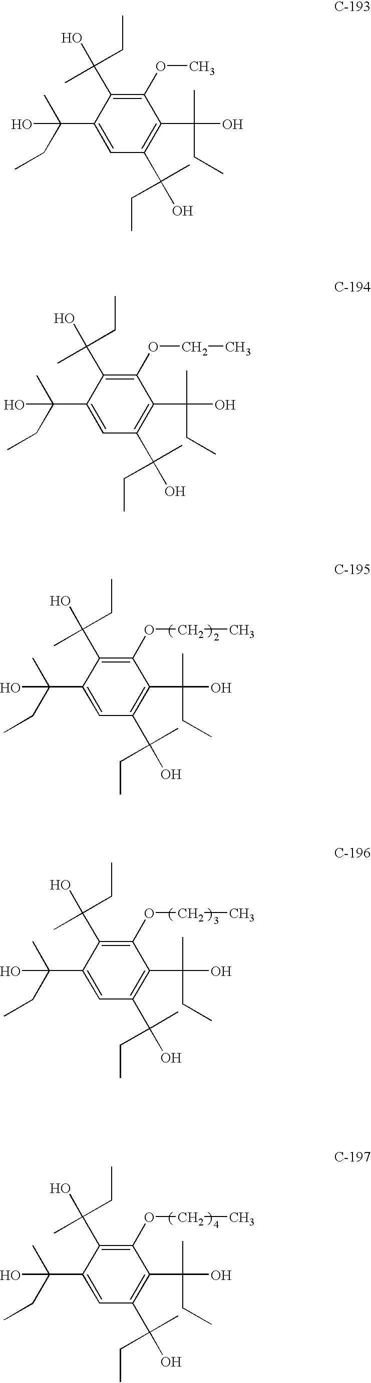

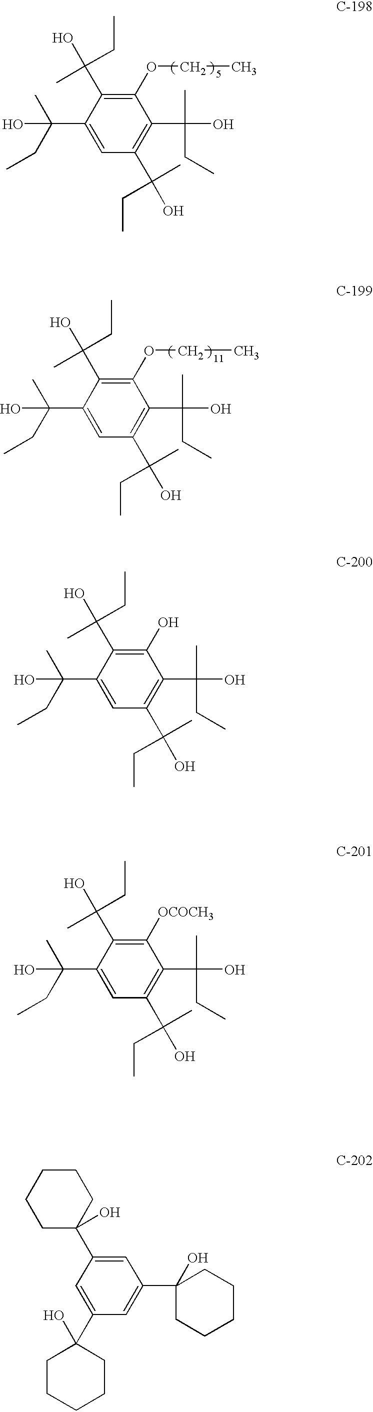

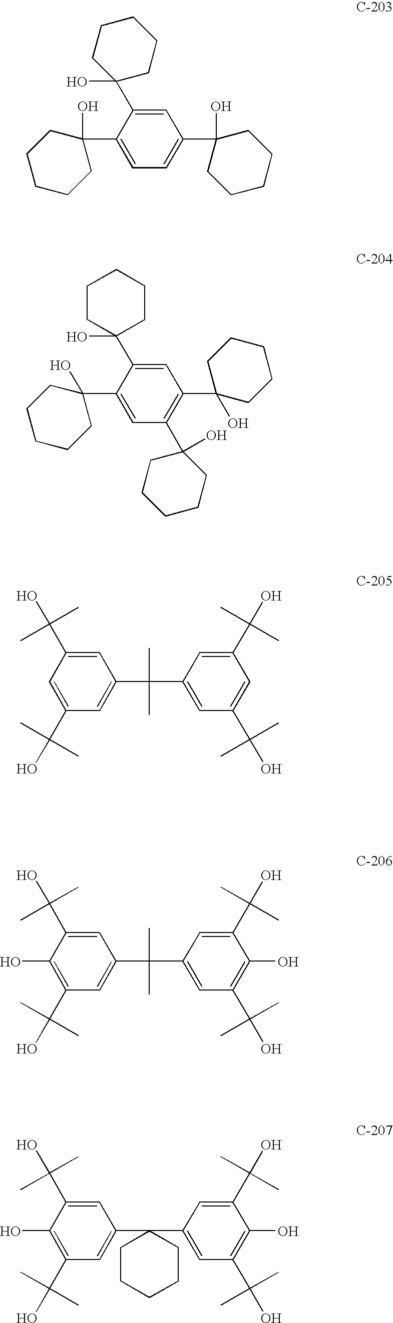

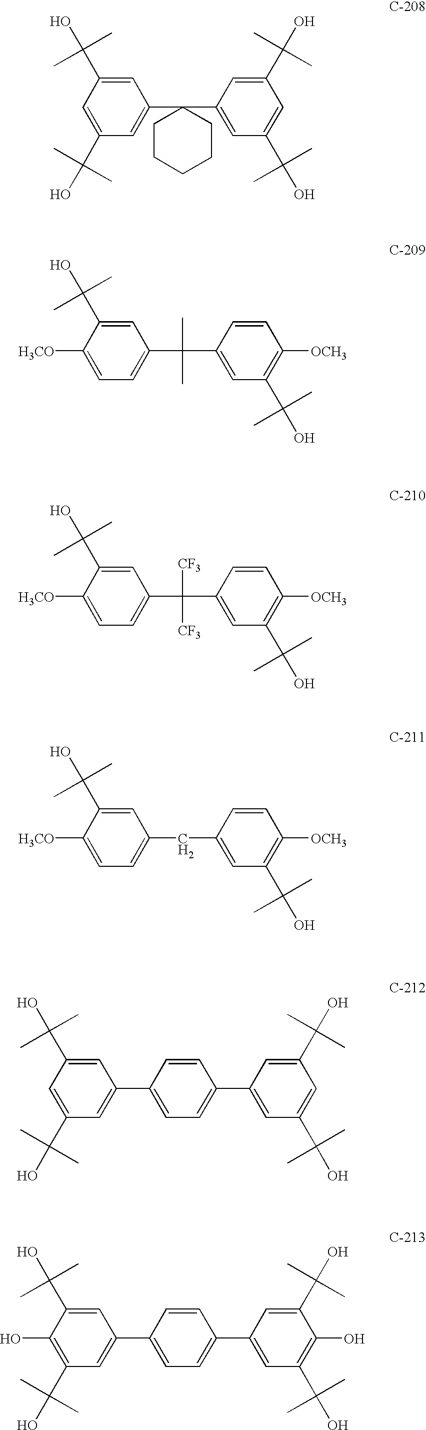

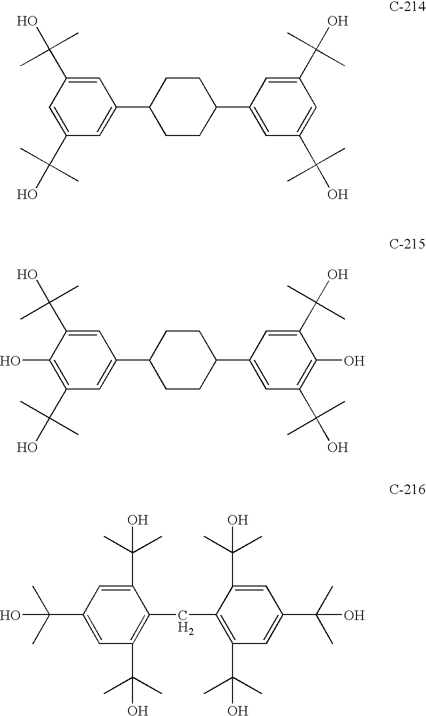

The compound (C) as component (C) is used usually in an amount of 3 to 65% by weight, preferably 5 to 50% by weight, based on the total solids content of the resist composition.

Commercially available compounds (C) can be utilized in the present invention. For example, some are available from Honshu Chemical Industry Co., Ltd., Tokyo Kasei Kogyo Co., Ltd., and Sigma-Aldrich Co.

The crosslinking agent which is excited by the acid generated by component (A) to induce a crosslinking reaction, which can be used as component (D), hereinafter referred to as “a crosslinking agent”, is a compound capable of crosslinking the alkali-soluble (B) resin in the presence of an acid, for example, an acid generated on irradiation with active light rays or radiations. Such a compound includes one having at least one kind of a substituent crosslinkable with the alkali-soluble resin (hereinafter referred to as a crosslinking substituent).

The crosslinking substituents include (i) a hydroxyalkyl group and derivatives thereof, such as an alkoxyalkyl group and an acetoxyalkyl group, (ii) a carbonyl group and derivatives thereof, such as a formyl group and a carboxyalkyl group, (iii) nitrogen-containing groups, such as a dimethylaminomethyl group, a diethylaminomethyl group, a dimethylolaminomethyl group, a diethylolaminomethyl group, and a morpholinomethyl group, (iv) glycidyl-containing groups, such as a glycidyl ether group, a glycidyl ester group, and a glycidylamino group, (v) aromatic groups, such as aryloxyalkyl groups and aralkyloxyalkyl groups, e.g., a benzyloxymethyl group and a benzoyloxymethyl group, and (vi) groups containing a polymerizable multiple bond, such as a vinyl group and an isopropenyl group. Preferred of them are hydroxyalkyl groups and alkoxyalkyl groups, with alkoxymethyl groups being particularly preferred.

The crosslinking agents having the crosslinking group include (i) methylol-containing compounds, such as methylol-containing melamine compounds, methylol-containing benzoguanamine compounds, methylol-containing urea compounds, methylol-containing glycoluril compounds, and methylol-containing phenol compounds, (ii) alkoxyalkyl-containing compounds, such as alkoxyalkyl-containing melamine compounds, alkoxyalkyl-containing benzoguanamine compounds, alkoxyalkyl-containing urea compounds, alkoxyalkyl-containing glycoluril compounds, and alkoxyalkyl-containing phenol compounds, (iii) carboxymethyl-containing compounds, such as carboxymethyl-containing melamine compounds, carboxymethyl-containing benzoguanamine compounds, carboxymethyl-containing urea compounds, carboxymethyl-containing glycoluril compounds, and carboxymethyl-containing phenol compounds, and (iv) epoxy compounds, such as bisphenol A epoxy compounds, bisphenol F epoxy compounds, bisphenol S epoxy compounds, novolak resin epoxy compounds, resol resin epoxy compounds, and poly(hydroxystyrene) epoxy compounds.

The alkali-soluble resin which has been endowed with the character as a crosslinking agent by introducing the crosslinking group to the acidic functional group of the alkali-soluble resin also serves as component (D). The amount of the crosslinking group to be introduced is usually 5 to 60 mol %, preferably 10 to 50 mol %, still preferably 15 to 40 mol %, based on the total acidic functional group content of the alkali-soluble resin. If the amount is less than 5 mol %, it is difficult to induce sufficient crosslinking reactions, which can result in a reduction of normalized remaining thickness or swelling and meandering of the pattern. If the amount is more than 60 mol %, the alkali-soluble resin tends to have reduced alkali solubility, i.e., reduced developability.

Crosslinking agents that are preferred as component (D) include alkoxymethylated urea compounds or resins thereof and alkoxymethylated glycoluril compounds or resins thereof. Particularly preferred crosslinking agents include the following groups of compounds (D1) and (D2).

The crosslinking agents (D1) are compounds having an N-hydroxymethyl group, an N-alkoxymethyl group or an N-acyloxymethyl group represented by formulae (2) to (4) and alkoxymethylated melamine compounds:

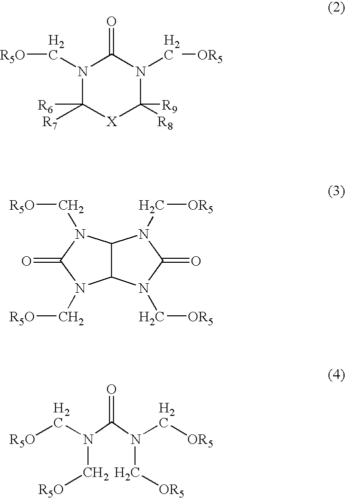

wherein a plurality of R₅'s each represent a hydrogen atom, an alkyl group (preferably having 1 to 5 carbon atoms, still preferably 1 to 3 carbon atoms, such as methyl, ethyl or propyl) or an acyl group (preferably having 2 to 6 carbon atoms, particularly 2 to 4 carbon atoms, such as acetyl or propionyl) R₆, R₇, R₈, and R₉ each represent a hydrogen atom, a hydroxyl group, an alkyl group (preferably having 1 to 5 carbon atoms, particularly 1 to 3 carbon atoms, such as methyl, ethyl or propyl) or an alkoxy group (preferably having 1 to 5 carbon atoms, particularly 1 to 3 carbon atoms, such as methoxy, ethoxy or propoxy); and X represents a single bond, a methylene group or an oxygen atom (preferably a single bond or a methylene group).

The substituents in formulae (2) to (4) may further be substituted with an alkyl group (e.g., methyl or ethyl), an alkoxy group (e.g., methoxy or ethoxy), a hydroxyl group, a halogen atom, etc.

Illustrative examples of the compounds included under the group (D1) are shown below.

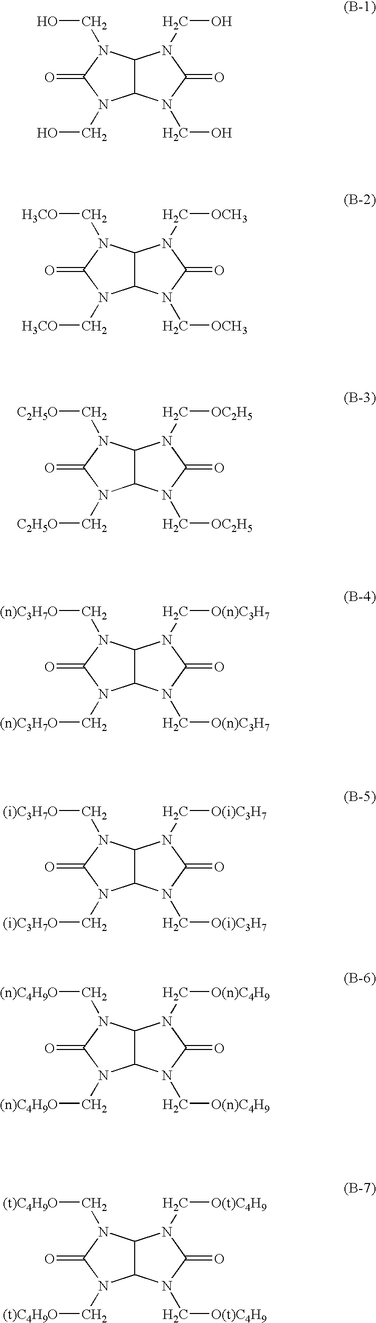

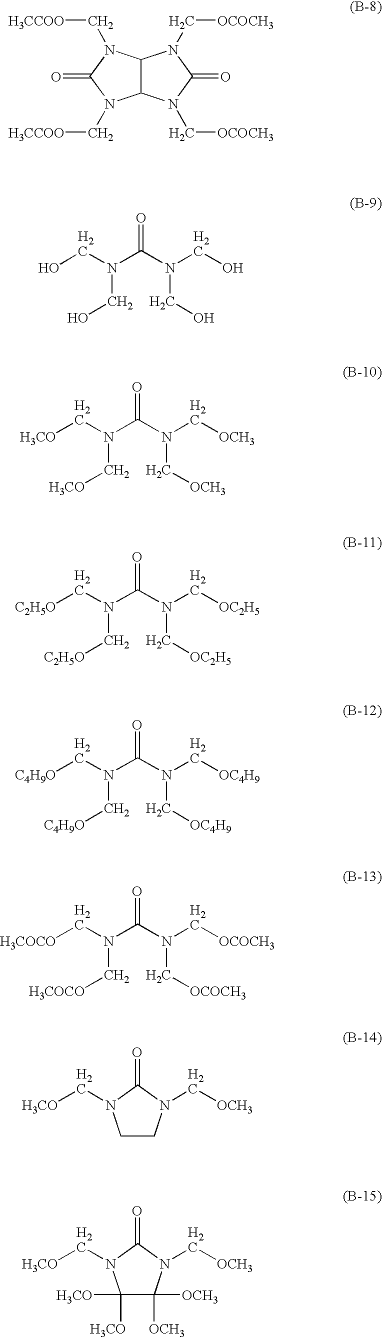

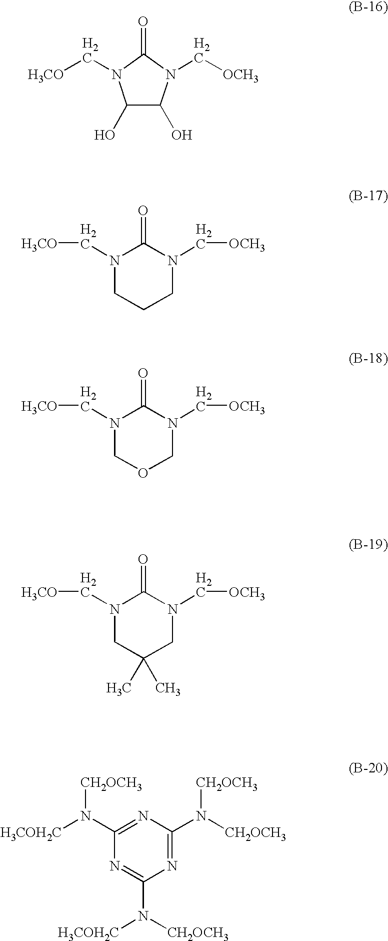

The crosslinking agents (Dl) are obtained by, for example, condensing a urea compound or a glycoluril compound with formalin to prepare a methylol-containing compound, which is etherified with a lower alcohol, such as methyl alcohol, ethyl alcohol, propyl alcohol or butyl alcohol. The reaction mixture is cooled to precipitate the product, which is collected. The crosslinking agents (D1) are also available on the market under trade names of CYMEL (from Mitsui Cyanamid) and NIKARAC (from Sanwa Chemical Co., Ltd.).

The crosslinking agents (D2) are phenol derivatives having 1 to 6 benzene rings per molecule and having at least two substituents selected from a hydroxymethyl group and an alkoxymethyl group bonded to at least one of the benzene rings. The crosslinking agents (D2) are preferably phenol derivatives having a molecular weight of not more than 1500, and containing 1 to 6 benzene rings and at least two substituents selected from a hydroxymethyl group and an alkoxymethyl group per molecule, the two or more substituents being either concentrated on one of the benzene rings or allotted to two or more benzene rings.

The alkoxymethyl group bonded to the benzene ring(s) is preferably one having 6 or fewer carbon atoms, such as methoxymethyl, ethoxymethyl, n-propoxymethyl, isopropoxymethyl, n-butoxymethyl, isobutoxymethyl, sec-butoxymethyl, and t-butoxymethyl. Alkoxy-substituted alkoxy groups, such as 2-methoxyethoxy and 2-methoxy-1-propyl, are also preferred.

Examples of particularly preferred crosslinking agents (D2) are shown below.

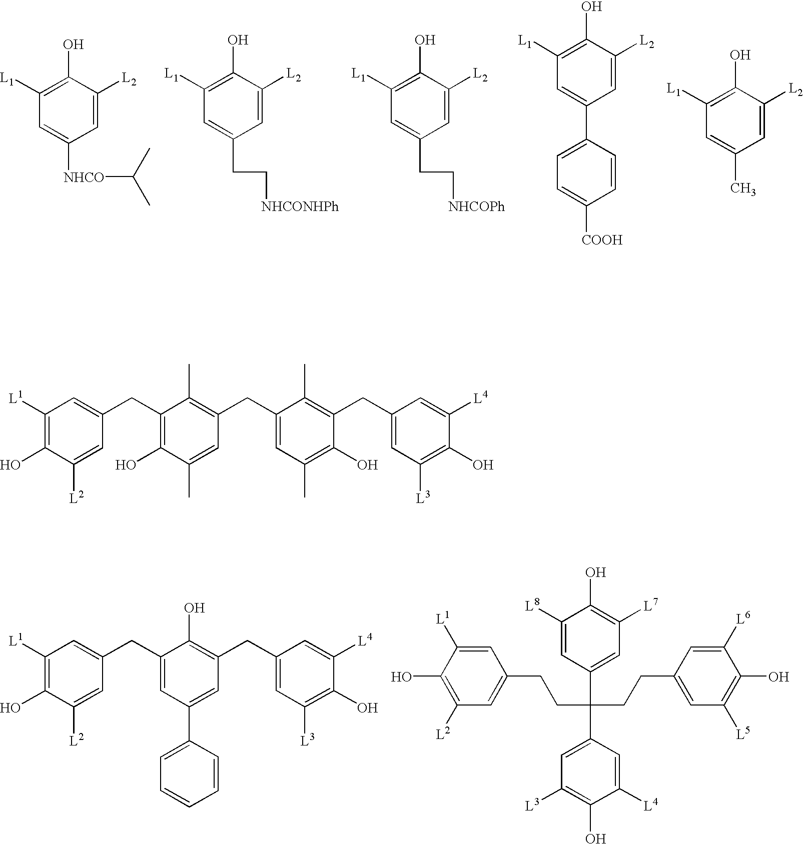

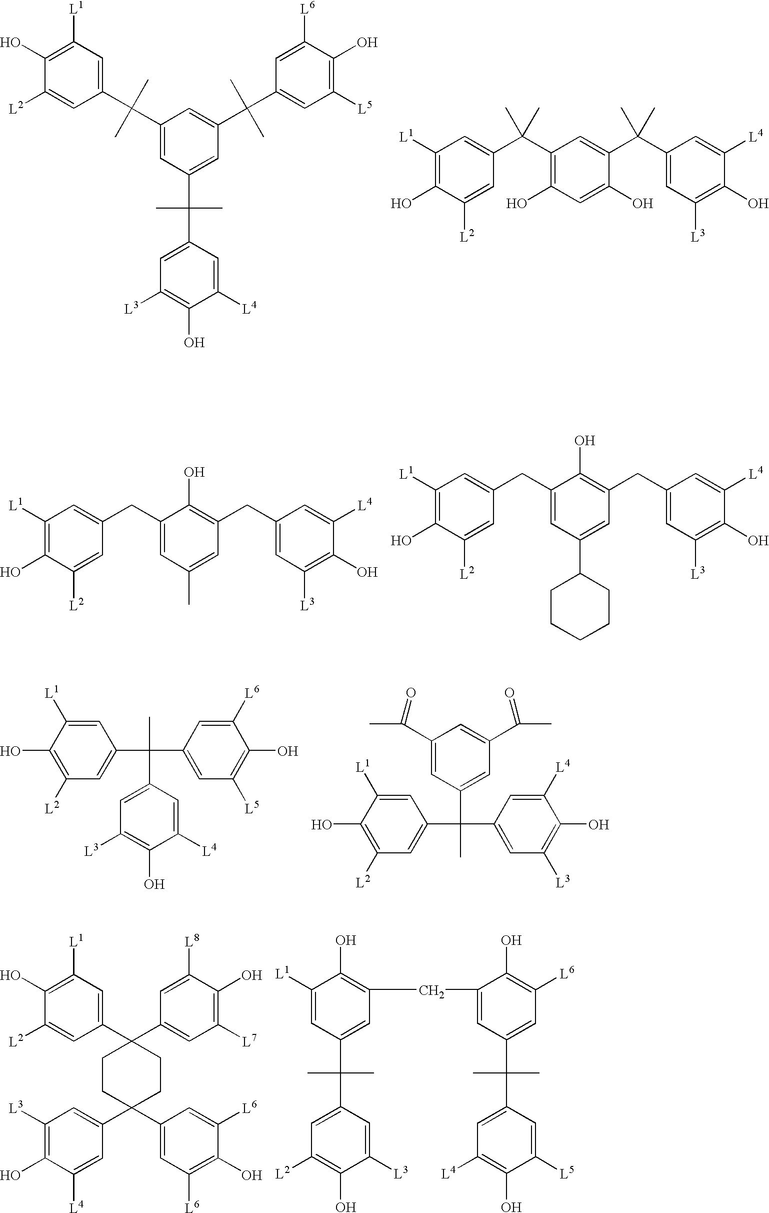

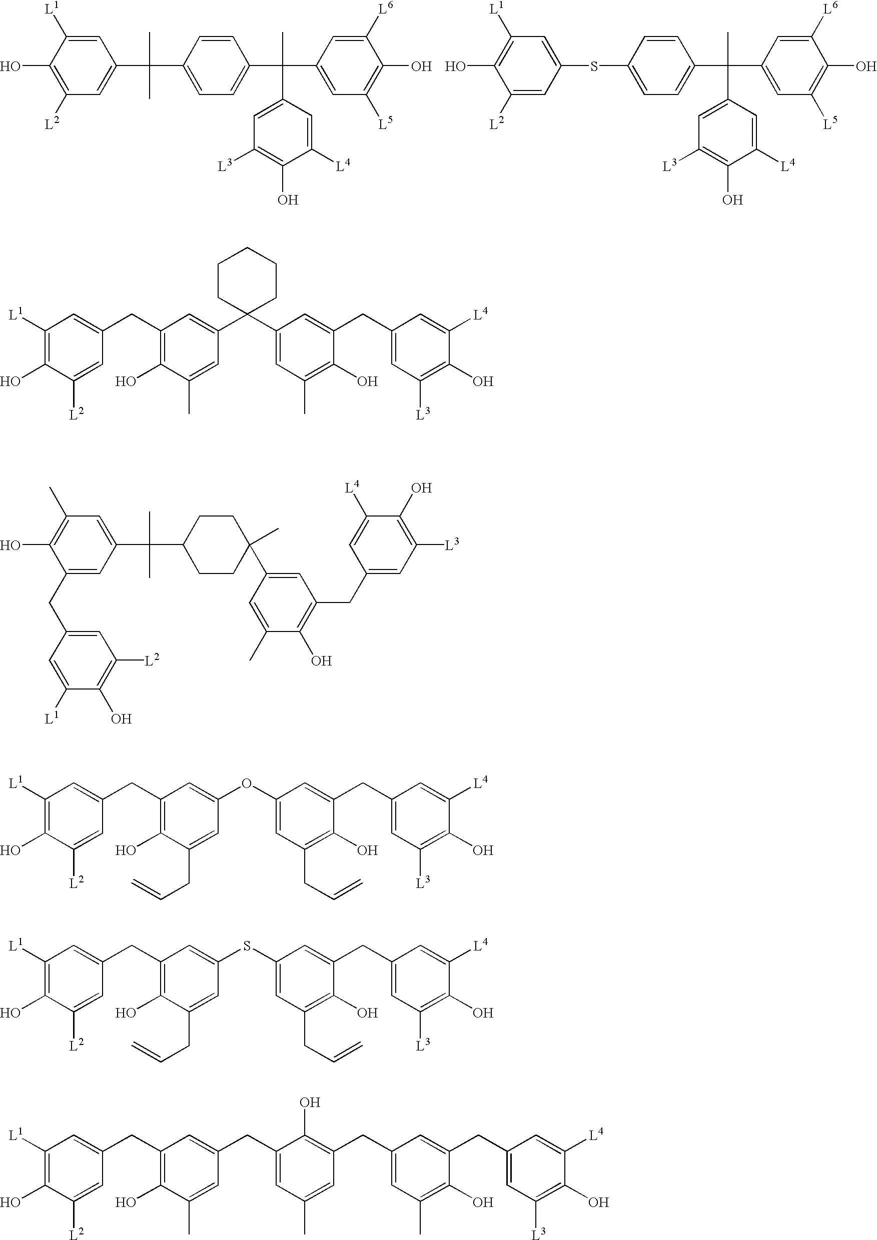

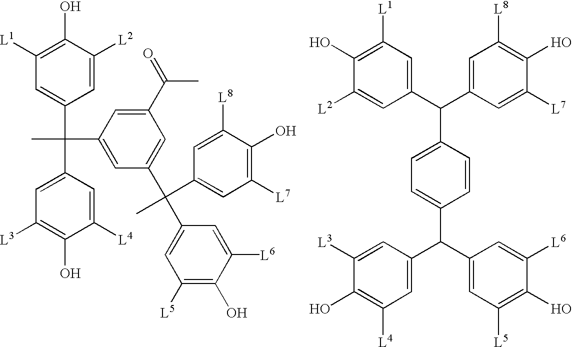

wherein L¹, L², L³, L⁴, L⁵, L⁶, L⁷ and L⁸, which may be the same or different, each represent a hydroxymethyl group, a methoxymethyl group or an ethoxymethyl group.

The phenol derivatives having a hydroxymethyl group are prepared by reacting a corresponding phenol compound having no hydroxymethyl group (any of the compounds of the formulae shown above in which L¹ to L⁸ are each a hydrogen atom) with formaldehyde in the presence of a base catalyst. In order to prevent resinification or gelation, the reaction is preferably carried out at 60° C. or lower temperatures. The details of the synthesis are given, e.g., in JP-A-6-282067 and JP-A-7-64285.

The phenol derivatives having an alkoxymethyl group are prepared by reacting a corresponding phenol derivative having a hydroxymethyl group with an alcohol in the presence of an acid catalyst. To prevent resinification or gelation, the reaction is desirably carried out 100° C. or lower temperatures. The details of the synthesis are given, e.g., in EP632003A1.

The phenol derivatives having a hydroxymethyl group or an alkoxymethyl group are preferred for their storage stability. Those having an alkoxymethyl group are particularly preferred for their storage stability. The phenol derivatives (crosslinking agents (D2)) may be used either individually or as a combination of two or more thereof.

The crosslinking agent as component (D) is used in an amount of 3 to 70% by weight, preferably 5 to 50% by weight, based on the total solids content of the resist composition. Proportions lower than 3% by weight lead to a reduction in normalized remaining thickness. Proportions exceeding 70% by weight not only result in a reduction in resolution but are unadvisable from the standpoint of storage stability of the resist composition.

The crosslinking agents (D1) and (D2) may be used in combination.

It is preferred for the resist composition of the present invention to contain (F) a basic compound. Basic compounds suitable as component (F) include compounds represented by formulae (A) to (E):

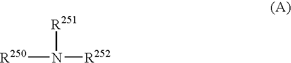

wherein R²⁵⁰, R²⁵¹, and R²⁵² each represent a hydrogen atom, an alkyl group having 1 to 6 carbon atoms, an aminoalkyl group having 1 to 6 carbon atoms, a hydroxyalkyl group having 1 to 6 carbon atoms, or a substituted or unsubstituted aryl group having 6 to 20 carbon atoms; R²⁵¹ and R²⁵² may be taken together to form a ring.

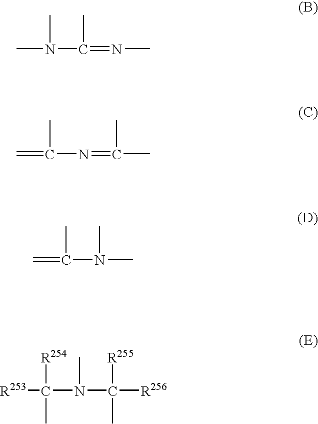

wherein R²⁵³, R²⁵⁴, R²⁵⁵, and R²⁵⁶ each represent an alkyl group having 1 to 6 carbon atoms; and the structure (B), (C), (D) or (E) may be a part of a cyclic structure.

Still preferred basic compounds include a 3- to 18-membered alicyclic amine having a nitrogen atom in its ring, substituted or unsubstituted isoindoline, a 4- to 9-membered condensed alicyclic amine having a nitrogen atom in its condensed ring, substituted or unsubstituted pyrazole, substituted or unsubstituted imidazole, substituted or unsubstituted triazole, substituted or unsubstituted tetrazole, substituted or unsubstituted isoxazole, substituted or unsubstituted oxazole, substituted or unsubstituted thiazole, substituted or unsubstituted indole, substituted or unsubstituted carbazole, substituted or unsubstituted indazole, substituted or unsubstituted benzimidazole, substituted or unsubstituted benzotriazole, substituted or unsubstituted pyrimidine, and substituted or unsubstituted pyrazine. Addition of these basic compounds brings about further improved resolution.

The 3- to 18-membered alicyclic amine having a nitrogen atom in its ring includes compounds having a 3- to 18-membered alicyclic structure containing a nitrogen atom in its ring as shown in compound Nos. (10-1) through (10-124) hereinafter given.

The 4- to 9-membered alicyclic amine having a nitrogen atom in its condensed ring includes compounds having a 4- to 9-membered alicyclic structure containing a nitrogen atom in its condensed ring as shown in compound Nos. (11-1) to (11-4) and (12-1) to (12-5) given infra.

Preferred substituents the above-recited rings may have include an alkyl group having 1 to 20 carbon atoms, an aryl group having 6 to 20 carbon atoms, an alkenyl group having 2 to 10 carbon atoms, an aralkyl group having 7 to 15 carbon atoms, a primary aliphatic amino group, a secondary aliphatic amino group, an alkoxy group having 1 to 20 carbon atoms, an acyl group having 2 to 20 carbon atoms, an amido group, an imido group, an ester group, a halogen atom, a halogen-substituted alkyl group, a halogen-substituted aryl group, an alkoxy group, an alkenyloxy group, a heterocyclic group, a hydroxyl group, a thiol group, a cyano group, a nitro group, a formyl group, a sulfonamido group, an acyl group, and an acyloxy group.

Examples of the alkyl group having 1 to 20 carbon atoms are methyl, ethyl, propyl, isopropyl, n-butyl, sec-butyl, t-butyl, pentyl, isopentyl, t-amyl, hexyl, heptyl, octyl, cyclopentyl, cyclohexyl, cycloheptyl, cyclopropylmethyl, 4-methylcyclohexyl, cyclohexylmethyl, norbornyl, adamantyl, decanyl, lauryl, palmityl, stearyl, 1,2-unsaturated cyclopentyl, 1,2-unsaturated cyclohexyl, and 1,2-unsaturated cycloheptyl.

These alkyl groups may further be substituted with an amino group, a hydroxyl group, an alkoxy group or a phenyl group. Such substituted alkyl groups include hydroxymethyl, 2-hydroxyethyl, aminomethyl, 2-aminoethyl, 3-aminopropyl, 4-aminobutyl, methoxymethyl, and phenylmethyl. Two alkyl groups on adjacent carbon atoms of a ring may be taken together to form a ring, such as a cyclobutane, cyclopentane, cyclohexane, cycloheptane or cyclooctane ring.

Examples of the aryl group having 6 to 20 carbon atoms are phenyl, naphthyl, biphenyl, phenanthrenyl, anthranyl, fluorenyl, pyrenyl, alkoxyphenyl (e.g., p-methoxyphenyl, m-methoxyphenyl, o-methoxyphenyl, ethoxyphenyl, p-t-butoxyphenyl or m-t-butoxyphenyl), alkylphenyl (e.g., 2-methylphenyl, 3-methylphenyl, 4-methylphenyl, ethylphenyl, 4-t-butylphenyl, 4-butylphenyl or dimethylphenyl), alkylnaphthyl (e.g., methylnaphthyl or ethylnaphthyl), alkoxyanphthyl (e.g., methoxynaphthyl or ethoxynaphthyl), dialkylnaphthyl (e.g., dimethylnaphthyl or diethylnaphthyl), and dialkoxynaphthyl (e.g., dimethoxynaphtyl or diethoxynaphthyl), hydroxyphenyl (e.g., 4-hydroxyphenyl or 2-hydroxyphenyl), aminophenyl (e.g., 4-aminophenyl or 2-aminophenyl), tolyl, and 4-aminophenyl.

Examples of the alkenyl group having 2 to 10 carbon atoms are vinyl, allyl, propenyl, butenyl, hexenyl, and cyclohexyl.

Examples of the aralkyl group having 7 to 15 carbon atoms are benzyl and phenethyl.

Examples of the primary aliphatic amino group are amino, methylamino, ethylamino, n-propylamino, isopropylamino, n-butylamino, isobutylamino, sec-butylamino, t-butylamino, pentylamino, t-amylamino, cyclopentylamino, hexylamino, cyclohexylamino, heptylamino, octylamino, nonylamino, decylamino, dodecylamino, cetylamino, methylenediamino, ethylenediamino, and tetraethylenepentamino.

Examples of the secondary aliphatic amino group are dimethylamino, diethylamino, di-n-propylamino, diisopropylamino, di-n-butylamino, diisobutylamino, di-sec-butylamino, dipentylamino, dicyclopentylamino, dicyclohexylamino, diheptylamino, dioctylamino, dinonylamino, didecylamino, didodecylamino, and dicetylamino.

Examples of the amido group are carbamoyl, N-methylcarbamoyl, N,N-dimethylcarbamoyl, acetamido, N-methylacetamido, propionamido, benzamido, methacrylamido, decanylamido, laurylamido, palmitylamido, and stearylamido.

Examples of the ester group are carbamate, methyl ester, ethyl ester, propyl ester, isopropyl ester, n-butyl ester, sec-butyl ester, t-butyl ester, pentyl ester, isopentyl ester, t-amyl ester, hexyl ester, heptyl ester, octyl ester, cyclopentyl ester, cyclohexyl ester, cycloheptyl ester, norbornyl ester, and adamantyl ester groups.

The halogen-substituted alkyl group includes chloromethyl, trifluoromethyl, 1,1,1-trifluoroethyl, 1,1,1-trichloroethyl, and nonafluorobutyl.

The halogen-substituted aryl group includes fluorophenyl, chlorophenyl, bromophenyl, iodophenyl, 2-fluorophenyl, 3-fluorophenyl, 4-fluorophenyl, 2,3,5,6-tetrafluorophenyl, and 2,3,4,5,6-pentafluorophenyl.

The alkoxy group and the alkenyloxy group include methoxy, ethoxy, propoxy, isopropoxy, n-butoxy, sec-butoxy, t-butoxy, pentyloxy, isopentyloxy, t-amyloxy, hexyloxy, heptyloxy, octyloxy, cyclopentyloxy, cyclohexyloxy, cycloheptyloxy, norbornyloxy, adamantyloxy, acryloxy, and methacryloxy.

The acyl group includes acetyl, trifluoroacetyl, benzoyl, and naphthalenoyl.

Examples of particularly preferred basic compounds as component (F) are 1,5-diazabicyclo[4.3.0]non-5-ene, 1,8-diazabicyclo[5.4.0]undec-7-ene, 1,4-diazabicyclo[2,2,2]octane, hexamethylenetetramine, pyrazoles, imidazoles, pyrimidines, tertiary morpholines (e.g., CHMETU), quinuclidine, (−)-sparteine, 2,8-dimethyl-6H,12H-5,11-methanodibenzo[b,f][1,5]diazocine, and julolidine.

Especially preferred of them are triphenylimidazole, 1,5-diazabicyclo[4.3.0]non-5-ene, 1,8-diazabicyclo[5.4.0]undec-7-ene, 1,4-diazabicyclo[2,2,2]octane, hexamethylenetetramine, CHMETU, quinuclidine, (−)-sparteine, 2,8-dimethyl-6H,12H-5,11-methanodibenzo]b,f][1,5]diazocine, and julolidine.

These basic compounds having no acidic group are used either individually or as a combination of two or more thereof as component (F). Component (F) is used usually in an amount of 0.001 to 10% by weight, preferably 0.01 to 5% by weight, based on the total solids content of the resist composition. Less than 0.001% of component (F) is ineffective. Addition of more than 10% of component (F) can reduce the sensitivity or the developability of non-exposed areas.

If desired, the resist composition can further comprise (G) a surface active agent. At least one of fluorine-containing surface active agents, silicon-containing surface active agents, and surface active agents containing both fluorine and silicon can be used preferably.

Examples of suitable surface active agents are described, e.g., in JP-A-62-36663, JP-A-61-226746, JP-A-61-226745, JP-A-62-170950, JP-A-63-34540, JP-A-7-230165, JP-A-8-62834, JP-A-9-54432, JP-A-9-5988, and U.S. Pat. Nos. 5,405,720, 5,360,692, 5,529,881, 5,296,330, 5,436,098, 5,576,143, 5,294,511, and 5,824,451. Commercially available fluorine-containing or silicon-containing surface active agents which can be utilized as component (G) include EFTOP series EF301 and EF303 (from Shin Akita Kasei K.K.); Fluorad series FC430 and FC431 (from Sumitomo 3M Ltd.); Megafac series F171, F173, F176, F189, and R08 (from Dainippon Ink & Chemicals Inc.); Surflon series S-382, SC101, 102, 103, 104, 105 and 106 (from Asahi Glass Co., Ltd.); and Troy Sol S-366 (from Troy Chemical Industries, Inc.). Polysiloxane polymer KP-341 (from Shin-Etsu Chemical Co., Ltd.) is also useful as a silicon-containing surface active agent.

Other useful surface active agents include nonionic surface active agents, such as polyoxyethylene alkyl ethers, e.g., polyoxyethylene lauryl ether, polyoxyethylene stearyl ether, polyoxyethylene cetyl ether, and polyoxyethylene oleyl ether; polyoxyethylene alkylaryl ethers, e.g., polyoxyethylene octylphenyl ether and polyoxyethylene nonylphenyl ether; ethylene oxide-propylene oxide block copolymers; sorbitan fatty acid esters, e.g., sorbitan monolaurate, sorbitan monopalmitate, sorbitan monostearate, sorbitan monooleate, sorbitan trioleate, and sorbitan tristearate; polyoxyethylene sorbitan fatty acid esters, e.g., polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate.

Component (G), preferably the fluorine- and/or silicon-containing surface active agent, is used usually in an amount of 0.001 to 2% by weight, preferably 0.01 to 1% by weight, based on the total solids content of the resist composition. The above-recited surface active agents can be used either individually or as an appropriate mixture thereof.

If desired, the resist composition of the invention can further comprise other components, such as dyes. Suitable dyes include oil soluble dyes and basic dyes. Examples thereof are Oil Yellow #101, Oil Yellow #103, Oil Pink #312, Oil Green BG, Oil Blue BOS, Oil Blue #603, Oil Black BY, Oil Black BS, and Oil Black T-505 (all available from Orient Chemical Industries, Ltd.); Crystal Violet (C.I. 42555), Methyl Violet (C.I. 42535), Rhodamine B (C.I. 45170B), Malachite Green (C.I. 42000), and Methylene Blue (C.I. 52015).

Components (A) to (D) and, if desired, components (F) and (G)) are dissolved in a solvent (component (E)) capable of dissolving these components to prepare a resist composition of the invention, which is ready to be applied to a substrate. The solvent as component (E) includes (i) alcohol solvents typified by propylene glycol monomethyl ether, propylene glycol monoethyl ether, ethylene glycol, ethylene glycol monomethyl ether, and ethylene glycol monoethyl ether and (ii) non-alcohol solvents typified by ethylene chloride, cyclohexanone, cyclopentanone, 2-heptanone, γ-butyrolactone, methyl ethyl ketone, 2-methoxyethyl acetate, ethylene glycol monomethyl ether acetate, ethylene glycol monoethyl ether acetate, propylene glycol monomethyl ether acetate, propylene glycol monoethyl ether acetate, toluene, ethyl acetate, methyl lactate, ethyl lactate, methyl methoxypropionate, ethyl ethoxypropionate, methylpyruvate, ethyl pyruvate, propyl pyruvate, N,N-dimethylformamide, dimethyl sulfoxide, N-methylpyrrolidone, tetrahydrofuran, and propylene carbonate. The alcohol solvents are preferred to the non-alcohol solvents. The alcohol solvents exhibit high dissolving capabilities for the compound (C). The above-enumerated solvents can be used either individually or as a mixture thereof. The non-alcohol solvents are effective in improving the resist profile (reducing tailing of side walls) and the in-plane uniformity of the resist pattern. In using a mixed solvent, it is particularly preferred to combine at least one of the alcohol solvents (i) and at least one of the non-alcohol solvents (ii). An advisable mixing ratio of the alcohol solvent (i) to the non-alcohol solvent (ii) ranges 99.9/0.1 to 10/90, preferably 95/5 to 20/80, still preferably 90/10 to 40/60, by weight.

The resist composition of the invention preferably has a solids content of 0.1 to 30% by weight, particularly 1.0 to 20% by weight.

Patterning of the resist film in the production of, for example, precise integrated circuit devices is performed as follows. The negative photoresist composition of the invention is applied to a substrate to form a negative-working resist film. The substrate includes a silicon wafer with a silicon dioxide coat and a transparent substrate, such as a glass substrate and an ITO substrate.

The resist film is exposed with an e-beam lithography system (accelerating voltage: 75 keV or higher) or an X-ray lithography system, heated, developed, rinsed, and dried to fabricate a satisfactory resist pattern.

Aqueous alkali solutions are used as a developing solution for the negative-working photoresist composition of the invention. The alkali includes inorganic alkalis, such as sodium hydroxide, potassium hydroxide, sodium carbonate, sodium silicate, sodium metasilicate, and aqueous ammonia; primary amines, such as ethylamine and n-propylamine; secondary amines, such as diethylamine and di-n-butylamine; tertiary amines, such as triethylamine and methyldiethylamine; alcohol amines, such as dimethylethanolamine and triethanolamine; quaternary ammonium salts, such as tetramethylammonium hydroxide, tetraethylammonium hydroxide, and choline; and cyclic amines, such as pyrrole and piperidine. The aqueous alkali solution may contain adequate amounts of alcohols, such as isopropyl alcohol, and surface active agents, such as nonionic surface active agents. Developing solutions containing the quaternary ammonium salt, particularly tetramethylammonium hydroxide or choline, are preferred.

### EXAMPLES

The present invention will now be illustrated in greater detail with reference to Examples, but it should be understood that the invention is by no means limited thereto.

### Synthesis Example 1

Synthesis of Alkali-Soluble Resin a-(39):

In 100 ml of acetone was dissolved 12.0 g of poly(4-hydroxystyrene) (Mw=10,500; Mw/Mn=1.2), 2.0 g of pyridine was added, and 1.3 g of acetic anhydride was added thereto. The mixture was heated at 50° C. for 3 hours while stirring to conduct reaction. The reaction mixture was poured into 1 liter of ion-exchanged water with vigorous stirring, whereupon a white resin precipitated. The resulting resin was dried under reduced pressure to give 12.2 g of resin a-(39).

Resin a-(39) was found to have a weight average molecular weight (Mw: polystyrene equivalent) of 11,400 and a molecular weight distribution (Mw/Mn) of 1.2 as measured by GPC. The molar composition ratio x/y (4-hydroxystyrene/4-acetoxystyrene) was 88/12 measured by NMR analysis.

### Synthesis Example 2

Synthesis of Alkali-Soluble Resin a-(91):

In 30 ml of 1-methoxy-2-propanol were dissolved 3.8 g (0.015 mol) of 2-[(4′-hydroxyphenyl)carbonyloxy)ethyl methacrylate, 1.0 g (0.009 mol) of 2-hydroxyethyl acrylate, and 0.3 g of acrylonitrile. A solution of 50 mg of a polymerization initiator 2,2′-azobis(2,4-dimethylvaleronitrile) (V-65, available from Wako Pure Chemical Industries, Ltd.), 8.8 g (0.035 mol) of 2-[(4′-hydroxyphenyl)carbonyloxy)ethyl methacrylate, 2.4 g (0.021 mol) of 2-hydroxyethyl acrylate, and 0.7 g (0.014 mol) of acrylonitrile in 70 ml of 1-methoxy-2-propanol was added thereto dropwise at 70° C. over 2 hours while stirring in a nitrogen stream. Two hours later, an additional 50 mg portion of the initiator was added, and the reaction was continued for 2 hours. The temperature was raised to 90° C., and the stirring was continued for another hour. The reaction mixture was allowed to cool and poured into 1 liter of ion-exchanged water with vigorous stirring, whereupon a white resin precipitated. The resulting resin was dried under reduced pressure to give 15.8 g of resin a-(91). Resin a-(91) had a weight average molecular weight (Mw: polystyrene equivalent) of 11,000 and a molecular weight distribution (Mw/Mn) of 1.5 measured by GPC. NMR analysis revealed that the molar composition ratio x/y/z was 60/30/10.

Other alkali-soluble resins according to the present invention were synthesized in the same manner as in Synthesis Examples 1 and 2.

### Synthesis Example 3

Synthesis of Crosslinking Agent HM-1:

In a 10% aqueous potassium hydroxide solution was dissolved 20 g of 1-[α-(4-hydroxyphenyl)ethyl]-4-[α,α-bis(4-hydroxyphenyl)ethyl]benzene (Trisp-PA, available from Honshu Chemical Industry Co., Ltd.) by stirring. To the solution was slowly added 60 ml of a 37% aqueous formalin solution at room temperature over 1 hour while stirring. After the addition, the stirring was continued for 6 hours at room temperature. The reaction mixture was poured into dilute sulfuric acid. The precipitate thus formed was collected by filtered, thoroughly washed with water, and recrystallized from 30 ml of methanol to yield 20 g of a hydroxymethyl-containing phenol derivative having the formula below (designated HM-1). The purity was 92% as measured by liquid chromatography.

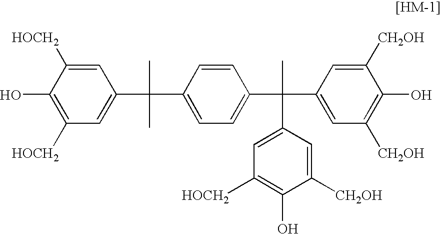

### Synthesis Example 4

Synthesis of Crosslinking agent MM-1:

In 1 liter of methanol was dissolved 20 g of the hydroxymethyl-containing phenol derivative HM-1 obtained in Synthesis Example 3 by heating with stirring. To the resulting solution was added 1 ml of concentrated sulfuric acid, followed by heating under reflux for 12 hours. After completion of the reaction, the reaction mixture was cooled, and 2 g of potassium carbonate was added thereto. The mixture was thoroughly concentrated, and the concentrate was dissolved in 300 ml of ethyl acetate. The solution was washed with water and concentrated to dryness to afford 22 g of a methoxymethyl-containing phenol derivative having the formula below (designated MM-1) as a white solid. The purity was 90% measured by liquid chromatography.

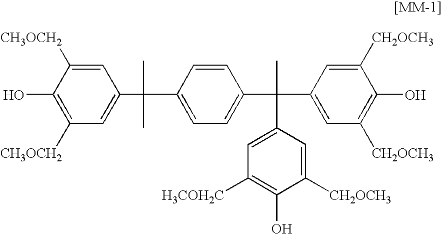

Phenol derivatives MM-2, MM-3, and MM-4 shown below were synthesized in the same manner as described above.

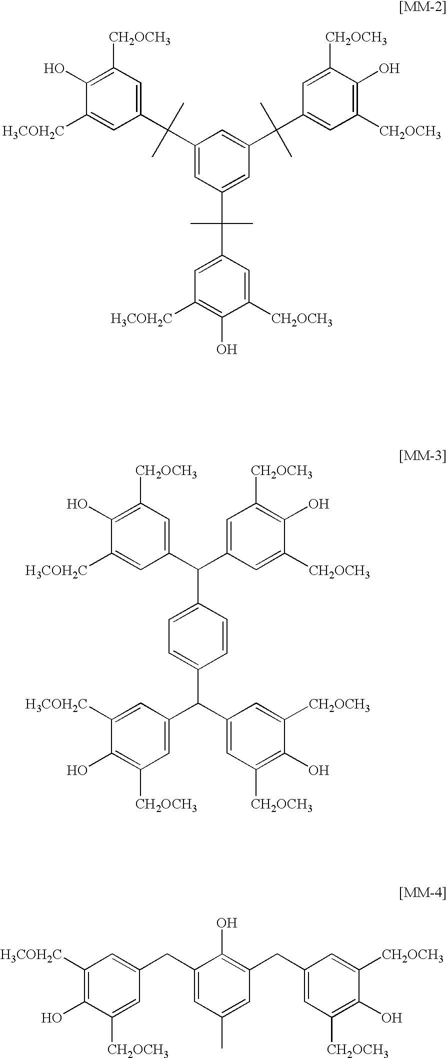

### Examples 1 to 18 and Comparative Examples 1 to 8

1) Resist Film Formation

The compounds (A) to (D), (G), and (F) shown in Tables 1 and 2 below were dissolved in the solvent (E) shown in Tables 1 and 2 to prepare a negative resist composition having the formulation shown below.

Resist Composition Formulation:

| | | |
|---|---|---|
| Alkali-soluble resin (B) | 2.0 | g |
| Acid generator (A) | 0.14 | g |
| (C) + (D) | 0.90 | g (in total) |
| Surface active agent (G) | 0.0040 | g |
| Basic compound (F) | 0.0080 | g |
| Solvent (E) | 18.0 | g (in total) |

The composition was filtered through a 0.1 μm Teflon filter and applied to a hexamethyldisilazane-treated silicon wafer with a spin coater and dried on a vacuum contact hot plate at 110° C. for 90 seconds to form a 0.3 μm thick resist film.

TABLE 1

| Exam- | | | | | | |
|---|---|---|---|---|---|---|
| ple | | | | | | |
| No. | (A) | (B) | (C)/(D) | (E) | (G) | (F) |
| 1 | A1-5/ | 1 | C-6/MM-1 = | S1/S3/S8 = | W1/W2 = | OE-3 |
| | PAG7-3 = | | 6/1 | 70/20/10 | 1/1 | |
| | 9/1 | | | | | |
| 2 | A1-14/ | 2 | C-1/MM-1 = | S1/S6 = | W1/W5 = | OE-4 |
| | PAG7-3 = | | 3/2 | 85/15 | 1/1 | |
| | 3/1 | | | | | |
| 3 | A1-21/ | 93 | C1/B2 = 1/1 | S1/S7 = | W1 | OE-2 |
| | PAG7-3 = | | | 68/32 | | |
| | 2/1 | | | | | |
| 4 | A1-28/ | 57 | C-119/B-8 = | S1/S6/S10 = | W4 | OE-3 |
| | PAG7-5 = | | 5/4 | 65/28/7 | | |
| | 1/1 | | | | | |
| 5 | A1-5 | 35 | C-6/B-10 = | S1/S9 = | W3 | OE-4 |
| | | | 1/3 | 88/12 | | |
| 6 | A1-7 | 27 | C-70/B-20 = | S1/S11 = | W1 | OE-2 |
| | | | 3/1 | 90/10 | | |
| 7 | A1-13 | 25 | C-94/B-1 = | S1/S3 = | W1 | OE-1 |
| | | | 1/3 | 70/30 | | |
| 8 | A1-33 | 1 | C-102/B-3 = | S1 | W1 | OE-3 |
| | | | 2/1 | | | |
| 9 | PAG7-3 | 27 | C-97/B-6 = | S8 | W1 | OE-1 |
| | | | 2/1 | | | |
| 10 | A1-7 | 57 | C-55/ | S3 | W1 | OE-1 |
| | | | MM-1 = | | | |
| | | | 7/3 | | | |
| 11 | A1-5 | 93 | C-207/ | S1 | W1 | OE-1 |
| | | | MM-2 = | | | |
| | | | 1/3 | | | |
| 12 | A1-42 | 31 | C-23/B-2 = | S2 | W1/W5 = | OE-1 |
| | | | 5/1 | | 1/1 | |
| 13 | A1-5 | 3 | C-2/B-20 = | S7 | W1 | OE-1 |
| | | | 1/1 | | | |
| 14 | PAG7-2 | 2 | C-43/B-20 = | S4 | W1 | OE-1 |
| | | | 1/5 | | | |
| 15 | A1-45 | 91 | C-51/ | S1 | W1 | OE-1 |
| | | | MM-1 = | | | |
| | | | 3/1 | | | |
| 16 | A1-30 | 27 | C-1/B-7 = | S2 | W1 | OE-1 |
| | | | 1/1 | | | |
| 17 | A1-33 | 1 | C-42/ | S6 | — | OE-1 |
| | | | MM-1 = | | | |
| | | | 1/3 | | | |
| 18 | PAG7-3 | 39 | C-41/B-2 = | S1 | — | — |
| | | | 5/2 | | | |

TABLE 2

| Comparative | | | | | | |
|---|---|---|---|---|---|---|
| Example No. | (A) | (B) | (C) | (E) | (G) | (F) |
| 1 | A1-7 | 1 | C-1 | S1 | W1 | OE-1 |
| 2 | A1-5 | 27 | C-1 | S5 | W1 | OE-1 |
| 3 | A1-13 | 2 | C-1 | S1 | W1 | OE-1 |
| 4 | A1-14 | 91 | C-1 | S1 | — | OE-1 |
| 5 | A1-5 | 1 | C-1 | S5 | — | OE-1 |
| 6 | A1-7 | 1 | C-1 | S3 | — | OE-1 |
| 7 | A1-21 | 1 | C-1 | S3 | — | — |
| 8 | A1-33 | 1 | C-1 | S1 | — | — |

The alkali-soluble resins (B) shown in Tables 1 and 2 had the following molar composition ratios and molecular weights:

(1) Mw=15,000; Mw/Mn=1.1

(2) Mw=9,000; Mw/Mn=1.2

(3) Mw=8,000; Mw/Mn=1.3

(25) x/y=70/30; Mw=16,000; Mw/Mn=1.5

(27) x/y=80:20; Mw=9,000; Mw/Mn=1.1

(31) x/y=90/10; Mw=8,500; Mw/Mn=1.3

(35) x/y=75:25; Mw=20,000; Mw/Mn=2.1

(39) x/y=88:12; Mw=11,400; Mw/Mn=1.2

(57) x/y=95:5; Mw=5,000; Mw/Mn=1.2

(91) x/y/z=60/30/10; Mw=11,000; Mw/Mn=1.5

(93) x/y=85:15; Mw=9,300; Mw/Mn=1.1

In Table 1 all the mixing ratios of the acid generators (A), the solvents (E), and the surface active agents (G) and the (C)/(D) mixing ratios are given by weight. The solvents (E), surface active agents (G), and basic compounds (F) used in Examples and Comparative Examples are shown below.

Solvent (E):

S1: propylene glycol monomethyl ether acetate

S2: propylene glycol monomethyl ether propionate

S3: ethyl lactate

S4: butyl acetate

S5: 2-heptanone

S6: propylene glycol monomethyl ether

S7: ethoxyethyl propionate

S8: γ-butyrolactone

S9: ethylene carbonate

S10: propylene carbonate

S11: cyclohexanone

Surface Active Agent (G):

W1: Megafac F176 (F-containing surfactant, available from Dainippon Ink & Chemicals Inc.)

W2: Megafac R08 (F- and S-containing, from Dainippon Ink & Chemical)

W3: polysiloxane KP-341 (from Shin-Etsu Chemical Co., Ltd.)

W4: polyoxyethylene triphenyl ether

W5: Troy Sol S-366 (from Troy Chemical Industries, Inc.)

Basic Compound (F):

OE-1: 4-dimethylaminopyridine

OE-2: benzimidazole

OE-3: 2,4,5-triphenylimidazole

OE-4: 1,4-diazabicyclo[5.4.0]undecene

(2) Patterning

The resist film was exposed in a line/space grating pattern by use of an e-beam lithography system (accelerating voltage: 50 keV) and heated on a vacuum contact hot plate at 110° C. for 60 seconds. The resist film was soaked in a 2.38% aqueous solution of tetramethylammonium hydroxide (TMAH) for 60 seconds, rinsed with water for 30 seconds, and dried. The pattern was observed under a scanning electron microscope and evaluated as follows. The results are shown in Table 3.

Sensitivity and Resolution:

The minimum exposure dose necessary to resolve 0.15 μm wide lines (line:space=1:1) was taken as a sensitivity, and the resolution limit (line:space=1:1) at that dose was taken as a resolution. Where a resist film was incapable of resolving 0.15 μm lines (line:space=1:1), the resolution limit of the resist was taken as a resolution, and the dose for the resolution limit was taken as a sensitivity.

Isolated Line Performance:

The resolution limit (the minimum line width) in resolving an isolated line pattern (line:space=1:10) at the sensitivity (the minimum dose for resolving the above-described dense line pattern (line:space=1/1)) was taken as isolated line performance.

TABLE 3

| | | | Isolated Line |
|---|---|---|---|
| | Resolution | Sensitivity | Performance |
| | (μm) | (μC/cm²) | (μm) |
| Example 1 | 0.08 | 8 | 0.09 |
| Example 2 | 0.08 | 9 | 0.10 |
| Example 3 | 0.08 | 10 | 0.10 |
| Example 4 | 0.09 | 10 | 0.10 |
| Example 5 | 0.010 | 12 | 0.11 |
| Example 6 | 0.08 | 9 | 0.10 |
| Example 7 | 0.09 | 12 | 0.11 |
| Example 8 | 0.09 | 9 | 0.10 |
| Example 9 | 0.10 | 9 | 0.11 |
| Example 10 | 0.09 | 8 | 0.11 |
| Example 11 | 0.09 | 10 | 0.10 |
| Example 12 | 0.10 | 7 | 0.12 |
| Example 13 | 0.09 | 9 | 0.11 |
| Example 14 | 0.09 | 12 | 0.11 |
| Example 15 | 0.09 | 8 | 0.11 |
| Example 16 | 0.08 | 10 | 0.10 |
| Example 17 | 0.09 | 8 | 0.11 |
| Example 18 | 0.11 | 6 | 0.11 |
| Comparative | 0.09 | 8 | 0.15 |
| Example 1 | | | |
| Comp. Example 2 | 0.10 | 9 | 0.16 |
| Comp. Example 3 | 0.09 | 9 | 0.15 |
| Comp. Example 4 | 0.09 | 8 | 0.16 |
| Comp. Example 5 | 0.10 | 9 | 0.16 |
| Comp. Example 6 | 0.08 | 9 | 0.14 |
| Comp. Example 7 | 0.09 | 7 | 0.15 |
| Comp. Example 8 | 0.10 | 7 | 0.16 |

It is seen from Table 3 that the negative resist compositions of the present invention are markedly superior to the comparative ones in sensitivity, resolution, and isolated line performance.

### Examples 19 to 23 and Comparative Example 9

A resist film was formed of the compositions of Examples 2, 7, 8, 10, and 11 and Comparative Example 4 in the same manner as in Example 1. The resist film was exposed in a line/space grating pattern by means of an e-beam lithography system at an accelerating voltage of 100 keV. The exposed film was heated, developed and rinsed in the same manner as in Example 1. The resulting pattern was evaluated under a scanning electron micrograph in the same manner as in Example 1. The results obtained are shown in Table 4.

TABLE 4

| | | | Isolated Line |
|---|---|---|---|
| | Resolution | Sensitivity | Performance |
| | (μm) | (μC/cm²) | (μm) |
| Example 19 | 0.065 | 12.5 | 0.090 |
| Example 20 | 0.070 | 16.5 | 0.095 |
| Example 21 | 0.070 | 13.5 | 0.095 |
| Example 22 | 0.075 | 11.5 | 0.100 |
| Example 23 | 0.075 | 14.0 | 0.100 |
| Comp. Example 9 | 0.070 | 12.0 | 0.155 |

The results in Table 4 prove the negative resist compositions of the invention markedly superior to the comparative one in sensitivity, resolution, and isolated line performance in e-beam lithography even at a high accelerating voltage.

The present invention provides a negative resist composition which is excellent in sensitivity, resolution, and isolated line performance under a high accelerating voltage condition and therefore suited to e-beam lithography.

This application is based on Japanese Patent application JP 2001-383291, filed Dec. 17, 2001, the entire content of which is hereby incorporated by reference, the same as if set forth at length.

What is claimed is:

1. A negative resist composition comprising the components of:
(A) a compound capable of generating an acid on exposure to active light or a radiation;
(B) a resin soluble in an aqueous alkali solution;
(C) a compound having an alcohol structure which is excited by the acid generated by the component (A) to reduce an alkali solubility of a resist film formed of the negative resist composition;
(D) a crosslinking agent which is excited by the acid generated by the component (A) to induce a crosslinking reaction; and
(E) a solvent.

2. The negative resist composition according to claim 1, wherein the component (D) is at least one compound selected from the group consisting of a compound represented by the following formula (2): 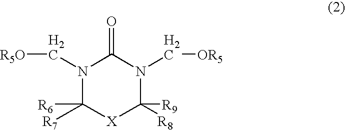
wherein two R₅'s each independently represent a hydrogen atom, an alkyl group or an acyl group; R₆, R₇, R₈, and R₉ each independently represent a hydrogen atom, a hydroxyl group, an alkyl group or an alkoxy group; and X represents a single bond, a methylene group or an oxygen atom, a compound represented by the following formula (3): 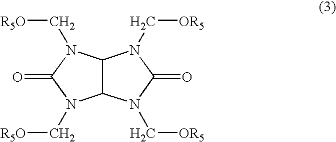
wherein a plurality of R₅'s each independently represent a hydrogen atom, an alkyl group or an acyl group,
a compound represented by the following formula (4): 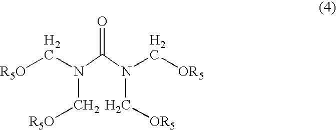
wherein a plurality of R₅'s each independently represent a hydrogen atom, an alkyl group or an acyl group,
and an alkoxymethylated melamine compound.

3. The negative resist composition according to claim 1, wherein the component (D) is a phenol derivative having 1 to 6 benzene rings and having at least two substituents selected from a hydroxymethyl group and an alkoxymethyl group bonded to at least one of the benzene rings.

4. The negative resist composition according to claim 1, which further comprises the component (F) a basic compound.

5. The negative resist composition according to claim 2, which further comprises the component (F) a basic compound.

6. The negative resist composition according to claim 3, which further comprises the component (F) a basic compound.

7. The negative resist composition according to claim 1, which further comprises the component (G) a surface active agent.

8. The negative resist composition according to claim 1, wherein the component (B) comprises a repeating unit represented by the following formula (a): 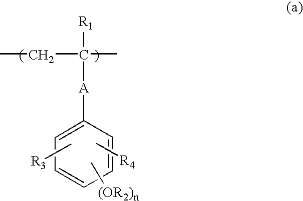
wherein R₁ represents a hydrogen atom, a halogen atom, a cyano group, a substituted or unsubstituted alkyl group or a substituted or unsubstituted haloalkyl group; R₂ represents a hydrogen atom, a substituted or unsubstituted alkyl group, a substituted or unsubstituted cycloalkyl group, a substituted or unsubstituted aryl group, a substituted or unsubstituted aralkyl group or a substituted or unsubstituted acyl group; R₃ and R₄ each independently represent a hydrogen atom, a halogen atom, a cyano group, a substituted or unsubstituted alkyl group, a substituted or unsubstituted cycloalkyl group, a substituted or unsubstituted alkenyl group, a substituted or unsubstituted aralkyl group or a substituted or unsubstituted aryl group; A represents a single bond, a substituted or unsubstituted alkylene group, a substituted or unsubstituted alkenylene group, a substituted or unsubstituted cycloalkylene group, a substituted or unsubstituted arylene
group, —O—, —SO₂—, —O—CO—R₅—, —CO—O—R₆— or —CO—N(R₇)—R₈—; R₅, R₆, and R₈ each independently represent a single bond, a substituted or unsubstituted alkylene group, a substituted or unsubstituted alkenylene group, a substituted or unsubstituted cycloalkylene group, a substituted or unsubstituted arylene group, or a divalent linking group made up of at least one of these divalent groups and at least one member selected from the group consisting of an ether structure, an ester structure, an amide structure, a urethane structure, and a ureido structure; R₇ represents a hydrogen atom, a substituted or unsubstituted alkyl group, a substituted or unsubstituted cycloalkyl group, a substituted or unsubstituted aralkyl group or a substituted or unsubstituted aryl group; n represents an integer of 1 to 3; when n is 2 or 3, two R₂'s may be taken together to form a ring; and R₂ and R₃ or R₄ may be taken together to form a ring.

9. The negative resist composition according to claim 1, wherein the component (B) has a weight average molecular weight of 1,000 to 200,000.

10. The negative resist composition according to claim 1, wherein the component (B) has a molecular weight distribution of 1 to 10.

11. The negative resist composition according to claim 1, wherein the component (A) is in an amount of 0.001 to 40% by weight based on a solid content of the composition.

12. The negative resist composition according to claim 1, wherein the component (B) is in an amount of 30 to 95% by weight based on a solid content of the composition.

13. The negative resist composition according to claim 1, wherein the component (C) is in an amount of 3 to 65% by weight based on a solid content of the composition.

14. The negative resist composition according to claim 1, wherein the component (D) is in an amount of 3 to 70% by weight based on a solid content of the composition.

15. The negative resist composition according to claim 4, wherein the component (F) comprises one of structures represented by formulae (A) to (E): 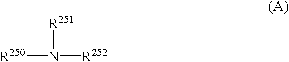
wherein R²⁵⁰, R²⁵¹, and R²⁵² each independently represent a hydrogen atom, an alkyl group having 1 to 6 carbon atoms, an aminoalkyl group having 1 to 6 carbon atoms, a hydroxyalkyl group having 1 to 6 carbon atoms, or a substituted or unsubstituted aryl group having 6 to 20 carbon atoms; R²⁵¹ and R²⁵² may be taken together to form a ring; 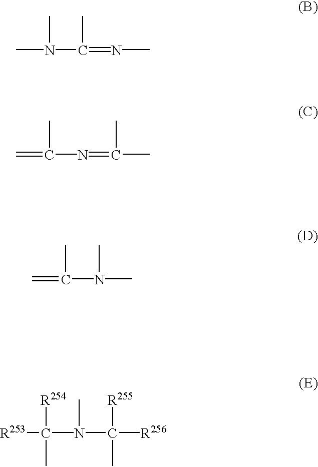
wherein R²⁵³, R²⁵⁴, R²⁵⁵, and R²⁵⁶ each independently represent an alkyl group having 1 to 6 carbon atoms.

16. The negative resist composition according to claim 5, wherein the component (F) comprises one of structures represented by formulae (A) to (E): 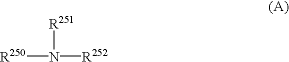
wherein R²⁵⁰, R²⁵¹, and R²⁵² each independently represent a hydrogen atom, an alkyl group having 1 to 6 carbon atoms, an aminoalkyl group having 1 to 6 carbon atoms, a hydroxyalkyl group having 1 to 6 carbon atoms, or a substituted or unsubstituted aryl group having 6 to 20 carbon atoms; R²⁵¹ and R²⁵² may be taken together to form a ring; 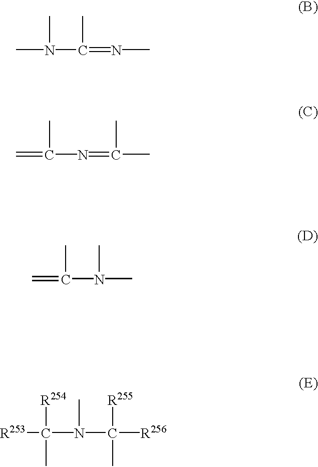
wherein R²⁵³, R²⁵⁴, R²⁵⁵, and R²⁵⁶ each independently represent an alkyl group having 1 to 6 carbon atoms.

17. The negative resist composition according to claim 6, wherein the component (F) comprises one of structures represented by formulae (A) to (E): 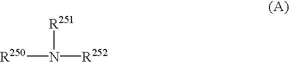
wherein R²⁵⁰, R²⁵¹, and R²⁵² each independently represent a hydrogen atom, an alkyl group having 1 to 6 carbon atoms, an aminoalkyl group having 1 to 6 carbon atoms, a hydroxyalkyl group having 1 to 6 carbon atoms, or a substituted or unsubstituted aryl group having 6 to 20 carbon atoms; R²⁵¹ and R²⁵² may be taken together to form a ring; 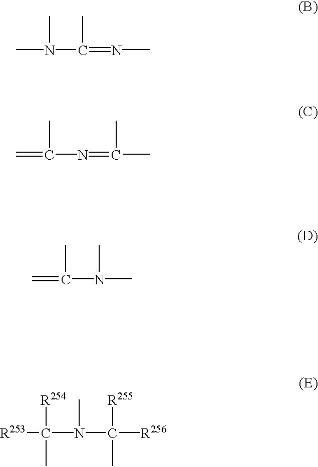
wherein R²⁵³, R²⁵⁴, R²⁵⁵, and R²⁵⁶ each independently represent an alkyl group having 1 to 6 carbon atoms.
